(19) United States
(12) Patent Application Publication
(10) Pub. No.: US 2026/0202964 A1
(43) Pub. Date: Jul. 16, 2026

(54) Random Access Decoding with Rapid Convergence in Variable-Length Encoded Bitstreams

(71) Applicant: AtomBeam Technologies Inc., Moraga, CA (US)

(72) Inventors: Joshua Cooper, Columbia, SC (US); Charles Yeomans, Orinda, CA (US)

(21) Appl. No.: 19/546,740

(22) Filed: Feb. 23, 2026

Related U.S. Application Data
(63) Continuation-in-part of application No. 19/422,108, filed on Dec. 16, 2025.
Application No. 19/422,108 is a continuation of application No. 18/737,962, filed on Jun. 8, 2024, now Pat. No. 12,498,853.
Application No. 18/737,962 is a continuation-in-part of application No. 18/469,520, filed on Sep. 18, 2023, now Pat. No. 12,079,474.
Application No. 18/469,520 is a continuation of application No. 18/178,556, filed on Mar. 6, 2023, now Pat. No. 11,762,557.
Application No. 18/178,556 is a continuation-in-part of application No. 17/727,913, filed on Apr. 25, 2022, now Pat. No. 11,620,051.
Application No. 17/727,913 is a continuation of application No. 17/404,699, filed on Aug. 17, 2021, now Pat. No. 11,385,794.
(60) Provisional application No. 63/332,525, filed on Apr. 19, 2022.

(51) Int. Cl. G06F 3/06; H03M 7/30

(52) U.S. Cl. CPC G06F 3/0608; G06F 3/0623; G06F 3/0659; G06F 3/067; H03M 7/6005; H03M 7/6011

(57) ABSTRACT

Systems and methods that enable random access decoding within variable-length encoded bitstreams by initializing multiple decoder instances at staggered bit offsets and detecting convergence through agreement among decoded outputs. In an embodiment, given an arbitrary target offset N in a Huffman-encoded bitstream, decoder instances are initialized at consecutive positions N through N+L−1, where L is the maximum codeword length. Each instance decodes independently according to the codebook until a valid codeword boundary is identified. This agreement-based detection provides correctness guarantees without requiring synchronization markers, external indices, or modifications to the encoded data. The disclosed techniques preserve compression efficiency while enabling efficient random access, search operations, and partial decoding previously unavailable with variable-length encodings.

### CROSS-REFERENCE TO RELATED APPLICATIONS

Priority is claimed in the application data sheet to the following patents or patent applications, each of which is expressly incorporated herein by reference in its entirety:
Ser. No. 19/422,108
Ser. No. 18/737,962
Ser. No. 18/469,520
Ser. No. 18/178,556
Ser. No. 17/727,913
Ser. No. 17/404,699
63/332,525

### BACKGROUND OF THE INVENTION

### Field of the Invention

The present invention is in the field of computer data encoding, and in particular random access decoding within variable-length encoded bitstreams.

### Discussion of the State of the Art

Data compression has become essential in modern computing systems for reducing storage requirements and transmission bandwidth. Variable-length coding schemes, particularly Huffman coding and its variants, represent a widely deployed class of compression techniques that achieve high compression ratios by assigning shorter codes to more frequently occurring symbols. These prefix-free codes ensure that sequential decoding from a known starting point produces a unique and unambiguous sequence of decoded symbols. Canonical Huffman coding, which imposes additional structural constraints on the codeword assignment, has gained particular prominence due to its ability to represent the codebook compactly by storing only code lengths and symbol ordering rather than the entire tree structure.

Despite their widespread adoption and compression efficiency, variable-length codes present a fundamental limitation when applications require random access to compressed data. When decoding begins at an arbitrary bit position within an encoded bitstream, rather than at a known codeword boundary, the decoder cannot reliably determine where valid codewords begin and end. The prefix-free property alone does not provide self-synchronization capability. As a result, a decoder initiated at a misaligned position will interpret arbitrary bit sequences as valid codewords, producing incorrect decoded output that may persist indefinitely. This lack of self-synchronization severely restricts the utility of variable-length encoding in applications requiring partial decoding, search operations, or indexed access to specific portions of compressed data streams.

Conventional approaches to enabling random access in variable-length encoded data have relied on external mechanisms to restore alignment. One common solution involves inserting explicit synchronization markers at regular intervals throughout the encoded bitstream. While such markers provide definitive resynchronization points, they introduce storage overhead and reduce compression efficiency. The periodic insertion of fixed-pattern markers also requires modification of the encoding process and complicates the integration of compression into existing data formats and protocols. Another approach maintains auxiliary indices that map logical positions or byte offsets to known codeword boundaries. However, these indices consume additional storage, must be updated whenever codebooks change, and become impractical for large datasets or streaming applications where the overhead of index maintenance outweighs the benefits of compression.

Some systems have attempted to address random access limitations by employing fixed-length block encoding, where data is divided into independent blocks that can be decoded separately. While this approach enables random access at block granularity, it fundamentally compromises compression efficiency because each block must be encoded independently without exploiting statistical dependencies across block boundaries. Additionally, the block structure imposes artificial constraints on the data organization and may not align well with the natural structure of the underlying data. Other systems have explored the use of restart points with reduced context, but these solutions still require explicit markers or metadata and sacrifice compression performance at the restart boundaries.

The theoretical foundations of variable-length coding have been extensively studied, and it is well established that certain structural properties of codebooks can affect decoding behavior when initiated from arbitrary positions. Research into self-synchronizing codes has identified specific code constructions that guarantee bounded resynchronization distances, but these constructions typically impose severe restrictions on the codebook design that limit compression efficiency or applicability. Furthermore, existing theoretical analyses have focused primarily on worst-case guarantees rather than characterizing typical convergence behavior under realistic source models and practical codebook constructions.

The present invention addresses these longstanding limitations by providing systems and methods for random access decoding within variable-length encoded bitstreams without requiring synchronization markers, external indices, or modifications to the encoded data. By initializing multiple decoder instances at staggered bit offsets and detecting convergence through agreement among decoded outputs, the disclosed techniques enable efficient boundary recovery and correct decoding from arbitrary starting positions while preserving the compression efficiency and format compatibility of standard variable-length encodings.

### SUMMARY OF THE INVENTION

The inventor has conceived, and reduced to practice, systems and methods that enable random access decoding within variable-length encoded bitstreams by initializing multiple decoder instances at staggered bit offsets and detecting convergence through agreement among decoded outputs. In an embodiment, given an arbitrary target offset N in a Huffman-encoded bitstream, decoder instances are initialized at consecutive positions N through N+L−1, where Lis the maximum codeword length. Each instance decodes independently according to the codebook until a valid codeword boundary is identified. This agreement-based detection provides correctness guarantees without requiring synchronization markers, external indices, or modifications to the encoded data. The disclosed techniques preserve compression efficiency while enabling efficient random access, search operations, and partial decoding previously unavailable with variable-length encodings.

According to a preferred embodiment, a computer system is disclosed configured to execute software instructions stored on nontransitory machine-readable storage media, wherein the software instructions comprise instructions that cause the computer system to: receive a variable-length encoded bitstream comprising a sequence of codewords drawn from a prefix-free codebook; select an arbitrary bit offset within the variable-length encoded bitstream; initialize a plurality of decoder instances at staggered bit offsets, wherein the staggered bit offsets comprise the arbitrary bit offset and a set of additional offsets positioned sequentially following the arbitrary bit offset, and wherein a spacing between consecutive offsets does not exceed a maximum codeword length associated with the prefix-free codebook; advance each decoder instance of the plurality of decoder instances through the variable-length encoded bitstream by decoding symbols according to the prefix-free codebook; monitor decoded outputs produced by the plurality of decoder instances to detect decoder agreement, wherein decoder agreement is identified when all decoder instances produce identical decoded symbol sequences over a defined region of the bitstream; identify a valid codeword boundary at a bit position where decoder agreement is detected; and decode data from the identified valid codeword boundary.

According to another preferred embodiment, a computer-implemented method is disclosed comprising the steps of: receiving a variable-length encoded bitstream comprising a sequence of codewords drawn from a prefix-free codebook; selecting an arbitrary bit offset within the variable-length encoded bitstream; initializing a plurality of decoder instances at staggered bit offsets, wherein the staggered bit offsets comprise the arbitrary bit offset and a set of additional offsets positioned sequentially following the arbitrary bit offset, and wherein a spacing between consecutive offsets does not exceed a maximum codeword length associated with the prefix-free codebook; advancing each decoder instance of the plurality of decoder instances through the variable-length encoded bitstream by decoding symbols according to the prefix-free codebook; monitoring decoded outputs produced by the plurality of decoder instances to detect decoder agreement, wherein decoder agreement is identified when all decoder instances produce identical decoded symbol sequences over a defined region of the bitstream; identifying a valid codeword boundary at a bit position where decoder agreement is detected; and decoding data from the identified valid codeword boundary.

According to an aspect of an embodiment, the plurality of decoder instances comprises L decoder instances initialized at consecutive bit offsets from N to N+L−1, where Nis the arbitrary bit offset and L is the maximum codeword length.

According to an aspect of an embodiment, additional software instructions cause the computer system to: execute the plurality of decoder instances in parallel using multiple processor cores or vectorized instructions; and evaluate agreement among the plurality of decoder instances continuously or at periodic checkpoints during parallel execution.

According to an aspect of an embodiment, additional software instructions cause the computer system to: execute the plurality of decoder instances in an interleaved manner by advancing each decoder instance incrementally; and evaluate agreement among the plurality of decoder instances after each incremental advancement or after a fixed number of decoding steps.

According to an aspect of an embodiment, additional software instructions cause the computer system to: order the plurality of decoder instances according to their current bit positions; advance only a decoder instance at an earliest position among the plurality of decoder instances at each decoding step; detect when two or more decoder instances reach a same bit position and merge the two or more decoder instances by discarding redundant instances; and identify a valid codeword boundary when a single decoder instance remains after merging.

According to an aspect of an embodiment, additional software instructions cause the computer system to: evaluate the prefix-free codebook to determine whether the prefix-free codebook is a BAD codebook or a NOT BAD codebook; classify the prefix-free codebook as a BAD codebook when a greatest common divisor of all codeword lengths in the prefix-free codebook is greater than one; and reject or modify the prefix-free codebook when the prefix-free codebook is classified as a BAD codebook.

According to an aspect of an embodiment, the prefix-free codebook is classified as a NOT BAD codebook when the greatest common divisor of all codeword lengths is equal to one, and wherein NOT BAD codebooks enable high-probability rapid convergence to valid codeword boundaries.

According to an aspect of an embodiment, the prefix-free codebook comprises a canonical Huffman codebook in which codewords of a same length are assigned consecutive binary values and shorter codewords have numerically smaller values than longer codewords. According to an aspect of an embodiment, additional software instructions cause the computer system to: require decoder agreement to persist over a minimum number of decoded symbols or bits before declaring convergence; and adjust a length of an agreement window to achieve a desired confidence level that convergence has occurred.

According to an aspect of an embodiment, additional software instructions cause the computer system to perform random access search by: identifying a candidate match location within the variable-length encoded bitstream using a search operation; initiating decoding at or near the candidate match location by selecting an arbitrary bit offset corresponding to the candidate match location; converging to a valid codeword boundary using the plurality of decoder instances and agreement-based boundary detection; and verifying the candidate match location by decoding a limited window of data surrounding the identified valid codeword boundary.

### BRIEF DESCRIPTION OF THE DRAWING FIGURES

The accompanying drawings illustrate several aspects and, together with the description, serve to explain the principles of the invention according to the aspects. It will be appreciated by one skilled in the art that the particular arrangements illustrated in the drawings are merely exemplary and are not to be considered as limiting of the scope of the invention or the claims herein in any way.

FIG. 1 is a diagram showing an embodiment of the system in which all components of the system are operated locally.

FIG. 2 is a diagram showing an embodiment of one aspect of the system, the data deconstruction engine.

FIG. 3 is a diagram showing an embodiment of one aspect of the system, the data reconstruction engine.

FIG. 4 is a diagram showing an embodiment of one aspect of the system, the library management module.

FIG. 5 is a diagram showing another embodiment of the system in which data is transferred between remote locations.

FIG. 6 is a diagram showing an embodiment in which a standardized version of the sourceblock library and associated algorithms would be encoded as firmware on a dedicated processing chip included as part of the hardware of a plurality of devices.

FIG. 7 is a diagram showing an example of how data might be converted into reference codes using an aspect of an embodiment.

FIG. 8 is a method diagram showing the steps involved in using an embodiment to store data.

FIG. 9 is a method diagram showing the steps involved in using an embodiment to retrieve data.

FIG. 10 is a method diagram showing the steps involved in using an embodiment to encode data.

FIG. 11 is a method diagram showing the steps involved in using an embodiment to decode data.

FIG. 12 is a diagram showing an exemplary system architecture, according to a preferred embodiment of the invention.

FIG. 13 is a diagram showing a more detailed architecture for a customized library generator.

FIG. 14 is a diagram showing a more detailed architecture for a library optimizer.

FIG. 15 is a diagram showing a more detailed architecture for a transmission and storage engine.

FIG. 16 is a method diagram illustrating key system functionality utilizing an encoder and decoder pair.

FIG. 17 is a method diagram illustrating possible use of a hybrid encoder/decoder to improve the compression ratio.

FIG. 18 is a flow diagram illustrating the use of a data encoding system used to recursively encode data to further reduce data size.

FIG. 19 is an exemplary system architecture of a data encoding system used for cyber security purposes.

FIG. 20 is a flow diagram of an exemplary method used to detect anomalies in received encoded data and producing a warning.

FIG. 21 is a flow diagram of a data encoding system used for Distributed Denial of Service (DDoS) attack denial.

FIG. 22 is an exemplary system architecture of a data encoding system used for data mining and analysis purposes.

FIG. 23 is a flow diagram of an exemplary method used to enable high-speed data mining of repetitive data.

FIG. 24 is an exemplary system architecture of a data encoding system used for remote software and firmware updates.

FIG. 25 is a flow diagram of an exemplary method used to encode and transfer software and firmware updates to a device for installation, for the purposes of reduced bandwidth consumption.

FIG. 26 is an exemplary system architecture of a data encoding system used for large-scale software installation such as operating systems.

FIG. 27 is a flow diagram of an exemplary method used to encode new software and operating system installations for reduced bandwidth required for transference.

FIG. 28 is a block diagram of an exemplary system architecture of a codebook training system for a data encoding system, according to an embodiment.

FIG. 29 is a block diagram of an exemplary architecture for a codebook training module, according to an embodiment.

FIG. 30 is a block diagram of another embodiment of the codebook training system using a distributed architecture and a modified training module.

FIG. 31 is a method diagram illustrating the steps involved in using an embodiment of the codebook training system to update a codebook.

FIG. 32 is an exemplary system architecture for an encoding system with multiple codebooks.

FIG. 33 is a flow diagram describing an exemplary algorithm for encoding of data using multiple codebooks.

FIG. 34 is a flow diagram describing an exemplary codebook sorting algorithm for determining a plurality of codebooks to be shuffled between during the encoding process.

FIG. 35 is a diagram showing an exemplary codebook shuffling method.

FIG. 36 is a block diagram illustrating an exemplary system architecture for compacting and encrypting anonymized data, according to an embodiment.

FIG. 37 is a diagram illustrating an exemplary data source tally record and its anonymized counterpart, according to some embodiments.

FIG. 38 is a block diagram illustrating an exemplary anonymized tally record that may be received by system and an exemplary half-backed codebook constructed using the information contained in the anonymized tally record.

FIG. 39 is a diagram illustrating two exemplary data sources, each of which is shown in non-anonymized tally record and anonymized tally record form.

FIG. 40A is diagram illustrating an exemplary process of constructing a half-backed codebook using two data sources and data source stencils, according to some embodiments.

FIG. 40B is a diagram illustrating an exemplary process of transforming a combined half-backed codebook comprising data from two different data sources using data source stencils according to some embodiments.

FIG. 41 is a diagram illustrating an exemplary hybrid stencil constructed using three different data sources, according to some embodiments.

FIG. 42 is an exemplary flow diagram for a method of preparing an anonymized tally record, according to some embodiments.

FIG. 43 is an exemplary flow diagram for a method for constructing a half-backed codebook using a received anonymized tally record, according to some embodiments.

FIG. 44 is a block diagram illustrating an exemplary hardware architecture of a computing device.

FIG. 45 is a block diagram illustrating an exemplary logical architecture for a client device.

FIG. 46 is a block diagram showing an exemplary architectural arrangement of clients, servers, and external services.

FIG. 47 is another block diagram illustrating an exemplary hardware architecture of a computing device.

FIG. 48 is a method diagram illustrating the steps involved in using an embodiment of the codebook system to perform indexing and data analysis.

FIG. 49 is a method diagram illustrating the steps involved in using a hierarchical library manager to process sourceblocks.

FIG. 50 illustrates a variable-length encoded bitstream and addresses one of the fundamental challenges in random access decoding of variable-length encoded data.

FIG. 51 illustrates the fundamental technique of multiple decoder initialization at staggered bit offsets, which forms the core mechanism for enabling random access decoding within variable-length encoded bitstreams.

FIG. 52 illustrates parallel decoder execution and agreement-based boundary detection, which represents one embodiment of executing multiple decoder instances to achieve rapid convergence to valid codeword boundaries.

FIG. 53 illustrates leapfrog and collision-merge execution, which represents an alternative embodiment for managing multiple decoder instances that reduces redundant decoding work compared to parallel execution.

FIG. 54 illustrates a system architecture for random access decoding that enables decoding to begin at an arbitrary bit offset within a variable-length encoded bitstream and to converge rapidly to a valid codeword boundary.

FIG. 55 illustrates a method flowchart for random access decoding that enables decoding to begin at an arbitrary bit offset within a variable-length encoded bitstream and to converge rapidly to a valid codeword boundary.

FIG. 56 illustrates a decision tree for codebook qualification that classifies variable-length prefix-free codebooks based on structural properties that affect convergence behavior under random access decoding.

FIG. 57 illustrates the temporal progression of decoder convergence showing the transition from incorrect decoding to correct decoding as multiple decoder instances advance through a variable-length encoded bitstream.

### DETAILED DESCRIPTION OF THE INVENTION

The inventor has conceived, and reduced to practice, systems and methods that enable random access decoding within variable-length encoded bitstreams by initializing multiple decoder instances at staggered bit offsets and detecting convergence through agreement among decoded outputs. In an embodiment, given an arbitrary target offset N in a Huffman-encoded bitstream, decoder instances are initialized at consecutive positions N through N+L−1, where L is the maximum codeword length. Each instance decodes independently according to the codebook until a valid codeword boundary is identified. This agreement-based detection provides correctness guarantees without requiring synchronization markers, external indices, or modifications to the encoded data. The disclosed techniques preserve compression efficiency while enabling efficient random access, search operations, and partial decoding previously unavailable with variable-length encodings.

This disclosure describes systems, methods, and machine-readable media for enabling random access decoding within variable-length encoded bitstreams, particularly those encoded using Huffman coding and its variants including canonical Huffman codes. The disclosed techniques address a fundamental limitation of variable-length prefix-free codes, which do not provide self-synchronization when decoding begins at arbitrary bit positions rather than known codeword boundaries. When a decoder is initiated at a misaligned position within a compressed bitstream, the prefix-free property alone cannot ensure that the decoder will realign to valid codeword boundaries, and incorrect decoding may persist indefinitely depending on the structure of the codebook and the statistical properties of the encoded data.

The disclosed approach operates by initializing multiple decoder instances at staggered bit offsets within the encoded bitstream. Given an arbitrary target offset N, decoder instances are initialized at consecutive positions N, N+1, N+2, through N+L−1, where L represents the maximum codeword length associated with the codebook, including any compound or hybrid codewords. Each decoder instance proceeds independently according to the same decoding rules and codebook, and the decoded outputs are monitored for agreement. When all decoder instances produce identical decoded symbol sequences over a defined region, convergence to a valid codeword boundary is detected. The point of agreement corresponds to a bit position that is guaranteed to be a valid codeword boundary, after which decoding may proceed with assurance of correctness.

The correctness guarantee provided by agreement-based detection does not rely on explicit synchronization markers, prior knowledge of codeword boundaries, or modification of the encoded bitstream. Because all possible starting alignments within a codeword-length window are represented by the decoder instances, agreement among all instances implies that decoding has converged to the unique correct alignment. This mechanism operates transparently with existing encoding formats and preserves the compression efficiency benefits of variable-length encoding.

Multiple execution embodiments are disclosed for managing the decoder instances, including parallel execution where all instances advance simultaneously using multiple processor cores or vectorized instructions, sequential interleaved execution where instances advance incrementally in a time-sliced manner, and leapfrog execution where only the instance at the earliest position advances at each step and instances are merged upon collision. Hybrid strategies may combine aspects of these approaches, and resource management techniques may limit active instances or prioritize certain instances based on heuristic indicators. The selection of execution strategy may be static or dynamic based on available hardware resources, observed convergence behavior, or characteristics of the encoded data.

The disclosure introduces a classification system for variable-length codebooks based on their convergence properties under random access decoding. A codebook is classified as BAD if it exhibits structural properties that prevent or significantly inhibit convergence when decoding is initiated from arbitrary bit offsets. Specifically, a codebook is BAD if the greatest common divisor of all codeword lengths is greater than one, or if the codebook may be expressed as a recursive composition of one or more BAD codebooks according to a defined composition operator. Codebooks that do not satisfy these criteria are classified as NOT BAD and enable high-probability rapid convergence under random access decoding. Canonical Huffman codebooks in which the greatest common divisor of the codeword lengths equals one constitute a provable subclass of NOT BAD codebooks.

Codebook qualification mechanisms evaluate codebooks prior to deployment or dynamically during operation to determine whether they are BAD or NOT BAD. Codebooks classified as BAD may be rejected, modified, or replaced with alternative codebooks that satisfy NOT BAD criteria. By explicitly qualifying codebooks according to their convergence properties, the disclosed systems provide predictable and reliable random access decoding behavior without relying on ad hoc heuristics or undocumented assumptions.

The performance characteristics of convergence are analyzed under probabilistic source models including finite-state Markov processes and other stationary or ergodic stochastic processes. For NOT BAD codebooks and data generated by such sources, the expected number of bits that must be decoded before convergence occurs is on the order of f(epsilon)M2, where M represents the average codeword length and f(epsilon) is a function that depends on the desired confidence level epsilon. This expected convergence distance is typically small relative to the size of encoded files or streams, making the disclosed techniques practical for random access, search, and partial decoding operations. Convergence may be declared only after decoder agreement persists over a minimum number of decoded symbols or bits, with the agreement window length selected to achieve a desired confidence level.

The disclosed techniques integrate with search, indexing, and partial decoding operations within systems that process variable-length encoded data. In search applications, decoding may begin at or near a candidate match location identified through approximate search techniques, rapidly converging to a valid codeword boundary to enable efficient verification without requiring decoding from the beginning of the stream or maintaining extensive alignment indices. For substring and pattern matching, the system decodes only a limited window surrounding a target offset, performing recognition on decoded symbols while minimizing decoding overhead. In systems with coarse-grained indices providing approximate bit offsets, the convergence techniques refine these approximate offsets into precise codeword boundaries.

Database and storage systems that maintain data in variable-length encoded form benefit from the disclosed random access capabilities. Compressed database engines, column stores, log-structured storage systems, and archival storage systems achieve improved query performance, reduced input and output operations, and new access patterns over compressed data through efficient partial decoding. The techniques enable these systems to access specific portions of compressed datasets without decompressing entire files or maintaining auxiliary structures that would otherwise impose storage and maintenance overhead.

System embodiments comprise a decoder subsystem configured to initialize multiple decoder instances at staggered bit offsets, agreement detection logic configured to identify convergence to valid codeword boundaries, optional codebook qualification logic configured to classify codebooks as BAD or NOT BAD, and control logic configured to terminate decoder instances upon convergence. These systems may be implemented in software, hardware, or combinations thereof, and may operate on stored or streaming encoded data. Method embodiments comprise selecting an arbitrary bit offset within a variable-length encoded bitstream, initializing a plurality of decoder instances at staggered offsets, advancing decoder instances according to a codebook, detecting agreement among decoder instances, identifying a valid codeword boundary based on detected agreement, and decoding data from the identified boundary. Computer-readable media store instructions that, when executed by one or more processors, cause the processors to perform these methods.

The disclosed subject matter explicitly excludes insertion of synchronization markers or delimiters into encoded bitstreams, modification of encoded data formats to support random access, guarantees of convergence for adversarially constructed BAD codebooks, and reliance on fixed-length encoding schemes. The techniques operate solely through decoder behavior and codebook structure, transforming variable-length encoded data from a sequential-access format into one that supports efficient random access while preserving encoding efficiency and remaining compatible with existing encoding systems.

Applications of the disclosed technology include network data transmission systems where bandwidth efficiency is critical, such as the Neurpac compaction system described in related disclosures. In such systems, control nodes manage leaf node connections and determine which services are compacted and how compaction is performed for bidirectional data flow. The random access capabilities enable features such as search within compacted data streams, partial decoding of transmitted files, and indexed access to compressed log files without requiring complete decompression. Security information and event management systems that collect log information from distributed resources benefit from reduced bandwidth consumption while maintaining the ability to search and analyze specific portions of the compressed log streams.

The disclosed random access decoding techniques fundamentally transform the utility of variable-length encoding by eliminating the traditional trade-off between compression efficiency and random access capability. By enabling efficient boundary recovery through decoder behavior rather than data structure modification, the invention preserves the compression benefits of variable-length codes while providing access patterns previously available only with fixed-length encodings or indexed compression schemes. This advancement enables new applications and deployment scenarios for compression technology in storage systems, network protocols, database engines, and data analytics platforms.

One or more different aspects may be described in the present application. Further, for one or more of the aspects described herein, numerous alternative arrangements may be described; it should be appreciated that these are presented for illustrative purposes only and are not limiting of the aspects contained herein or the claims presented herein in any way. One or more of the arrangements may be widely applicable to numerous aspects, as may be readily apparent from the disclosure. In general, arrangements are described in sufficient detail to enable those skilled in the art to practice one or more of the aspects, and it should be appreciated that other arrangements may be utilized and that structural, logical, software, electrical and other changes may be made without departing from the scope of the particular aspects. Particular features of one or more of the aspects described herein may be described with reference to one or more particular aspects or figures that form a part of the present disclosure, and in which are shown, by way of illustration, specific arrangements of one or more of the aspects. It should be appreciated, however, that such features are not limited to usage in the one or more particular aspects or figures with reference to which they are described. The present disclosure is neither a literal description of all arrangements of one or more of the aspects nor a listing of features of one or more of the aspects that must be present in all arrangements.

Headings of sections provided in this patent application and the title of this patent application are for convenience only, and are not to be taken as limiting the disclosure in any way.

Devices that are in communication with each other need not be in continuous communication with each other, unless expressly specified otherwise. In addition, devices that are in communication with each other may communicate directly or indirectly through one or more communication means or intermediaries, logical or physical.

A description of an aspect with several components in communication with each other does not imply that all such components are required. To the contrary, a variety of optional components may be described to illustrate a wide variety of possible aspects and in order to more fully illustrate one or more aspects. Similarly, although process steps, method steps, algorithms or the like may be described in a sequential order, such processes, methods and algorithms may generally be configured to work in alternate orders, unless specifically stated to the contrary. In other words, any sequence or order of steps that may be described in this patent application does not, in and of itself, indicate a requirement that the steps be performed in that order. The steps of described processes may be performed in any order practical. Further, some steps may be performed simultaneously despite being described or implied as occurring non-simultaneously (e.g., because one step is described after the other step). Moreover, the illustration of a process by its depiction in a drawing does not imply that the illustrated process is exclusive of other variations and modifications thereto, does not imply that the illustrated process or any of its steps are necessary to one or more of the aspects, and does not imply that the illustrated process is preferred. Also, steps are generally described once per aspect, but this does not mean they must occur once, or that they may only occur once each time a process, method, or algorithm is carried out or executed. Some steps may be omitted in some aspects or some occurrences, or some steps may be executed more than once in a given aspect or occurrence.

When a single device or article is described herein, it will be readily apparent that more than one device or article may be used in place of a single device or article. Similarly, where more than one device or article is described herein, it will be readily apparent that a single device or article may be used in place of the more than one device or article.

The functionality or the features of a device may be alternatively embodied by one or more other devices that are not explicitly described as having such functionality or features. Thus, other aspects need not include the device itself.

Techniques and mechanisms described or referenced herein will sometimes be described in singular form for clarity. However, it should be appreciated that particular aspects may include multiple iterations of a technique or multiple instantiations of a mechanism unless noted otherwise. Process descriptions or blocks in figures should be understood as representing modules, segments, or portions of code which include one or more executable instructions for implementing specific logical functions or steps in the process. Alternate implementations are included within the scope of various aspects in which, for example, functions may be executed out of order from that shown or discussed, including substantially concurrently or in reverse order, depending on the functionality involved, as would be understood by those having ordinary skill in the art.

### Definitions

A “BAD” codebook as used herein means a variable-length, prefix-free codebook that satisfies one or more structural criteria that prevent or significantly inhibit convergence under random access decoding. In one embodiment, a codebook is classified as BAD if the greatest common divisor of all codeword lengths is greater than one or the codebook may be expressed as a recursive composition of one or more BAD codebooks. BAD codebooks may cause decoder instances to fail to converge or to produce ambiguous agreement signals, and are therefore unsuitable for use with the random access decoding techniques disclosed herein. The term “bit” refers to the smallest unit of information that can be stored or transmitted. It is in the form of a binary digit (either 0 or 1). In terms of hardware, the bit is represented as an electrical signal that is either off (representing 0) or on (representing 1).

A “NOT BAD” codebook as used herein means a variable-length, prefix-free codebook that does not satisfy the criteria of a BAD codebook and that enables high-probability rapid convergence under random access decoding. In particular, canonical Huffman codebooks in which the greatest common divisor of the codeword lengths is equal to one constitute a provable subclass of NOT BAD codebooks. Other non-canonical Huffman variants and related prefix-free encodings may also be NOT BAD, provided they lack the structural defects associated with BAD codebooks.

The term “byte” refers to a series of bits exactly eight bits in length.

The term “codebook” refers to a database containing sourceblocks each with a pattern of bits and reference code unique within that library. The terms “library” and “encoding/decoding library” are synonymous with the term codebook.

The terms “compression” and “deflation” as used herein mean the representation of data in a more compact form than the original dataset. Compression and/or deflation may be either “lossless”, in which the data can be reconstructed in its original form without any loss of the original data, or “lossy” in which the data can be reconstructed in its original form, but with some loss of the original data.

The terms “compression factor” and “deflation factor” as used herein mean the net reduction in size of the compressed data relative to the original data (e.g., if the new data is 70% of the size of the original, then the deflation/compression factor is 30% or 0.3.)

The terms “compression ratio” and “deflation ratio”, and as used herein all mean the size of the original data relative to the size of the compressed data (e.g., if the new data is 70% of the size of the original, then the deflation/compression ratio is 70% or 0.7.)

The term “data” means information in any computer-readable form.

The term “data set” refers to a grouping of data for a particular purpose. One example of a data set might be a word processing file containing text and formatting information.

The term “effective compression” or “effective compression ratio” refers to the additional amount data that can be stored using the method herein described versus conventional data storage methods. Although the method herein described is not data compression, per se, expressing the additional capacity in terms of compression is a useful comparison.

The term “sourcepacket” as used herein means a packet of data received for encoding or decoding. A sourcepacket may be a portion of a data set.

The term “sourceblock” as used herein means a defined number of bits or bytes used as the block size for encoding or decoding. A sourcepacket may be divisible into a number of sourceblocks. As one non-limiting example, a 1 megabyte sourcepacket of data may be encoded using 512 byte sourceblocks. The number of bits in a sourceblock may be dynamically optimized by the system during operation. In one aspect, a sourceblock may be of the same length as the block size used by a particular file system, typically 512 bytes or 4,096 bytes.

The term “codeword” refers to the reference code form in which data is stored or transmitted in an aspect of the system. A codeword consists of a reference code to a sourceblock in the library plus an indication of that sourceblock's location in a particular data set.

### Conceptual Architecture

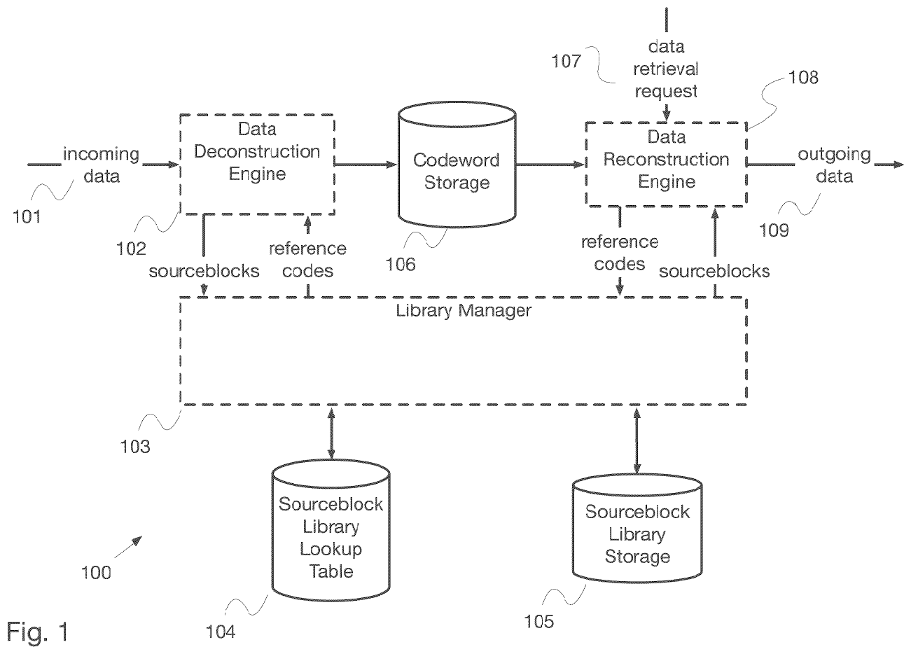

FIG. 1 is a diagram showing an embodiment 100 of the system in which all components of the system are operated locally. As incoming data 101 is received by data deconstruction engine 102. Data deconstruction engine 102 breaks the incoming data into sourceblocks, which are then sent to library manager 103. Using the information contained in sourceblock library lookup table 104 and sourceblock library storage 105, library manager 103 returns reference codes to data deconstruction engine 102 for processing into codewords, which are stored in codeword storage 106. When a data retrieval request 107 is received, data reconstruction engine 108 obtains the codewords associated with the data from codeword storage 106, and sends them to library manager 103. Library manager 103 returns the appropriate sourceblocks to data reconstruction engine 108, which assembles them into the proper order and sends out the data in its original form 109.

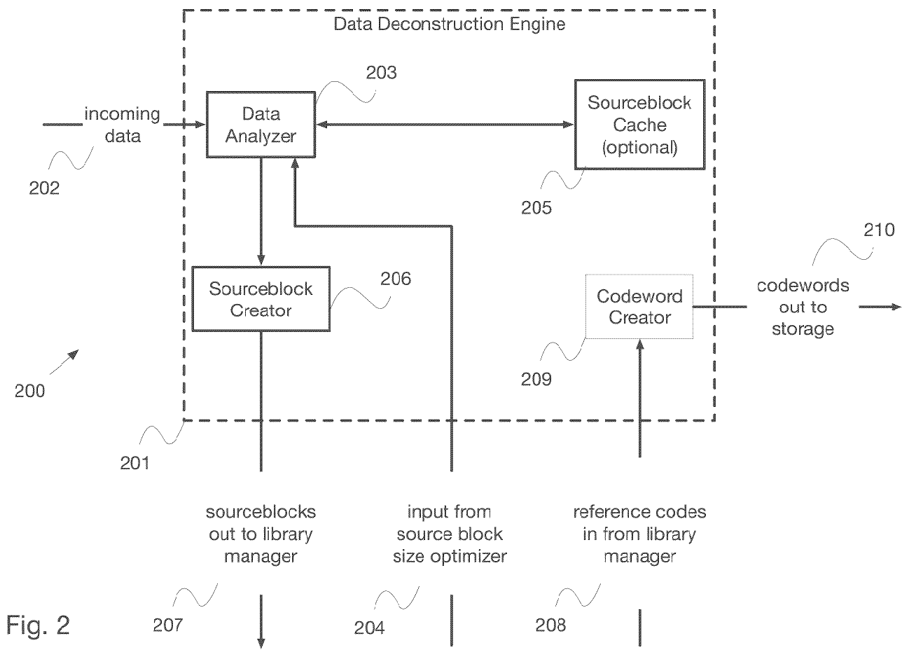

FIG. 2 is a diagram showing an embodiment of one aspect 200 of the system, specifically data deconstruction engine 201. Incoming data 202 is received by data analyzer 203, which optimally analyzes the data based on machine learning algorithms and input 204 from a sourceblock size optimizer, which is disclosed below. Data analyzer may optionally have access to a sourceblock cache 205 of recently-processed sourceblocks, which can increase the speed of the system by avoiding processing in library manager 103. Based on information from data analyzer 203, the data is broken into sourceblocks by sourceblock creator 206, which sends sourceblocks 207 to library manager 203 for additional processing. Data deconstruction engine 201 receives reference codes 208 from library manager 103, corresponding to the sourceblocks in the library that match the sourceblocks sent by sourceblock creator 206, and codeword creator 209 processes the reference codes into codewords comprising a reference code to a sourceblock and a location of that sourceblock within the data set. The original data may be discarded, and the codewords representing the data are sent out to storage 210.

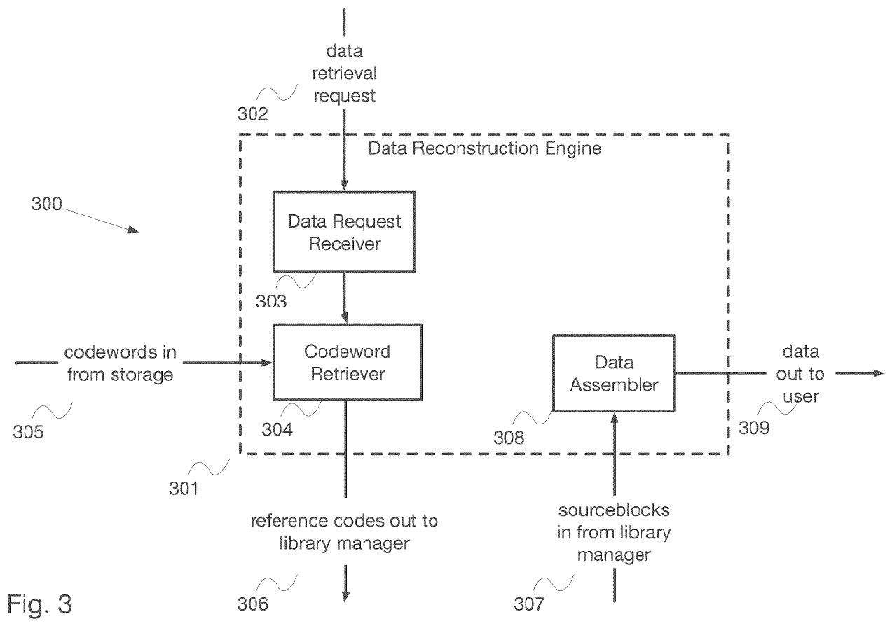

FIG. 3 is a diagram showing an embodiment of another aspect of system 300, specifically data reconstruction engine 301. When a data retrieval request 302 is received by data request receiver 303 (in the form of a plurality of codewords corresponding to a desired final data set), it passes the information to data retriever 304, which obtains the requested data 305 from storage. Data retriever 304 sends, for each codeword received, a reference codes from the codeword 306 to library manager 103 for retrieval of the specific sourceblock associated with the reference code. Data assembler 308 receives the sourceblock 307 from library manager 103 and, after receiving a plurality of sourceblocks corresponding to a plurality of codewords, assembles them into the proper order based on the location information contained in each codeword (recall each codeword comprises a sourceblock reference code and a location identifier that specifies where in the resulting data set the specific sourceblock should be restored to. The requested data is then sent to user 309 in its original form.

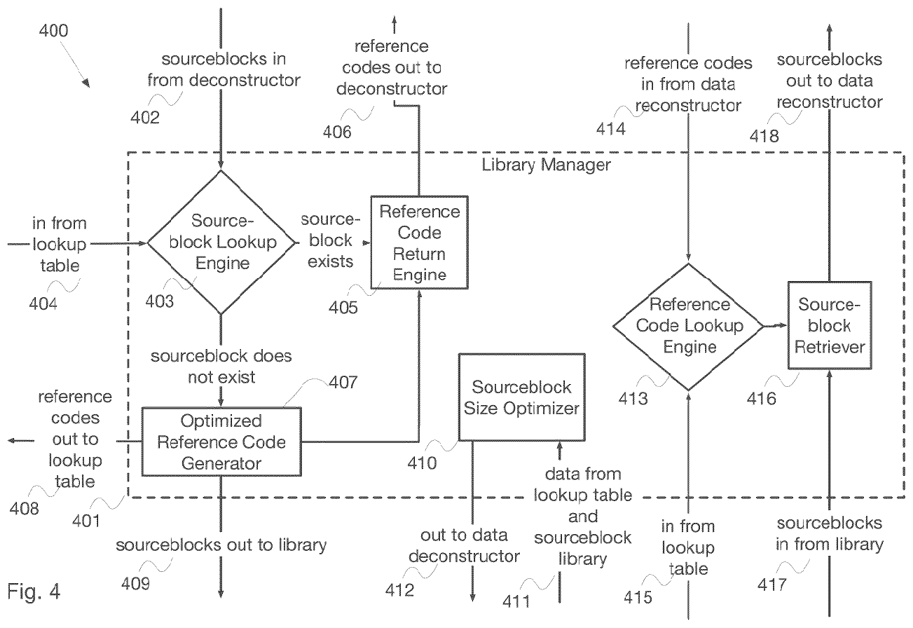

FIG. 4 is a diagram showing an embodiment of another aspect of the system 400, specifically library manager 401. One function of library manager 401 is to generate reference codes from sourceblocks received from data deconstruction engine 301. As sourceblocks are received 402 from data deconstruction engine 301, sourceblock lookup engine 403 checks sourceblock library lookup table 404 to determine whether those sourceblocks already exist in sourceblock library storage 105. If a particular sourceblock exists in sourceblock library storage 105, reference code return engine 405 sends the appropriate reference code 406 to data deconstruction engine 301. If the sourceblock does not exist in sourceblock library storage 105, optimized reference code generator 407 generates a new, optimized reference code based on machine learning algorithms. Optimized reference code generator 407 then saves the reference code 408 to sourceblock library lookup table 104; saves the associated sourceblock 409 to sourceblock library storage 105; and passes the reference code to reference code return engine 405 for sending 406 to data deconstruction engine 301. Another function of library manager 401 is to optimize the size of sourceblocks in the system. Based on information 411 contained in sourceblock library lookup table 104, sourceblock size optimizer 410 dynamically adjusts the size of sourceblocks in the system based on machine learning algorithms and outputs that information 412 to data analyzer 203. Another function of library manager 401 is to return sourceblocks associated with reference codes received from data reconstruction engine 301. As reference codes are received 414 from data reconstruction engine 301, reference code lookup engine 413 checks sourceblock library lookup table 415 to identify the associated sourceblocks; passes that information to sourceblock retriever 416, which obtains the sourceblocks 417 from sourceblock library storage 105; and passes them 418 to data reconstruction engine 301.

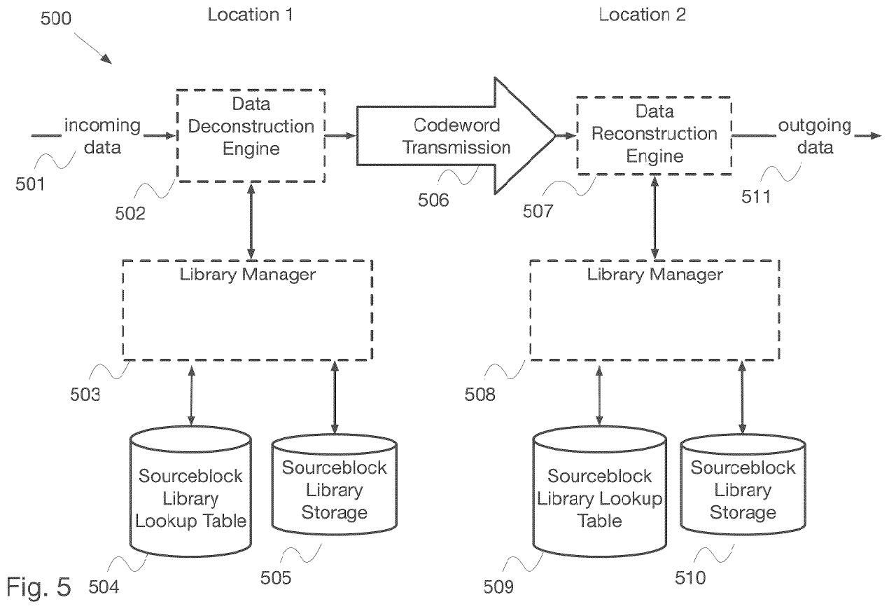

FIG. 5 is a diagram showing another embodiment of system 500, in which data is transferred between remote locations. As incoming data 501 is received by data deconstruction engine 502 at Location 1, data deconstruction engine 301 breaks the incoming data into sourceblocks, which are then sent to library manager 503 at Location 1. Using the information contained in sourceblock library lookup table 504 at Location 1 and sourceblock library storage 505 at Location 1, library manager 503 returns reference codes to data deconstruction engine 301 for processing into codewords, which are transmitted 506 to data reconstruction engine 507 at Location 2. In the case where the reference codes contained in a particular codeword have been newly generated by library manager 503 at Location 1, the codeword is transmitted along with a copy of the associated sourceblock. As data reconstruction engine 507 at Location 2 receives the codewords, it passes them to library manager module 508 at Location 2, which looks up the sourceblock in sourceblock library lookup table 509 at Location 2, and retrieves the associated from sourceblock library storage 510. Where a sourceblock has been transmitted along with a codeword, the sourceblock is stored in sourceblock library storage 510 and sourceblock library lookup table 504 is updated. Library manager 503 returns the appropriate sourceblocks to data reconstruction engine 507, which assembles them into the proper order and sends the data in its original form 511.

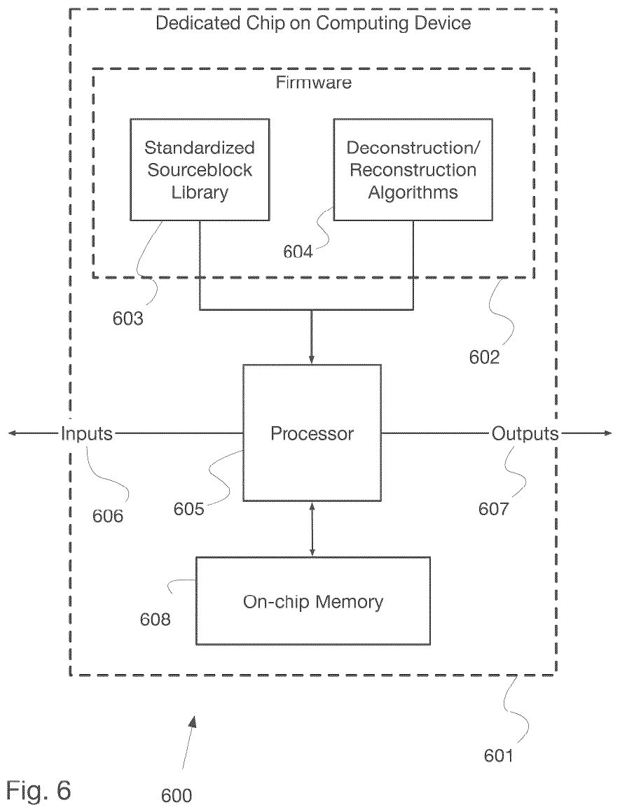

FIG. 6 is a diagram showing an embodiment 600 in which a standardized version of a sourceblock library 603 and associated algorithms 604 would be encoded as firmware 602 on a dedicated processing chip 601 included as part of the hardware of a plurality of devices 600. Contained on dedicated chip 601 would be a firmware area 602, on which would be stored a copy of a standardized sourceblock library 603 and deconstruction/reconstruction algorithms 604 for processing the data. Processor 605 would have both inputs 606 and outputs 607 to other hardware on the device 600. Processor 605 would store incoming data for processing on on-chip memory 608, process the data using standardized sourceblock library 603 and deconstruction/reconstruction algorithms 604, and send the processed data to other hardware on device 600. Using this embodiment, the encoding and decoding of data would be handled by dedicated chip 601, keeping the burden of data processing off device's 600 primary processors. Any device equipped with this embodiment would be able to store and transmit data in a highly optimized, bandwidth-efficient format with any other device equipped with this embodiment.

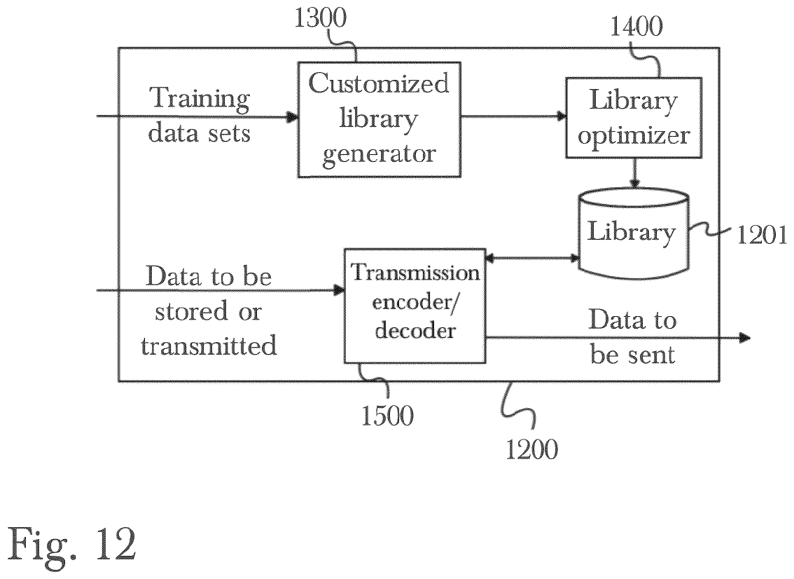

FIG. 12 is a diagram showing an exemplary system architecture 1200, according to a preferred embodiment of the invention. Incoming training data sets may be received at a customized library generator 1300 that processes training data to produce a customized word library 1201 comprising key-value pairs of data words (each comprising a string of bits) and their corresponding calculated binary Huffman codewords. The resultant word library 1201 may then be processed by a library optimizer 1400 to reduce size and improve efficiency, for example by pruning low-occurrence data entries or calculating approximate codewords that may be used to match more than one data word. A transmission encoder/decoder 1500 may be used to receive incoming data intended for storage or transmission, process the data using a word library 1201 to retrieve codewords for the words in the incoming data, and then append the codewords (rather than the original data) to an outbound data stream. Each of these components is described in greater detail below, illustrating the particulars of their respective processing and other functions, referring to FIGS. 2-4.

System 1200 provides near-instantaneous source coding that is dictionary-based and learned in advance from sample training data, so that encoding and decoding may happen concurrently with data transmission. This results in computational latency that is near zero but the data size reduction is comparable to classical compression. For example, if N bits are to be transmitted from sender to receiver, the compression ratio of classical compression is C, the ratio between the deflation factor of system 1200 and that of multi-pass source coding is p, the classical compression encoding rate is R_{C} bit/s and the decoding rate is R_{D} bit/s, and the transmission speed is S bit/s, the compress-send-decompress time will be

$${T}_{old} = \frac{N}{{R}_{C}} + \frac{N}{CS} + \frac{N}{{CR}_{D}}$$

while the transmit-while-coding time for system 1200 will be (assuming that encoding and decoding happen at least as quickly as network latency):

$${T}_{new} = \frac{{N}_{p}}{CS}$$

so that the total data transit time improvement factor is

$$\frac{{T}_{old}}{{T}_{new}} = \frac{\frac{CS}{{R}_{C}} + 1 + \frac{S}{{R}_{D}}}{p}$$

which presents a savings whenever

$$\frac{CS}{{R}_{C}} + \frac{S}{{R}_{D}} > p - 1.$$

This is a reasonable scenario given that typical values in real-world practice are C=0.32, R_{C}=1.1·10¹², R_{D}=4.2·10¹², S=10¹¹, giving

$$\frac{CS}{{R}_{C}} + \frac{S}{{R}_{D}} = 0.053 ... ,$$

such that system 1200 will outperform the total transit time of the best compression technology available as long as its deflation factor is no more than 5% worse than compression. Such customized dictionary-based encoding will also sometimes exceed the deflation ratio of classical compression, particularly when network speeds increase beyond 100 Gb/s.

The delay between data creation and its readiness for use at a receiving end will be equal to only the source word length t (typically 5-15 bytes), divided by the deflation factor C/p and the network speed S, i.e.

$${delay}_{invention} = \frac{tp}{CS}$$

since encoding and decoding occur concurrently with data transmission. On the other hand, the latency associated with classical compression is

$${delay}_{priorart} = \frac{N}{{R}_{C}} + \frac{N}{CS} + \frac{N}{{CR}_{D}}$$

where N is the packet/file size. Even with generous values chosen above as well as N=512K, t=10, and p=1.05, this results in delayᵢₙᵥₑₙₜᵢₒₙ≈3.3·10⁻¹⁰ while delayₚᵣᵢₒᵣₐᵣₜ≈1.3·10⁻⁷, a more than 400-fold reduction in latency.

A key factor in the efficiency of Huffman coding used by system 1200 is that key-value pairs be chosen carefully to minimize expected coding length, so that the average deflation/compression ratio is minimized. It is possible to achieve the best possible expected code length among all instantaneous codes using Huffman codes if one has access to the exact probability distribution of source words of a given desired length from the random variable generating them. In practice this is impossible, as data is received in a wide variety of formats and the random processes underlying the source data are a mixture of human input, unpredictable (though in principle, deterministic) physical events, and noise. System 1200 addresses this by restriction of data types and density estimation; training data is provided that is representative of the type of data anticipated in “real-world” use of system 1200, which is then used to model the distribution of binary strings in the data in order to build a Huffman code word library 1200.

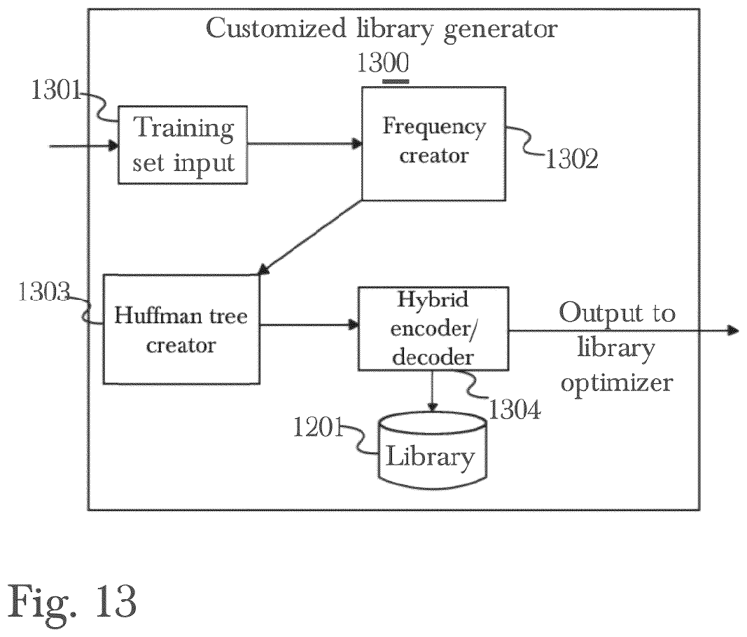

FIG. 13 is a diagram showing a more detailed architecture for a customized library generator 1300. When an incoming training data set 1301 is received, it may be analyzed using a frequency creator 1302 to analyze for word frequency (that is, the frequency with which a given word occurs in the training data set). Word frequency may be analyzed by scanning all substrings of bits and directly calculating the frequency of each substring by iterating over the data set to produce an occurrence frequency, which may then be used to estimate the rate of word occurrence in non-training data. A first Huffman binary tree is created based on the frequency of occurrences of each word in the first dataset, and a Huffman codeword is assigned to each observed word in the first dataset according to the first Huffman binary tree. Machine learning may be utilized to improve results by processing a number of training data sets and using the results of each training set to refine the frequency estimations for non-training data, so that the estimation yield better results when used with real-world data (rather than, for example, being only based on a single training data set that may not be very similar to a received non-training data set). A second Huffman tree creator 1303 may be utilized to identify words that do not match any existing entries in a word library 1201 and pass them to a hybrid encoder/decoder 1304, that then calculates a binary Huffman codeword for the mismatched word and adds the codeword and original data to the word library 1201 as a new key-value pair. In this manner, customized library generator 1300 may be used both to establish an initial word library 1201 from a first training set, as well as expand the word library 1201 using additional training data to improve operation.

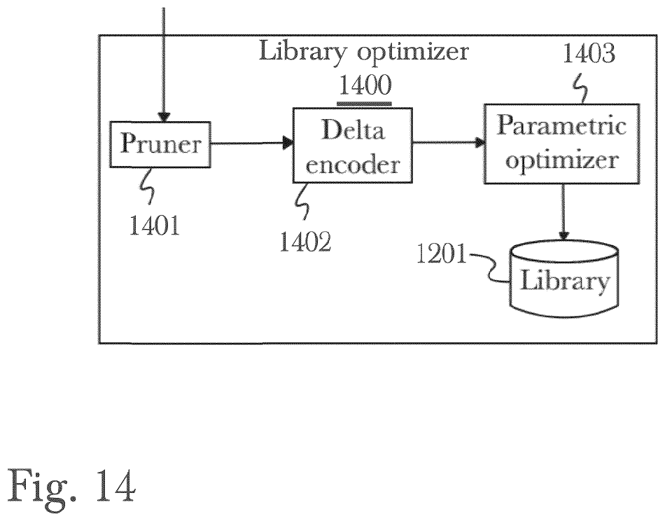

FIG. 14 is a diagram showing a more detailed architecture for a library optimizer 1400. A pruner 1401 may be used to load a word library 1201 and reduce its size for efficient operation, for example by sorting the word library 1201 based on the known occurrence probability of each key-value pair and removing low-probability key-value pairs based on a loaded threshold parameter. This prunes low-value data from the word library to trim the size, eliminating large quantities of very-low-frequency key-value pairs such as single-occurrence words that are unlikely to be encountered again in a data set. Pruning eliminates the least-probable entries from word library 1201 up to a given threshold, which will have a negligible impact on the deflation factor since the removed entries are only the least-common ones, while the impact on word library size will be larger because samples drawn from asymptotically normal distributions (such as the log-probabilities of words generated by a probabilistic finite state machine, a model well-suited to a wide variety of real-world data) which occur in tails of the distribution are disproportionately large in counting measure. A delta encoder 1402 may be utilized to apply delta encoding to a plurality of words to store an approximate codeword as a value in the word library, for which each of the plurality of source words is a valid corresponding key. This may be used to reduce library size by replacing numerous key-value pairs with a single entry for the approximate codeword and then represent actual codewords using the approximate codeword plus a delta value representing the difference between the approximate codeword and the actual codeword. Approximate coding is optimized for low-weight sources such as Golomb coding, run-length coding, and similar techniques. The approximate source words may be chosen by locality-sensitive hashing, so as to approximate Hamming distance without incurring the intractability of nearest-neighbor-search in Hamming space. A parametric optimizer 1403 may load configuration parameters for operation to optimize the use of the word library 1201 during operation. Best-practice parameter/hyperparameter optimization strategies such as stochastic gradient descent, quasi-random grid search, and evolutionary search may be used to make optimal choices for all interdependent settings playing a role in the functionality of system 1200. In cases where lossless compression is not required, the delta value may be discarded at the expense of introducing some limited errors into any decoded (reconstructed) data.

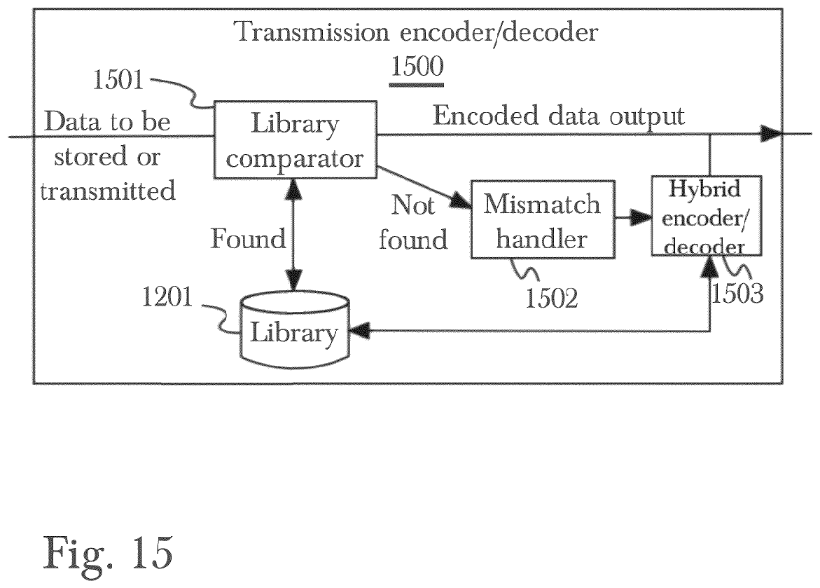

FIG. 15 is a diagram showing a more detailed architecture for a transmission encoder/decoder 1500. According to various arrangements, transmission encoder/decoder 1500 may be used to deconstruct data for storage or transmission, or to reconstruct data that has been received, using a word library 1201. A library comparator 1501 may be used to receive data comprising words or codewords, and compare against a word library 1201 by dividing the incoming stream into substrings of length t and using a fast hash to check word library 1201 for each substring. If a substring is found in word library 1201, the corresponding key/value (that is, the corresponding source word or codeword, according to whether the substring used in comparison was itself a word or codeword) is returned and appended to an output stream. If a given substring is not found in word library 1201, a mismatch handler 1502 and hybrid encoder/decoder 1503 may be used to handle the mismatch similarly to operation during the construction or expansion of word library 1201. A mismatch handler 1502 may be utilized to identify words that do not match any existing entries in a word library 1201 and pass them to a hybrid encoder/decoder 1503, that then calculates a binary Huffman codeword for the mismatched word and adds the codeword and original data to the word library 1201 as a new key-value pair. The newly-produced codeword may then be appended to the output stream. In arrangements where a mismatch indicator is included in a received data stream, this may be used to preemptively identify a substring that is not in word library 1201 (for example, if it was identified as a mismatch on the transmission end), and handled accordingly without the need for a library lookup.

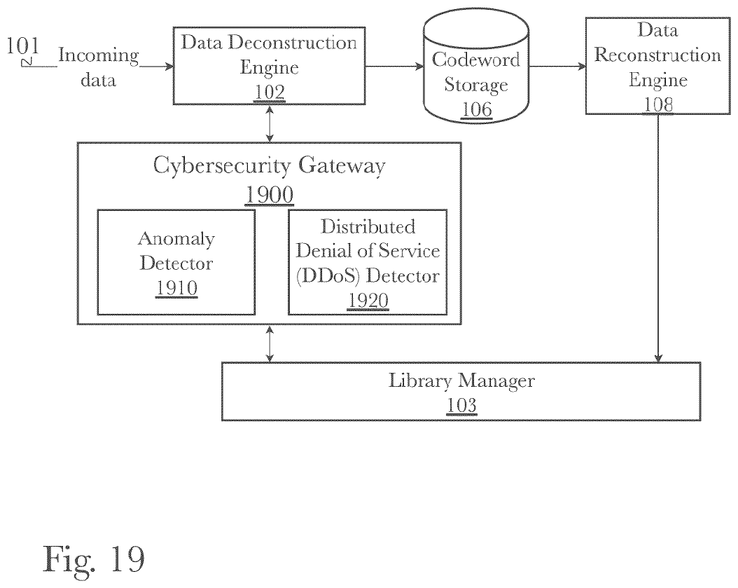

FIG. 19 is an exemplary system architecture of a data encoding system used for cyber security purposes. Much like in FIG. 1, incoming data 101 to be deconstructed is sent to a data deconstruction engine 102, which may attempt to deconstruct the data and turn it into a collection of codewords using a library manager 103. Codeword storage 106 serves to store unique codewords from this process, and may be queried by a data reconstruction engine 108 which may reconstruct the original data from the codewords, using a library manager 103. However, a cybersecurity gateway 1900 is present, communicating in-between a library manager 103 and a deconstruction engine 102, and containing an anomaly detector 1910 and distributed denial of service (DDoS) detector 1920. The anomaly detector examines incoming data to determine whether there is a disproportionate number of incoming reference codes that do not match reference codes in the existing library. A disproportionate number of non-matching reference codes may indicate that data is being received from an unknown source, of an unknown type, or contains unexpected (possibly malicious) data. If the disproportionate number of non-matching reference codes exceeds an established threshold or persists for a certain length of time, the anomaly detector 1910 raises a warning to a system administrator. Likewise, the DDoS detector 1920 examines incoming data to determine whether there is a disproportionate amount of repetitive data. A disproportionate amount of repetitive data may indicate that a DDoS attack is in progress. If the disproportionate amount of repetitive data exceeds an established threshold or persists for a certain length of time, the DDoS detector 1910 raises a warning to a system administrator. In this way, a data encoding system may detect and warn users of, or help mitigate, common cyber-attacks that result from a flow of unexpected and potentially harmful data, or attacks that result from a flow of too much irrelevant data meant to slow down a network or system, as in the case of a DDoS attack.

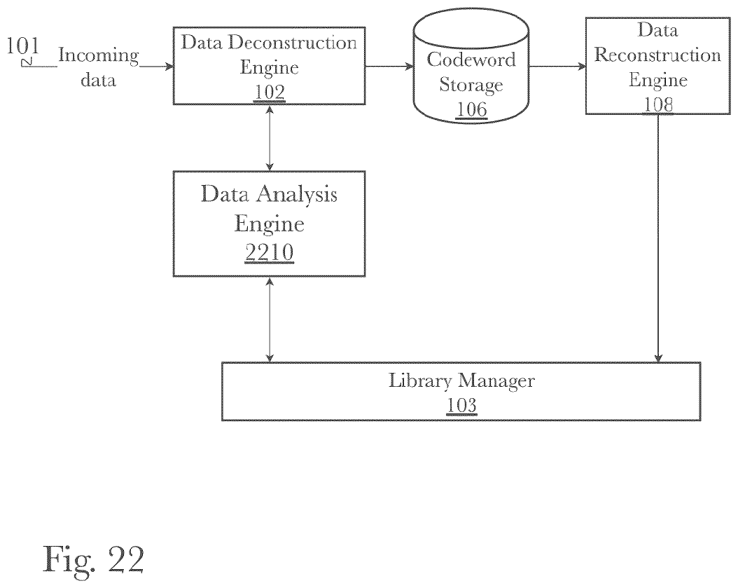

FIG. 22 is an exemplary system architecture of a data encoding system used for data mining and analysis purposes. Much like in FIG. 1, incoming data 101 to be deconstructed is sent to a data deconstruction engine 102, which may attempt to deconstruct the data and turn it into a collection of codewords using a library manager 103. Codeword storage 106 serves to store unique codewords from this process, and may be queried by a data reconstruction engine 108 which may reconstruct the original data from the codewords, using a library manager 103. A data analysis engine 2210, typically operating while the system is otherwise idle, sends requests for data to the data reconstruction engine 108, which retrieves the codewords representing the requested data from codeword storage 106, reconstructs them into the data represented by the codewords, and send the reconstructed data to the data analysis engine 2210 for analysis and extraction of useful data (i.e., data mining). Because the speed of reconstruction is significantly faster than decompression using traditional compression technologies (i.e., significantly less decompression latency), this approach makes data mining feasible. Very often, data stored using traditional compression is not mined precisely because decompression lag makes it unfeasible, especially during shorter periods of system idleness. Increasing the speed of data reconstruction broadens the circumstances under which data mining of stored data is feasible.

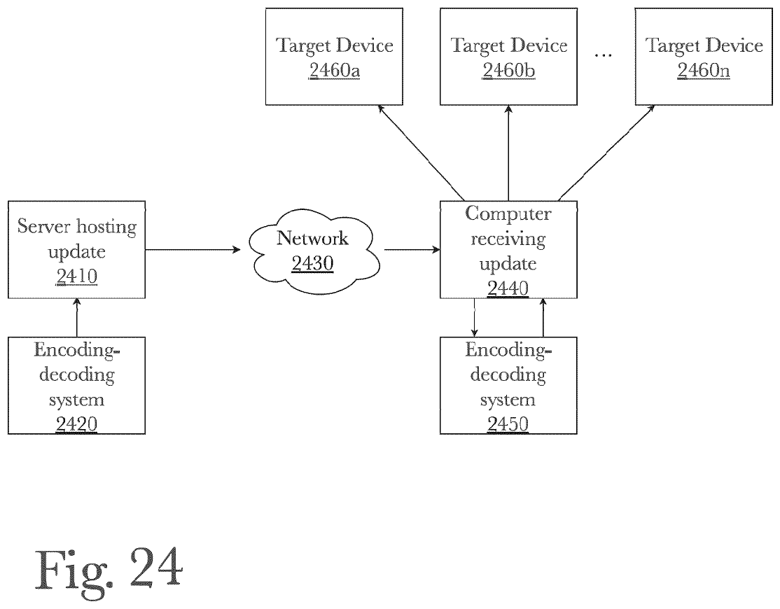

FIG. 24 is an exemplary system architecture of a data encoding system used for remote software and firmware updates. Software and firmware updates typically require smaller, but more frequent, file transfers. A server which hosts a software or firmware update 2410 may host an encoding-decoding system 2420, allowing for data to be encoded into, and decoded from, sourceblocks or codewords, as disclosed in previous figures. Such a server may possess a software update, operating system update, firmware update, device driver update, or any other form of software update, which in some cases may be minor changes to a file, but nevertheless necessitate sending the new, completed file to the recipient. Such a server is connected over a network 2430, which is further connected to a recipient computer 2440, which may be connected to a server 2410 for receiving such an update to its system. In this instance, the recipient device 2440 also hosts the encoding and decoding system 2450, along with a codebook or library of reference codes that the hosting server 2410 also shares. The updates are retrieved from storage at the hosting server 2410 in the form of codewords, transferred over the network 2430 in the form of codewords, and reconstructed on the receiving computer 2440. In this way, a far smaller file size, and smaller total update size, may be sent over a network. The receiving computer 2440 may then install the updates on any number of target computing devices 2460a-n, using a local network or other high-bandwidth connection.

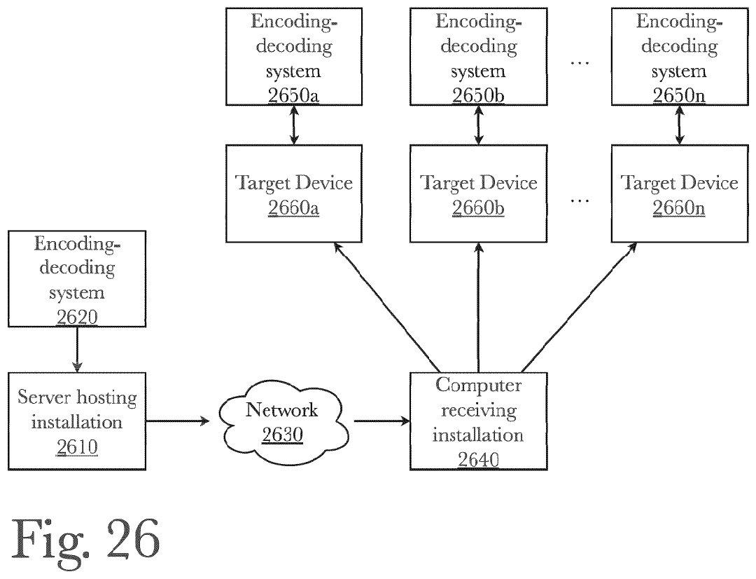

FIG. 26 is an exemplary system architecture of a data encoding system used for large-scale software installation such as operating systems. Large-scale software installations typically require very large, but infrequent, file transfers. A server which hosts an installable software 2610 may host an encoding-decoding system 2620, allowing for data to be encoded into, and decoded from, sourceblocks or codewords, as disclosed in previous figures. The files for the large scale software installation are hosted on the server 2610, which is connected over a network 2630 to a recipient computer 2640. In this instance, the encoding and decoding system 2650a-n is stored on or connected to one or more target devices 2660a-n, along with a codebook or library of reference codes that the hosting server 2610 shares. The software is retrieved from storage at the hosting server 2610 in the form of codewords, and transferred over the network 2630 in the form of codewords to the receiving computer 2640. However, instead of being reconstructed at the receiving computer 2640, the codewords are transmitted to one or more target computing devices, and reconstructed and installed directly on the target devices 2660a-n. In this way, a far smaller file size, and smaller total update size, may be sent over a network or transferred between computing devices, even where the network 2630 between the receiving computer 2640 and target devices 2660a-n is low bandwidth, or where there are many target devices 2660a-n.

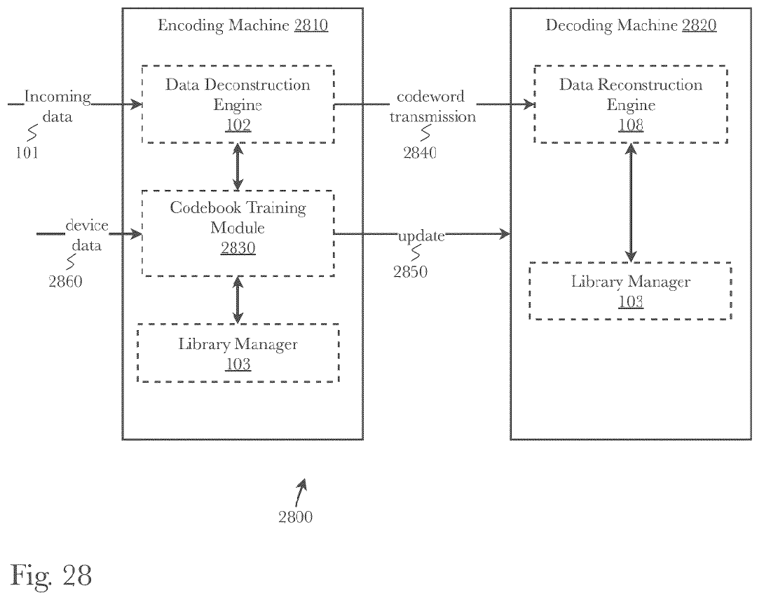

FIG. 28 is a block diagram of an exemplary system architecture 2800 of a codebook training system for a data encoding system, according to an embodiment. According to this embodiment, two separate machines may be used for encoding 2810 and decoding 2820. Much like in FIG. 1, incoming data 101 to be deconstructed is sent to a data deconstruction engine 102 residing on encoding machine 2810, which may attempt to deconstruct the data and turn it into a collection of codewords using a library manager 103. Codewords may be transmitted 2840 to a data reconstruction engine 108 residing on decoding machine 2820, which may reconstruct the original data from the codewords, using a library manager 103. However, according to this embodiment, a codebook training module 2830 is present on the decoding machine 2810, communicating in-between a library manager 103 and a deconstruction engine 102. According to other embodiments, codebook training module 2830 may reside instead on decoding machine 2820 if the machine has enough computing resources available; which machine the module 2830 is located on may depend on the system user's architecture and network structure. Codebook training module 2830 may send requests for data to the data reconstruction engine 2810, which routes incoming data 101 to codebook training module 2830. Codebook training module 2830 may perform analyses on the requested data in order to gather information about the distribution of incoming data 101 as well as monitor the encoding/decoding model performance. Additionally, codebook training module 2830 may also request and receive device data 2860 to supervise network connected devices and their processes and, according to some embodiments, to allocate training resources when requested by devices running the encoding system. Devices may include, but are not limited to, encoding and decoding machines, training machines, sensors, mobile computing devices, and Internet-of-things (“IoT”) devices. Based on the results of the analyses, the codebook training module 2830 may create a new training dataset from a subset of the requested data in order to counteract the effects of data drift on the encoding/decoding models, and then publish updated 2850 codebooks to both the encoding machine 2810 and decoding machine 2820.

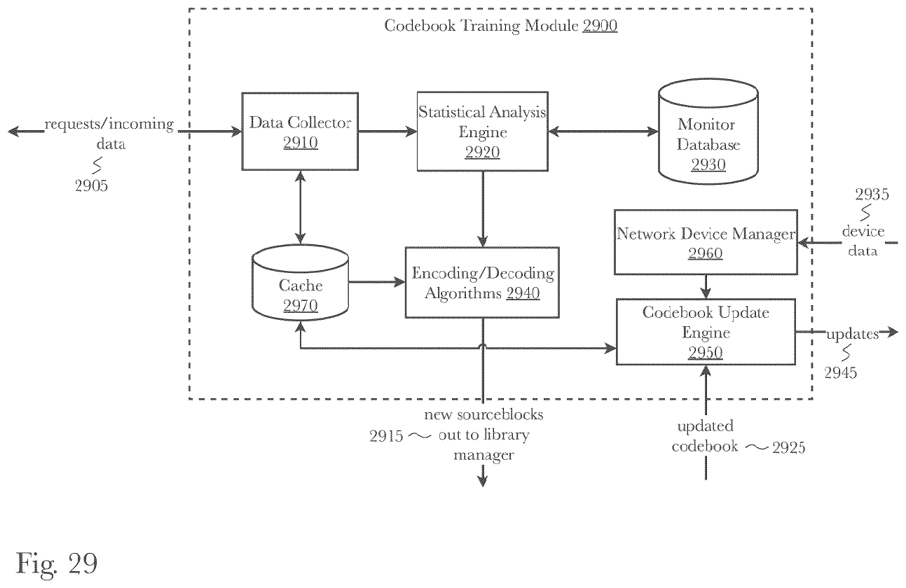

FIG. 29 is a block diagram of an exemplary architecture for a codebook training module 2900, according to an embodiment. According to the embodiment, a data collector 2910 is present which may send requests for incoming data 2905 to a data deconstruction engine 102 which may receive the request and route incoming data to codebook training module 2900 where it may be received by data collector 2910. Data collector 2910 may be configured to request data periodically such as at schedule time intervals, or for example, it may be configured to request data after a certain amount of data has been processed through the encoding machine 2810 or decoding machine 2820. The received data may be a plurality of sourceblocks, which are a series of binary digits, originating from a source packet otherwise referred to as a datagram. The received data may be compiled into a test dataset and temporarily stored in a cache 2970. Once stored, the test dataset may be forwarded to a statistical analysis engine 2920 which may utilize one or more algorithms to determine the probability distribution of the test dataset. Best-practice probability distribution algorithms such as Kullback-Leibler divergence, adaptive windowing, and Jensen-Shannon divergence may be used to compute the probability distribution of training and test datasets. A monitoring database 2930 may be used to store a variety of statistical data related to training datasets and model performance metrics in one place to facilitate quick and accurate system monitoring capabilities as well as assist in system debugging functions. For example, the original or current training dataset and the calculated probability distribution of this training dataset used to develop the current encoding and decoding algorithms may be stored in monitor database 2930.

Since data drifts involve statistical change in the data, the best approach to detect drift is by monitoring the incoming data's statistical properties, the model's predictions, and their correlation with other factors. After statistical analysis engine 2920 calculates the probability distribution of the test dataset it may retrieve from monitor database 2930 the calculated and stored probability distribution of the current training dataset. It may then compare the two probability distributions of the two different datasets in order to verify if the difference in calculated distributions exceeds a predetermined difference threshold. If the difference in distributions does not exceed the difference threshold, that indicates the test dataset, and therefore the incoming data, has not experienced enough data drift to cause the encoding/decoding system performance to degrade significantly, which indicates that no updates are necessary to the existing codebooks. However, if the difference threshold has been surpassed, then the data drift is significant enough to cause the encoding/decoding system performance to degrade to the point where the existing models and accompanying codebooks need to be updated. According to an embodiment, an alert may be generated by statistical analysis engine 2920 if the difference threshold is surpassed or if otherwise unexpected behavior arises.

In the event that an update is required, the test dataset stored in the cache 2970 and its associated calculated probability distribution may be sent to monitor database 2930 for long term storage. This test dataset may be used as a new training dataset to retrain the encoding and decoding algorithms 2940 used to create new sourceblocks based upon the changed probability distribution. The new sourceblocks may be sent out to a library manager 2915 where the sourceblocks can be assigned new codewords. Each new sourceblock and its associated codeword may then be added to a new codebook and stored in a storage device. The new and updated codebook may then be sent back 2925 to codebook training module 2900 and received by a codebook update engine 2950. Codebook update engine 2950 may temporarily store the received updated codebook in the cache 2970 until other network devices and machines are ready, at which point codebook update engine 2950 will publish the updated codebooks 2945 to the necessary network devices.

A network device manager 2960 may also be present which may request and receive network device data 2935 from a plurality of network connected devices and machines. When the disclosed encoding system and codebook training system 2800 are deployed in a production environment, upstream process changes may lead to data drift, or other unexpected behavior. For example, a sensor being replaced that changes the units of measurement from inches to centimeters, data quality issues such as a broken sensor always reading 0, and covariate shift which occurs when there is a change in the distribution of input variables from the training set. These sorts of behavior and issues may be determined from the received device data 2935 in order to identify potential causes of system error that is not related to data drift and therefore does not require an updated codebook. This can save network resources from being unnecessarily used on training new algorithms as well as alert system users to malfunctions and unexpected behavior devices connected to their networks. Network device manager 2960 may also utilize device data 2935 to determine available network resources and device downtime or periods of time when device usage is at its lowest. Codebook update engine 2950 may request network and device availability data from network device manager 2960 in order to determine the most optimal time to transmit updated codebooks (i.e., trained libraries) to encoder and decoder devices and machines.

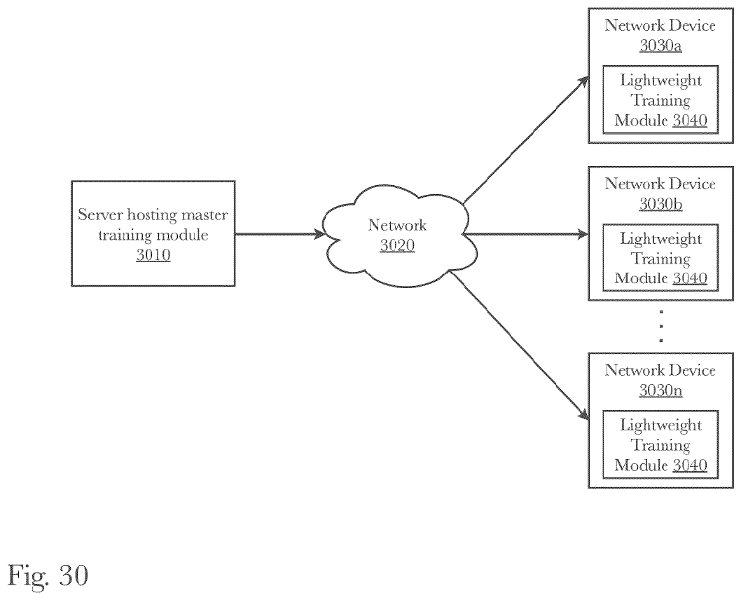

FIG. 30 is a block diagram of another embodiment of the codebook training system using a distributed architecture and a modified training module. According to an embodiment, there may be a server which maintains a master supervisory process over remote training devices hosting a master training module 3010 which communicates via a network 3020 to a plurality of connected network devices 3030a-n. The server may be located at the remote training end such as, but not limited to, cloud-based resources, a user-owned data center, etc. The master training module located on the server operates similarly to the codebook training module disclosed in FIG. 29 above, however, the server 3010 utilizes the master training module via the network device manager 2960 to farm out training resources to network devices 3030a-n. The server 3010 may allocate resources in a variety of ways, for example, round-robin, priority-based, or other manner, depending on the user needs, costs, and number of devices running the encoding/decoding system. Server 3010 may identify elastic resources which can be employed if available to scale up training when the load becomes too burdensome. On the network devices 3030a-n may be present a lightweight version of the training module 3040 that trades a little suboptimality in the codebook for training on limited machinery and/or makes training happen in low-priority threads to take advantage of idle time. In this way the training of new encoding/decoding algorithms may take place in a distributed manner which allows data gathering or generating devices to process and train on data gathered locally, which may improve system latency and optimize available network resources.

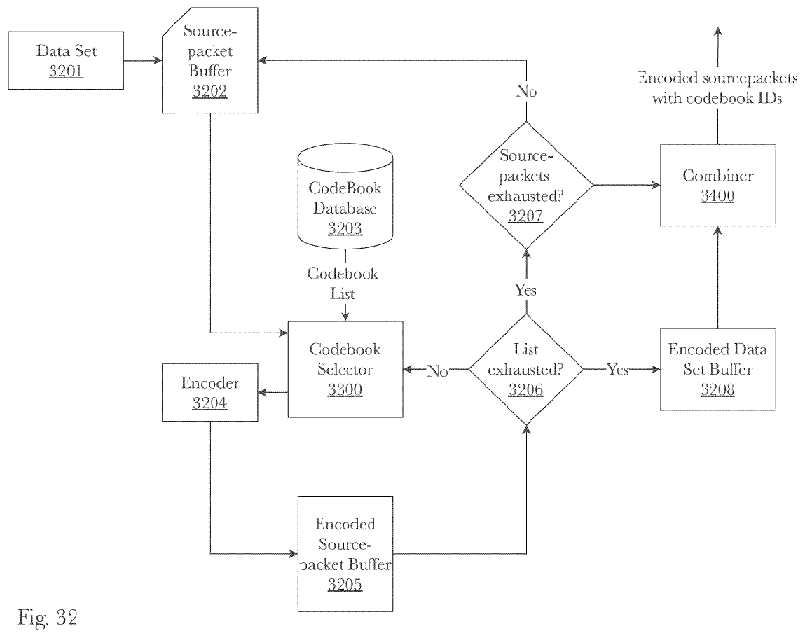

FIG. 32 is an exemplary system architecture for an encoding system with multiple codebooks. A data set to be encoded 3201 is sent to a sourcepacket buffer 3202. The sourcepacket buffer is an array which stores the data which is to be encoded and may contain a plurality of sourcepackets. Each sourcepacket is routed to a codebook selector 3300, which retrieves a list of codebooks from a codebook database 3203. The sourcepacket is encoded using the first codebook on the list via an encoder 3204, and the output is stored in an encoded sourcepacket buffer 3205. The process is repeated with the same sourcepacket using each subsequent codebook on the list until the list of codebooks is exhausted 3206, at which point the most compact encoded version of the sourcepacket is selected from the encoded sourcepacket buffer 3205 and sent to an encoded data set buffer 3208 along with the ID of the codebook used to produce it. The sourcepacket buffer 3202 is determined to be exhausted 3207, a notification is sent to a combiner 3400, which retrieves all of the encoded sourcepackets and codebook IDs from the encoded data set buffer 3208, and combines them into a single file for output.

According to an embodiment, the list of codebooks used in encoding the data set may be consolidated to a single codebook which is provided to the combiner 3400 for output along with the encoded sourcepackets and codebook IDs. In this case, the single codebook will contain the data from, and codebook IDs of, each of the codebooks used to encode the data set. This may provide a reduction in data transfer time, although it is not required since each sourcepacket (or sourceblock) will contain a reference to a specific codebook ID which references a codebook that can be pulled from a database or be sent alongside the encoded data to a receiving device for the decoding process.

In some embodiments, each sourcepacket of a data set 3201 arriving at the encoder 3204 is encoded using a different sourceblock length. Changing the sourceblock length changes the encoding output of a given codebook. Two sourcepackets encoded with the same codebook but using different sourceblock lengths would produce different encoded outputs. Therefore, changing the sourceblock length of some or all sourcepackets in a data set 3201 provides additional security. Even if the codebook was known, the sourceblock length would have to be known or derived for each sourceblock in order to decode the data set 3201. Changing the sourceblock length may be used in conjunction with the use of multiple codebooks.

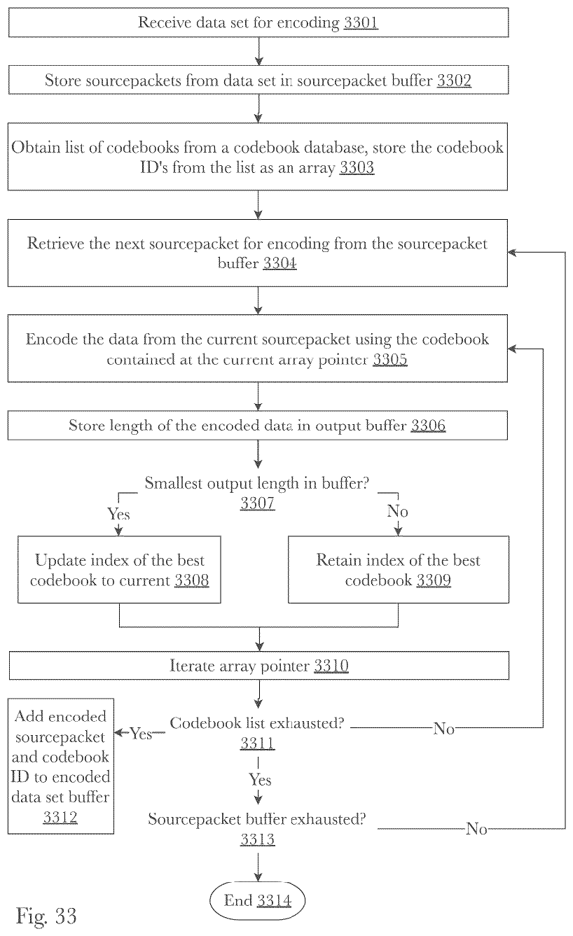

FIG. 33 is a flow diagram describing an exemplary algorithm for encoding of data using multiple codebooks. A data set is received for encoding 3301, the data set comprising a plurality of sourcepackets. The sourcepackets are stored in a sourcepacket buffer 3302. A list of codebooks to be used for multiple codebook encoding is retrieved from a codebook database (which may contain more codebooks than are contained in the list) and the codebook IDs for each codebook on the list are stored as an array 3303. The next sourcepacket in the sourcepacket buffer is retrieved from the sourcepacket buffer for encoding 3304. The sourcepacket is encoded using the codebook in the array indicated by a current array pointer 3305. The encoded sourcepacket and length of the encoded sourcepacket is stored in an encoded sourcepacket buffer 3306. If the length of the most recently stored sourcepacket is the shortest in the buffer 3607, an index in the buffer is updated to indicate that the codebook indicated by the current array pointer is the most efficient codebook in the buffer for that sourcepacket. If the length of the most recently stored sourcepacket is not the shortest in the buffer 3607, the index in the buffer is not updated because a previous codebook used to encode that sourcepacket was more efficient 3309. The current array pointer is iterated to select the next codebook in the list 3310. If the list of codebooks has not been exhausted 3311, the process is repeated for the next codebook in the list, starting at step 3305. If the list of codebooks has been exhausted 3311, the encoded sourcepacket in the encoded sourcepacket buffer (the most compact version) and the codebook ID for the codebook that encoded it are added to an encoded data set buffer 3312 for later combination with other encoded sourcepackets from the same data set. At that point, the sourcepacket buffer is checked to see if any sourcepackets remain to be encoded 3313. If the sourcepacket buffer is not exhausted, the next sourcepacket is retrieved 3304 and the process is repeated starting at step 3304. If the sourcepacket buffer is exhausted 3313, the encoding process ends 3314. In some embodiments, rather than storing the encoded sourcepacket itself in the encoded sourcepacket buffer, a universal unique identification (UUID) is assigned to each encoded sourcepacket, and the UUID is stored in the encoded sourcepacket buffer instead of the entire encoded sourcepacket.

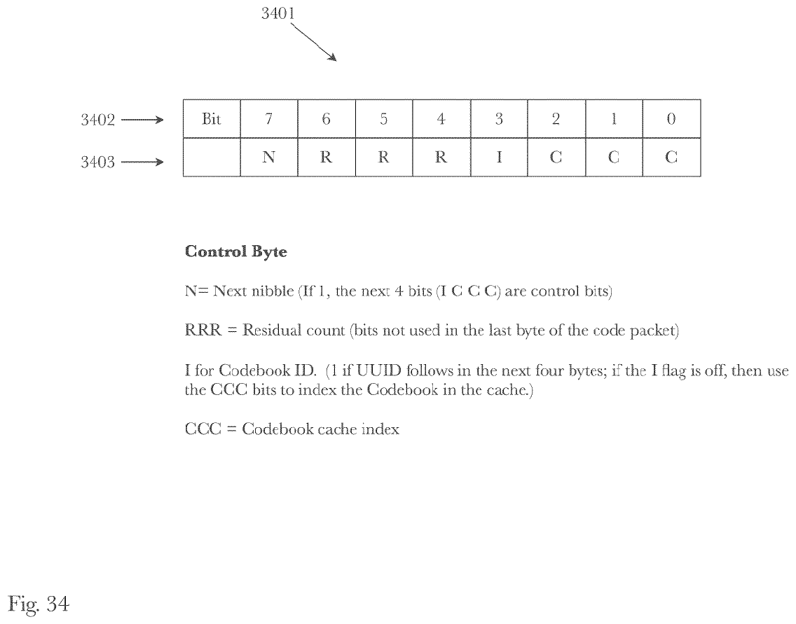

FIG. 34 is a diagram showing an exemplary control byte used to combine sourcepackets encoded with multiple codebooks. In this embodiment, a control byte 3401 (i.e., a series of 8 bits) is inserted at the before (or after, depending on the configuration) the encoded sourcepacket with which it is associated, and provides information about the codebook that was used to encode the sourcepacket. In this way, sourcepackets of a data set encoded using multiple codebooks can be combined into a data structure comprising the encoded sourcepackets, each with a control byte that tells the system how the sourcepacket can be decoded. The data structure may be of numerous forms, but in an embodiment, the data structure comprises a continuous series of control bytes followed by the sourcepacket associated with the control byte. In some embodiments, the data structure will comprise a continuous series of control bytes followed by the UUID of the sourcepacket associated with the control byte (and not the encoded sourcepacket, itself). In some embodiments, the data structure may further comprise a UUID inserted to identify the codebook used to encode the sourcepacket, rather than identifying the codebook in the control byte. Note that, while a very short control code (one byte) is used in this example, the control code may be of any length, and may be considerably longer than one byte in cases where the sourceblocks size is large or in cases where a large number of codebooks have been used to encode the sourcepacket or data set.

In this embodiment, for each bit location 3402 of the control byte 3401, a data bit or combinations of data bits 3403 provide information necessary for decoding of the sourcepacket associated with the control byte. Reading in reverse order of bit locations, the first bit N (location 7) indicates whether the entire control byte is used or not. If a single codebook is used to encode all sourcepackets in the data set, N is set to 0, and bits 3 to 0 of the control byte 3401 are ignored. However, where multiple codebooks are used, N is set to 1 and all 8 bits of the control byte 3401 are used. The next three bits RRR (locations 6 to 4) are a residual count of the number of bits that were not used in the last byte of the sourcepacket. Unused bits in the last byte of a sourcepacket can occur depending on the sourceblock size used to encode the sourcepacket. The next bit I (location 3) is used to identify the codebook used to encode the sourcepacket. If bit I is 0, the next three bits CCC (locations 2 to 0) provide the codebook ID used to encode the sourcepacket. The codebook ID may take the form of a codebook cache index, where the codebooks are stored in an enumerated cache. If bit I is 1, then the codebook is identified using a four-byte UUID that follows the control byte.

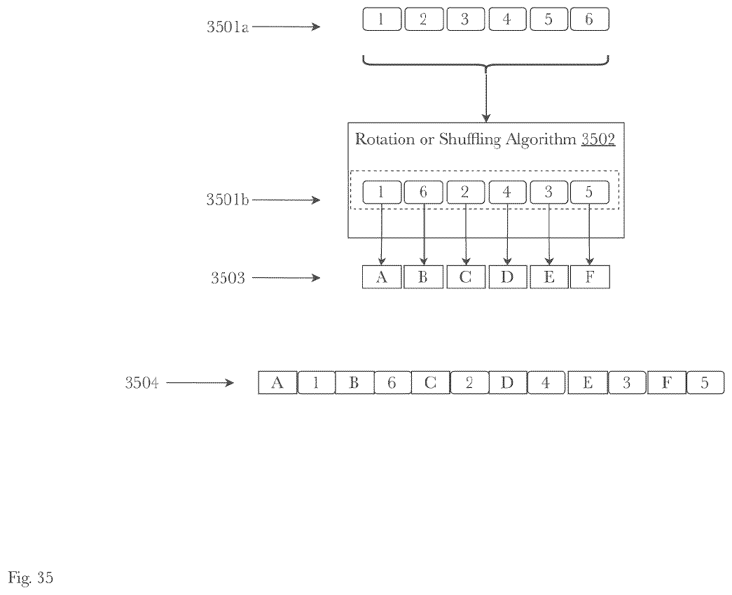

FIG. 35 is a diagram showing an exemplary codebook shuffling method. In this embodiment, rather than selecting codebooks for encoding based on their compaction efficiency, codebooks are selected either based on a rotating list or based on a shuffling algorithm. The methodology of this embodiment provides additional security to compacted data, as the data cannot be decoded without knowing the precise sequence of codebooks used to encode any given sourcepacket or data set.

Here, a list of six codebooks is selected for shuffling, each identified by a number from 1 to 6 3501a. The list of codebooks is sent to a rotation or shuffling algorithm 3502, and reorganized according to the algorithm 3501b. The first six of a series of sourcepackets, each identified by a letter from A to E, 3503 is each encoded by one of the algorithms, in this case A is encoded by codebook 1, B is encoded by codebook 6, C is encoded by codebook 2, D is encoded by codebook 4, E is encoded by codebook 13 A is encoded by codebook 5. The encoded sourcepackets 3503 and their associated codebook identifiers 3501b are combined into a data structure 3504 in which each encoded sourcepacket is followed by the identifier of the codebook used to encode that particular sourcepacket.

According to an embodiment, the codebook rotation or shuffling algorithm 3502 may produce a random or pseudo-random selection of codebooks based on a function. Some non-limiting functions that may be used for shuffling include: 1. given a function f(n) which returns a codebook according to an input parameter n in the range 1 to N are, and given t the number of the current sourcepacket or sourceblock: f(t*M modulo p), where M is an arbitrary multiplying factor (1<=M<=p−1) which acts as a key, and p is a large prime number less than or equal to N; 2. f(A\hat{ }t modulo p), where A is a base relatively prime to p−1 which acts as a key, and p is a large prime number less than or equal to N; 3. f(floor(t*x)modulo N), and x is an irrational number chosen randomly to act as a key; 4. f(t XOR K) where the XOR is performed bit-wise on the binary representations of t and a key K with same number of bits in its representation of N. The function f(n) may return the nth codebook simply by referencing the nth element in a list of codebooks, or it could return the nth codebook given by a formula chosen by a user.

In one embodiment, prior to transmission, the endpoints (users or devices) of a transmission agree in advance about the rotation list or shuffling function to be used, along with any necessary input parameters such as a list order, function code, cryptographic key, or other indicator, depending on the requirements of the type of list or function being used. Once the rotation list or shuffling function is agreed, the endpoints can encode and decode transmissions from one another using the encodings set forth in the current codebook in the rotation or shuffle plus any necessary input parameters.

In some embodiments, the shuffling function may be restricted to permutations within a set of codewords of a given length.

Note that the rotation or shuffling algorithm is not limited to cycling through codebooks in a defined order. In some embodiments, the order may change in each round of encoding. In some embodiments, there may be no restrictions on repetition of the use of codebooks.

In some embodiments, codebooks may be chosen based on some combination of compaction performance and rotation or shuffling. For example, codebook shuffling may be repeatedly applied to each sourcepacket until a codebook is found that meets a minimum level of compaction for that sourcepacket. Thus, codebooks are chosen randomly or pseudo-randomly for each sourcepacket, but only those that produce encodings of the sourcepacket better than a threshold will be used.

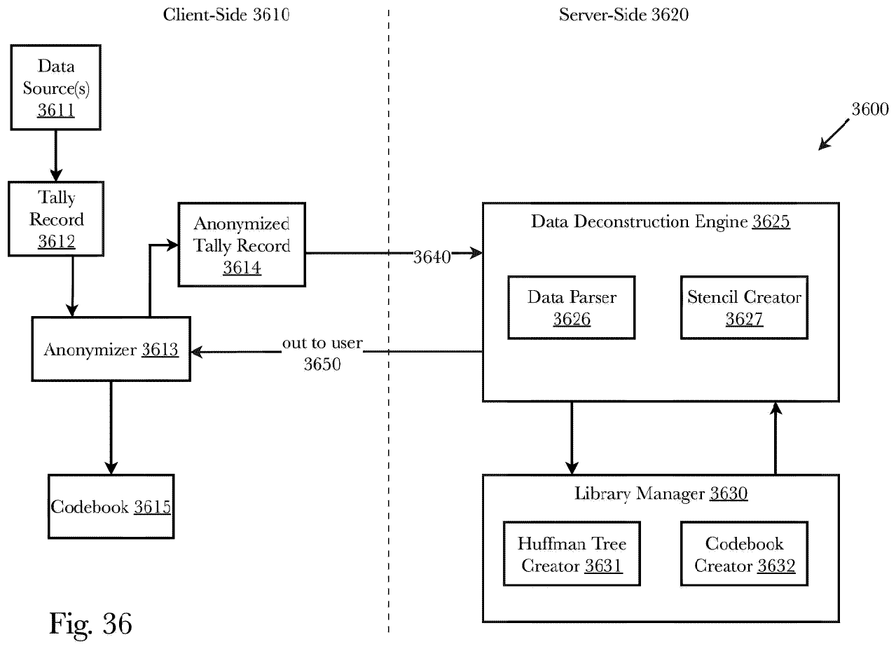

FIG. 36 is a block diagram illustrating an exemplary system architecture 3600 for compacting and encrypting anonymized data, according to an embodiment. According to some embodiments, the system 3600 may be configured in a client-server representation to facilitate and maintain data integrity and privacy by dividing the executable into two pieces: (1) tallies/counts, anonymization and deanonymization, all carried out on the client-side 3610 by the system 3600 user and/or data owner, and (2) codebook construction and optimization which is carried out on the server-side 3620 by system 3600.

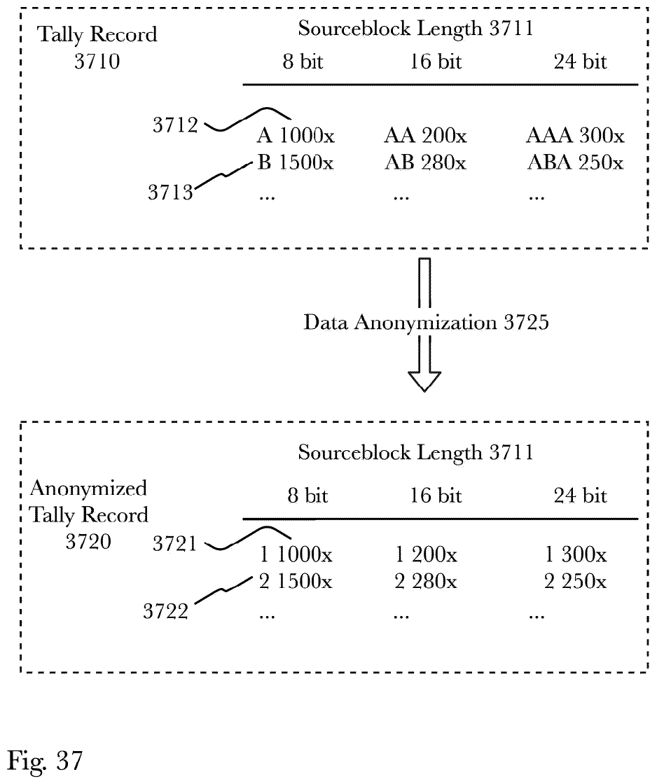

On the client-side 3610 a system 3600 user (or data owner or user, all terms can be understood to represent the same entity and are used interchangeably throughout this disclosure) may have one or more data sources 3611 which may or may not contain information that the user wants to keep private while also taking advantage of the compaction and encryption capabilities of system 3600. The user needs to prepare their data source(s) 3611 prior to sending the data to the server-side 3620. The first data preparation step that the user needs to complete is to collect the substring (i.e., sourceblock) counts of all reasonable lengths. For example, for a given data source the user may choose to divide the data source 3611 into a plurality of sourceblocks of length 8-bits and then count and log each occurrence of each sourceblock until all sourceblocks have been accounted for. Continuing this example, the user may choose to divide the data source 3611 again into a plurality of sourceblocks of length 16-bits and then count and log each occurrence of each sourceblock until all sourceblocks have been accounted for. The user may repeat this process for a given data source(s) 3611 any number of times, using different sourceblock lengths each time. The result of this process is a tally record 3612 which comprises the following information: the sourceblock lengths used to divide the data source; for each data sourceblock length the list of the plurality of sourceblocks, and for each sourceblock a tally of the number of times the sourceblock was counted in the data source 3611. The next step the user needs to perform in order to prepare their data from processing by system 3600 on the server-side 3620 is to anonymize the tally record using an anonymizer 3613. Anonymizer may be configured to both anonymize and deanonymize data according to a data anonymization mechanism selected by the data owner on the client-side 3610. Data anonymization of the tally record 3612 results in an anonymized tally record 3614. The anonymized tally record 3614 may comprise the same information as the tally record 3612 with the only difference being that the sourceblocks are replaced tokens that represent the actual sourceblock data. The anonymized tally record 3614 is fully prepared for data compaction and encryption and may be sent 3640 to a data deconstruction engine 3625 for processing. FIG. 37 shows an exemplary tally record and anonymized tally record, according to an embodiment.

According to some embodiments, on the server-side anonymized data compaction system 3600 may be configured to receive one or more anonymized data sets in the form of an anonymized tally record 3614, the anonymized tally record 3614 may comprise information including, but not limited to, the sourceblock lengths chosen to divide the data source 3611, for each sourceblock length a plurality of tokens (i.e., anonymized data sourceblocks), and for each token a tally (e.g., count or some other indication) of the number of times the data sourceblock represented by the token occurs in the data source 3611. System 3600 may comprise a data deconstruction engine 3625 comprising a record parser 3626 and a stencil creator 3627, and a library manager 3630 comprising a codebook creator 3632 and Huffman tree creator 3631. Data deconstruction engine 3625 may be configured to receive and parse an anonymized tally record 3614 using a data parser 3626 which scans through the received anonymized tally record 3614 in order to identify the token that occurs the most often (i.e., which token has the highest associated tally). According to some embodiments, data parser 3626 may begin parsing the anonymized tally record 3614 starting with the tokens representing the smallest sourceblock length, and once all the tokens for that sourceblock length have been parsed and sent to library manager 3630 the data parser 3626 moves onto the next sourceblock length set of tokens. The identified token may be sent to library manager 3630 for codeword assignment. Data parser 3626 can continue to iterate through the anonymized tally record 3614 to identify the token that has the next highest tally value and send that token to library manager 3630; this process may repeat until each token in the tally record has been parsed and sent to library manager 3630. If two or more tokens have the same tally value, then data parser 3626 may be configured to send the first of the two or more tokens that is identified to library manager 3630.

The token with the highest tally value and all subsequent tokens are sent to library manager 3630 where a Huffman tree creator 3631 may create a first Huffman binary tree based on the tally (occurrences) of each token in the tally record, wherein the topmost binary tree node represents the token with the highest tally value, and a Huffman reference codeword is assigned to each token in the tally record according to the first Huffman binary tree. This process of parsing tokens, Huffman tree creation, and codeword generation is performed for each set of tokens representing different sourceblock lengths. In this way, each sourceblock length set of tokens has its own Huffman tree and corresponding set of reference codes. Codebook creator 3632 may use the codewords created by the Huffman binary tree to create a half-backed codebook comprising a plurality of tokens and for each token a unique codeword. This codebook is referred to as half-backed because it only contains half of the relevant information (the codewords) necessary to encrypt, store, transmit, and decrypt the data source 3611 in compacted form. The missing half of information is the sourceblock associated with each of the codewords, which are represented as tokens in the half-backed codebook. Codebook creator 3632 may also leverage machine learning to optimize the construction of the half-backed codebook, ensuring that the data compaction is the most optimal. For example, codebook creator may use machine learning or some other computational mechanism (e.g., calculating compaction ratio) to identify which sourceblock length resulted in the most optimal compaction after Huffman binary tree creation and codeword assignment, and then select this sourceblock length and its associated tokens/codewords to create a half-backed codebook. According to some embodiments, codebook creator 3632 may be further configured to create a combined half-backed codebook comprising tokens from two or more data sources 3611. A combined half-backed codebook may be comprised of sourceblocks from one data source at one sourceblock length, and sourceblocks from another data source at a different sourceblock length. For example, a first data source may result in optimal compaction using sourceblock lengths of 8-bits, whereas a second data source may result in optimal compaction using sourceblock lengths of 16-bits, and these two data sources may be combined into a half-backed codebook despite not using uniform sourceblock lengths between the two data sources. Once a half-backed codebook has been created it may be sent 3650 back to data owner on the client-side 3610 who can perform deanonymization on the tokens contained in the half-backed codebook, replacing each token with its data sourceblock equivalent. This results in the data owner having in their possession a codebook 3615 comprising a plurality of data sourceblocks and for each sourceblock a unique codeword representing the sourceblock in compacted and encrypted form.

According to some embodiments, a stencil creator 3627 may also be a component of system 3600. Stencil creator 3627 may be configured to create a stencil data structure for a half-backed codebook that contains tokens from two or more data sources. The stencil may contain information or mechanisms for extracting tokens and codewords belonging to one of the two or more data sources that are represented by the tokens contained in the combined half-backed codebook. The created stencil and the half-backed codebook may be transmitted to the data owner on the client-side 3610, wherein the data owner may use the stencil to extract the correct tokens from the combined half-backed codebook in order to create the deanonymized codebook 3615. According to some embodiments, stencil creator 3627 may be configured to create a hybrid stencil that may be used to generate a hybrid synthesized codebook comprising sourceblocks from multiple data sources and for each sourceblock a codeword. The hybrid stencil may be created such that each codeword appears only once in the hybrid synthesized codebook. The use of hybrid stencil allows system 3600 to synthesize codebooks by combining partial results from multiple datasets/data sources. On the client-side 3610 when the user receives a combined half-backed codebook and its stencils or a hybrid synthesized codebook and its hybrid stencil, the user may first deanonymize the received codebook and then use the stencil to extract the correct values into their own codebooks. This results in the formation of the same number of codebooks as the number of data sources 3611 which were used to create the combined half-backed codebook or hybrid synthesized codebook.

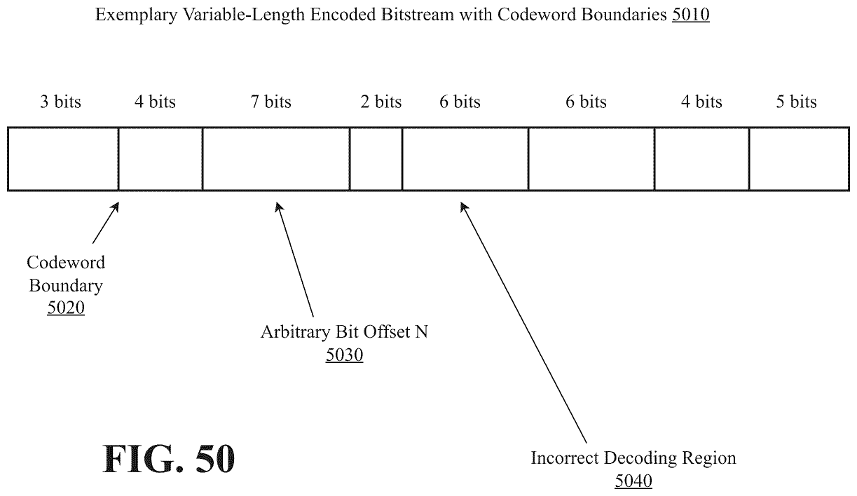

FIG. 50 illustrates a variable-length encoded bitstream and addresses one of the fundamental challenges in random access decoding of variable-length encoded data. Variable-length encoded bitstream 5010 represents a sequence of bits formed by concatenating codewords of varying bit lengths, where each codeword represents a symbol or sourceblock and is drawn from a prefix-free codebook. Huffman codes and their variants are representative examples of such encodings. In variable-length encoded bitstream 5010, individual codewords are shown with different lengths, including a 3-bit codeword, a 4-bit codeword, a 7-bit codeword, a 2-bit codeword, a 6-bit codeword, another 6-bit codeword, a 4-bit codeword, and a 5-bit codeword. This variation in codeword length is characteristic of Huffman coding and similar variable-length encoding schemes, where more frequent symbols are assigned shorter codewords to achieve compression efficiency.

Codeword boundary 5020 represents a bit position within variable-length encoded bitstream 5010 at which a valid codeword begins. Decoding initiated at codeword boundary 5020 and proceeding sequentially according to an associated codebook yields a correct and unique sequence of decoded symbols. Multiple codeword boundaries 5020 are shown along variable-length encoded bitstream 5010, with each boundary marking the start of a new codeword. These boundaries are critical for correct decoding because prefix-free codes guarantee that sequential decoding from a correct codeword boundary yields a unique and unambiguous decoding of the encoded bitstream.

Arbitrary bit offset N 5030 represents any bit position within variable-length encoded bitstream 5010 that is not known a priori to coincide with codeword boundary 5020. Decoding initiated at arbitrary bit offset N 5030 may initially produce incorrect decoded symbols. As shown, arbitrary bit offset N 5030 falls within a codeword rather than at codeword boundary 5020, which creates the fundamental problem addressed by this disclosure. When decoding begins at a bit position that is not a valid codeword boundary, the prefix-free property alone does not ensure that decoding will realign to a valid boundary. Instead, a decoder may interpret arbitrary bit sequences as valid codewords, producing an incorrect sequence of decoded symbols.

Incorrect decoding region 5040 illustrates the portion of variable-length encoded bitstream 5010 where naïve decoding from arbitrary bit offset N 5030 produces incorrect output. This region is shown with dashed boundaries to indicate that the decoding is not aligned with actual codeword boundaries 5020. In some cases, incorrect decoding may persist for long distances or indefinitely, depending on the structure of the codebook and the encoded data. Because a decoder cannot distinguish between correct and incorrect output without additional information when starting at arbitrary bit offset N 5030, there is no inherent mechanism for detecting when decoding has become correct in conventional variable-length decoding systems.

FIG. 50 demonstrates the non-self-synchronizing nature of prefix-free codes. Prefix-free codes, including Huffman codes and their variants, are constructed such that no valid codeword is a prefix of another valid codeword. This property guarantees that sequential decoding from a correct codeword boundary 5020 yields a unique and unambiguous decoding of the encoded bitstream. However, prefix-free codes are generally not self-synchronizing. The technical problem illustrated is that when decoding is initiated at arbitrary bit offset N 5030 within variable-length encoded bitstream 5010, the decoder lacks information about the correct alignment of codewords. As a result, naïve decoding from such an offset typically produces incorrect output within incorrect decoding region 5040.

The varying codeword lengths shown in variable-length encoded bitstream 5010 exemplify how variable-length encoding achieves compression by assigning shorter codes to more frequent symbols and longer codes to less frequent symbols. The 2-bit codeword represents the shortest encoding, while the 7-bit codeword represents the longest encoding shown. This distribution of codeword lengths is typical of Huffman encoding, where the maximum codeword length and the distribution of lengths affect both compression efficiency and the convergence properties relevant to random access decoding. Conventional approaches to enabling random access within encoded data streams include the insertion of explicit synchronization markers, periodic restart points, or fixed-length block encodings. However, such approaches introduce significant drawbacks, including increased storage overhead, reduced compression efficiency, and inflexibility in encoding formats.

The spatial relationship between codeword boundary 5020 and arbitrary bit offset N 5030 emphasizes that random access decoding must address the challenge of determining valid codeword boundaries when starting from an arbitrary position. The misalignment between arbitrary bit offset N 5030 and codeword boundary 5020 creates incorrect decoding region 5040, which must be overcome through the techniques disclosed in subsequent figures. The extent of incorrect decoding region 5040 depends on multiple factors, including the structure of the codebook, the statistical properties of the encoded data, and the specific misalignment between arbitrary bit offset N 5030 and the nearest valid codeword boundary 5020.

FIG. 50 establishes the need for systems and methods that enable random access decoding within variable-length encoded bitstream 5010 without modifying the encoded data, without inserting synchronization markers, and without sacrificing the efficiency benefits of variable-length encoding. The challenge illustrated by the relationship between arbitrary bit offset N 5030 and codeword boundary 5020 motivates the development of techniques that detect convergence to valid codeword boundaries through decoder behavior itself, thereby enabling correct random access decoding using existing encoding formats. By showing incorrect decoding region 5040 as a consequence of starting at arbitrary bit offset N 5030 rather than at codeword boundary 5020, the illustration demonstrates the fundamental technical problem that must be solved to enable efficient random access, search, and partial decoding operations over variable-length encoded data.

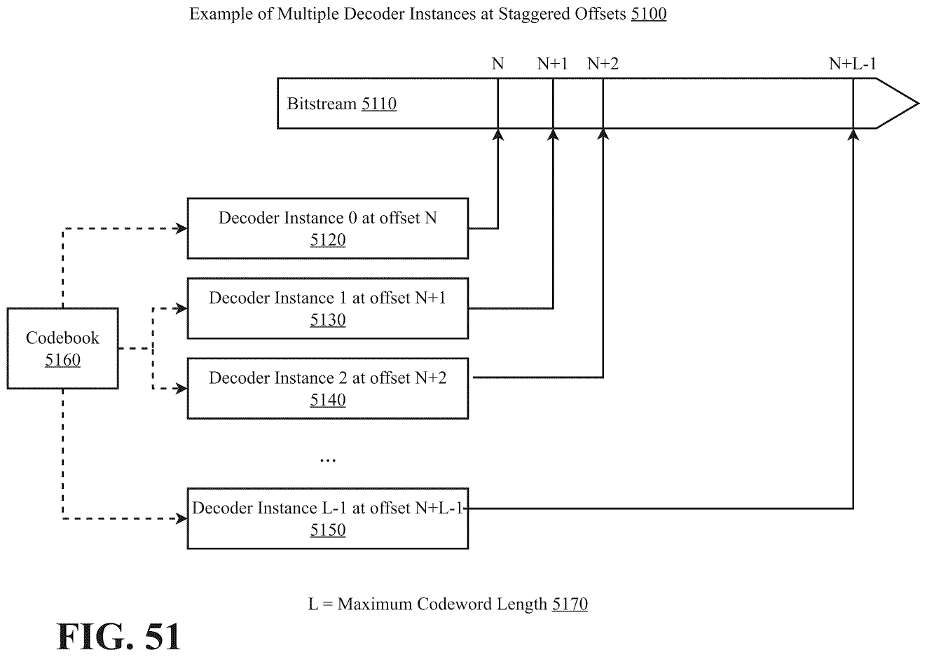

FIG. 51 illustrates the fundamental technique of multiple decoder initialization at staggered bit offsets, which forms the core mechanism for enabling random access decoding within variable-length encoded bitstreams. Bitstream 5110 represents a variable-length encoded bitstream, which is a sequence of bits formed by concatenating codewords of varying bit lengths. Each codeword in bitstream 5110 represents a symbol or sourceblock and is drawn from a prefix-free codebook. Huffman codes and their variants are representative examples of such encodings used in bitstream 5110. Random access decoding is performed by initializing a plurality of decoder instances at staggered bit offsets within bitstream 5110. This approach recognizes that when starting from an arbitrary bit offset, at least one of the staggered decoder instances will align with or quickly converge to a valid codeword boundary.

Decoder instance 0 at offset N 5120 represents the first decoder instance initialized at an arbitrary target offset N within bitstream 5110. Given an arbitrary target offset N, decoder instance 0 at offset N 5120 begins decoding from position N in bitstream 5110. Decoder instance 0 at offset N 5120 proceeds independently according to decoding rules and accesses codebook 5160 to interpret bit sequences as codewords. The arbitrary nature of offset N means that decoder instance 0 at offset N 5120 may not initially align with a valid codeword boundary and may produce incorrect decoded symbols until convergence occurs. Each decoder instance is a decoding process initialized at a specific bit offset within bitstream 5110 and configured to decode symbols according to a particular codebook.

Decoder instance 1 at offset N+1 5130 represents the second decoder instance initialized at offset N+1, which is one bit position after the starting position of decoder instance 0 at offset N 5120. Decoder instance 1 at offset N+1 5130 operates in parallel with decoder instance 0 at offset N 5120, independently decoding bitstream 5110 from its staggered starting position. By initiating decoding one bit position later than decoder instance 0 at offset N 5120, decoder instance 1 at offset N+1 5130 explores a different alignment possibility within bitstream 5110. This staggered approach ensures that all possible bit-level alignments within the maximum codeword length are represented by the collection of decoder instances.

Decoder instance 2 at offset N+2 5140 represents the third decoder instance initialized at offset N+2, continuing the pattern of staggered initialization. Decoder instance 2 at offset N+2 5140 begins decoding from a position two bits after the arbitrary target offset N. Like decoder instance 0 at offset N 5120 and decoder instance 1 at offset N+1 5130, decoder instance 2 at offset N+2 5140 proceeds independently according to the same decoding rules and codebook 5160. The sequential one-bit offset pattern continues through the entire set of decoder instances, ensuring comprehensive coverage of all possible starting alignments within the maximum codeword length. Multiple decoder instances may operate concurrently or in an interleaved manner, depending on the execution strategy employed by the system.

The ellipsis notation between decoder instance 2 at offset N+2 5140 and decoder instance L−1 at offset N+L−1 5150 indicates that additional decoder instances are initialized at consecutive bit offsets following the established pattern. These intermediate decoder instances, not explicitly shown to avoid visual clutter, continue the sequence at offsets N+3, N+4, and so forth, up to offset N+L−2. Each intermediate decoder instance operates according to the same principles as decoder instance 0 at offset N 5120, decoder instance 1 at offset N+1 5130, and decoder instance 2 at offset N+2 5140, independently decoding bitstream 5110 using codebook 5160. The complete set of decoder instances from offset N through offset N+L−1 ensures that every possible bit alignment within the maximum codeword length is explored simultaneously or in an organized manner.

Decoder instance L−1 at offset N+L−1 5150 represents the final decoder instance in the plurality of decoder instances, initialized at offset N+L−1 where L is maximum codeword length 5170. Decoder instance L−1 at offset N+L−1 5150 completes the coverage of all possible starting positions within one maximum codeword length from the arbitrary target offset N. By initializing decoder instances at all positions from N through N+L−1, the system guarantees that at least one decoder instance must begin at a valid codeword boundary or at a position that will rapidly converge to correct decoding. The index L−1 reflects zero-based counting of L total decoder instances, with decoder instance 0 at offset N 5120 being the first and decoder instance L−1 at offset N+L−1 5150 being the last.

Codebook 5160 represents the prefix-free codebook used by all decoder instances to interpret bit sequences in bitstream 5110 as codewords corresponding to symbols or sourceblocks. Codebook 5160 contains the mapping between binary codewords and their corresponding decoded symbols. All decoder instances, including decoder instance 0 at offset N 5120, decoder instance 1 at offset N+1 5130, decoder instance 2 at offset N+2 5140, and decoder instance L−1 at offset N+L−1 5150, access the same codebook 5160 to perform their decoding operations. Codebook 5160 may be a canonical Huffman codebook, a non-canonical Huffman codebook, or another type of prefix-free variable-length code. The structural properties of codebook 5160, particularly whether it is classified as a BAD codebook or a NOT BAD codebook, affect the convergence behavior of the decoder instances. Canonical Huffman codebooks with codeword lengths having a greatest common divisor of one are examples of NOT BAD codebooks that enable high-probability rapid convergence to valid codeword boundaries under random access decoding.

Maximum codeword length L 5170 represents the maximum number of bits required to represent any single codeword or compound codeword used by the decoder, including primary codewords and any secondary or hybrid encodings employed by the system. Maximum codeword length L 5170 determines the number of decoder instances that must be initialized to ensure complete coverage of all possible starting alignments. By initializing L decoder instances at consecutive bit offsets from N to N+L−1, the system guarantees that at least one decoder instance will start at a position that aligns with a valid codeword boundary in bitstream 5110. This is because any codeword boundary in bitstream 5110 can be at most L−1 bits away from the arbitrary starting offset N. Maximum codeword length L 5170 is a property of codebook 5160 and defines the window of bit positions that must be covered by the staggered decoder initialization strategy.

The connection between all decoder instances and codebook 5160 is shown with dashed lines, indicating that each decoder instance accesses codebook 5160 but does not modify it. This shared read-only access to codebook 5160 ensures that all decoder instances apply the same decoding rules, which is essential for the agreement-based boundary detection mechanism. When decoder instances begin producing identical decoded symbol sequences, this agreement indicates that they have all converged to the same valid codeword alignment, regardless of their different starting positions.

The arrangement of decoder instance 0 at offset N 5120, decoder instance 1 at offset N+1 5130, decoder instance 2 at offset N+2 5140, through decoder instance L−1 at offset N+L−1 5150 demonstrates the systematic coverage of all possible bit-level alignments within maximum codeword length L 5170. This comprehensive coverage is the key insight that enables marker-free random access decoding. Because all possible starting positions within one maximum codeword length are represented by decoder instances, at least one instance must be correctly aligned with a codeword boundary or will rapidly converge to correct decoding. The incorrect instances will produce divergent decoded outputs, while the correctly aligned instance or instances that have converged will produce consistent outputs that can be detected through agreement mechanisms.

FIG. 51 establishes that the number of decoder instances L is determined by maximum codeword length 5170 of codebook 5160, ensuring that the staggered initialization pattern spans exactly one maximum codeword length. This relationship between the number of decoder instances and maximum codeword length L 5170 is mathematically necessary and sufficient for the random access decoding technique. If fewer than L decoder instances were initialized, there would be gaps in coverage where a valid codeword boundary might not be represented. If more than L decoder instances were initialized, the additional instances would be redundant because they would duplicate the alignment possibilities already covered by the first L instances.

The multiple decoder initialization technique illustrated enables random access decoding without requiring modification of bitstream 5110, without inserting explicit synchronization markers, and without maintaining complex alignment indices. By launching decoder instance 0 at offset N 5120 through decoder instance L−1 at offset N+L−1 5150 at staggered positions, the system explores all possible alignments in parallel or in an organized sequential manner. Each decoder instance proceeds independently according to codebook 5160, and the decoded outputs from all instances are subsequently analyzed to detect agreement, which signals convergence to a valid codeword boundary. This approach transforms variable-length encoded data from a sequential-access format into one that supports efficient random access, search, and partial decoding, while preserving the efficiency and flexibility benefits of variable-length encoding and remaining compatible with existing encoding systems.

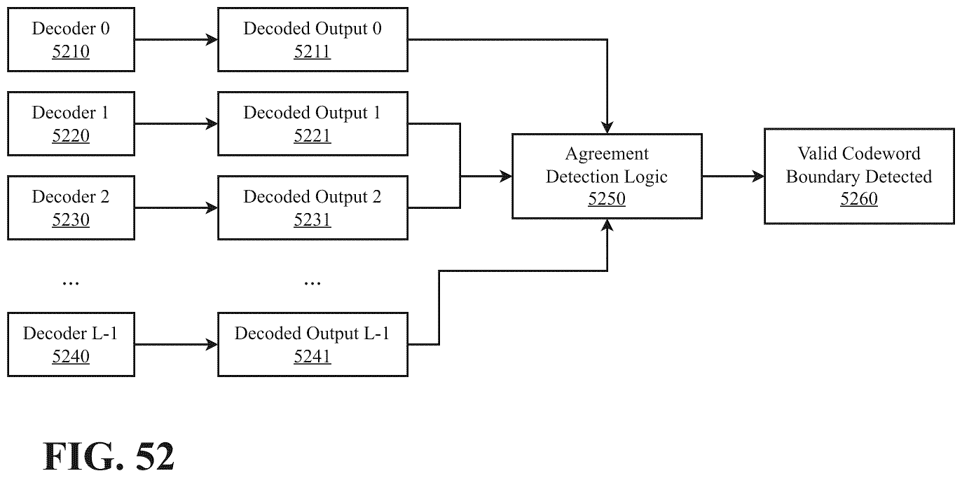

FIG. 52 illustrates parallel decoder execution and agreement-based boundary detection, which represents one embodiment of executing multiple decoder instances to achieve rapid convergence to valid codeword boundaries. Exemplary parallel execution 5205 indicates that all decoder instances are executed in parallel, allowing multiple decoders to advance independently and simultaneously through an encoded bitstream. In parallel decoder execution, each decoder instance advances independently through the encoded bitstream, decoding symbols according to an associated codebook. Parallel execution may be implemented using multiple processor cores, vectorized instructions, graphics processing units, or other forms of parallel hardware. Agreement among decoder instances may be evaluated continuously or at periodic checkpoints during exemplary parallel execution 5205. This parallel execution approach provides conceptual simplicity and minimizes convergence latency, at the cost of increased concurrent resource usage.

Decoder 0 5210 represents the first decoder instance in a plurality of decoder instances initialized at staggered bit offsets. Decoder 0 5210 begins decoding from an arbitrary target offset N within a variable-length encoded bitstream. Decoder 0 5210 operates according to decoding rules specified by a codebook and produces decoded output 0 5211 as it advances through the bitstream. During exemplary parallel execution 5205, decoder 0 5210 proceeds independently of other decoder instances, without requiring communication or synchronization with peer decoders. Decoder 0 5210 interprets consecutive bit sequences from the bitstream as codewords according to the prefix-free property of the codebook, generating a sequence of decoded symbols that constitute decoded output 0 5211.

Decoder 1 5220 represents the second decoder instance initialized at a bit offset one position after the starting position of decoder 0 5210. Decoder 1 5220 operates in parallel with decoder 0 5210 during exemplary parallel execution 5205, independently decoding the bitstream from offset N+1 and producing decoded output 1 5221. Like decoder 0 5210, decoder 1 5220 applies the same codebook and decoding rules but starts from a different bit position. The parallel operation of decoder 1 5220 and decoder 0 5210 means that both decoders advance through the bitstream simultaneously, each producing their respective decoded outputs without waiting for the other to complete decoding operations.

Decoder 2 5230 represents the third decoder instance initialized at bit offset N+2, continuing the pattern of staggered parallel execution. Decoder 2 5230 operates concurrently with decoder 0 5210 and decoder 1 5220 during exemplary parallel execution 5205, producing decoded output 2 5231 as it decodes from its assigned starting position. The parallel nature of decoder 2 5230 allows it to advance through the bitstream at the same time as other decoder instances, with all decoders making progress simultaneously rather than sequentially. This concurrent execution pattern extends through all decoder instances in the plurality.

The ellipsis notation between decoder 2 5230 and decoder L−1 5240 indicates that additional decoder instances exist and operate in parallel during exemplary parallel execution 5205. These intermediate decoder instances follow the same pattern as decoder 0 5210, decoder 1 5220, and decoder 2 5230, each starting at consecutive bit offsets N+3, N+4, and so forth, each producing corresponding decoded outputs, and each executing concurrently with all other decoder instances. The complete set of decoder instances from decoder 0 5210 through decoder L−1 5240 operates simultaneously, exploring all possible bit-level alignments within the maximum codeword length in parallel.

Decoder L−1 5240 represents the final decoder instance in the plurality of decoder instances, initialized at bit offset N+L−1 where L is the maximum codeword length. Decoder L−1 5240 executes in parallel with all other decoder instances during exemplary parallel execution 5205, producing decoded output L−1 5241 as it decodes from the last offset position in the staggered initialization pattern. Decoder L−1 5240 completes the coverage of all possible starting alignments, ensuring that at least one decoder among decoder 0 5210 through decoder L−1 5240 must be correctly aligned or will rapidly converge to a valid codeword boundary.

Decoded output 0 5211 represents the sequence of decoded symbols produced by decoder 0 5210 as it advances through the variable-length encoded bitstream. Decoded output 0 5211 consists of symbols that decoder 0 5210 has interpreted from consecutive bit sequences according to the codebook. If decoder 0 5210 begins at a position that does not align with a valid codeword boundary, decoded output 0 5211 may initially contain incorrect symbols until convergence occurs. Decoded output 0 5211 is provided to agreement detection logic 5250 for comparison with other decoded outputs to determine when decoder instances have converged to the same codeword alignment.

Decoded output 1 5221 represents the sequence of decoded symbols produced by decoder 1 5220. Because decoder 1 5220 starts from a different bit offset than decoder 0 5210, decoded output 1 5221 may initially differ from decoded output 0 5211 if the two decoders are not yet aligned with the same codeword boundaries. As decoding proceeds during exemplary parallel execution 5205, decoded output 1 5221 is continuously or periodically compared with decoded output 0 5211 and other decoded outputs by agreement detection logic 5250. When decoded output 1 5221 begins producing identical symbol sequences as other decoded outputs, this indicates that decoder 1 5220 has converged to the correct codeword alignment.

Decoded output 2 5231 represents the sequence of decoded symbols produced by decoder 2 5230. Like decoded output 0 5211 and decoded output 1 5221, decoded output 2 5231 may initially contain incorrect symbols if decoder 2 5230 is not aligned with a valid codeword boundary. Decoded output 2 5231 contributes to the collection of decoded outputs that are analyzed by agreement detection logic 5250. The comparison of decoded output 2 5231 with decoded output 0 5211, decoded output 1 5221, and other decoded outputs enables detection of agreement patterns that signal convergence.

The ellipsis notation between decoded output 2 5231 and decoded output L−1 5241 indicates that additional decoded outputs exist corresponding to the intermediate decoder instances between decoder 2 5230 and decoder L−1 5240. Each intermediate decoded output is produced by its corresponding decoder instance and is provided to agreement detection logic 5250 for analysis. The complete set of decoded outputs from decoded output 0 5211 through decoded output L−1 5241 enables comprehensive agreement detection across all possible starting alignments within the maximum codeword length.

Decoded output L−1 5241 represents the sequence of decoded symbols produced by decoder L−1 5240, completing the set of decoded outputs from all decoder instances. Decoded output L−1 5241 is provided to agreement detection logic 5250 along with decoded output 0 5211 through all intermediate decoded outputs. When all decoded outputs including decoded output L−1 5241 produce identical symbol sequences over a defined region, this agreement confirms that all decoder instances have converged to the same valid codeword alignment, regardless of their different starting positions.

Agreement detection logic 5250 represents the component that monitors and compares decoded outputs from all decoder instances to identify when convergence to a valid codeword boundary has occurred. As decoding proceeds during exemplary parallel execution 5205, agreement detection logic 5250 receives decoded output 0 5211, decoded output 1 5221, decoded output 2 5231, through decoded output L−1 5241 and evaluates whether these outputs agree with each other. Agreement detection logic 5250 implements comparison mechanisms that identify when all decoder instances produce identical decoded symbol sequences over a defined portion of the bitstream. Agreement among decoder instances is used as an indicator that decoding has converged to a valid codeword boundary. The point at which agreement is achieved corresponds to a bit position that is guaranteed to be a valid codeword boundary, providing a correctness guarantee that does not rely on explicit synchronization markers or prior knowledge of codeword boundaries.

Agreement detection logic 5250 may evaluate agreement continuously as new decoded symbols are produced, or may perform periodic agreement checks at defined intervals. In some embodiments, agreement detection logic 5250 requires that agreement persists over a minimum number of decoded symbols or bits to reduce the likelihood of false positives. The specific agreement criteria implemented by agreement detection logic 5250 may be configured based on system requirements, codebook characteristics, or desired confidence levels. Because all possible starting alignments within a codeword-length window are represented by the decoder instances from decoder 0 5210 through decoder L−1 5240, agreement among all instances detected by agreement detection logic 5250 implies that decoding has converged to the unique correct alignment. When agreement detection logic 5250 determines that all decoded outputs agree, it signals valid codeword boundary detected 5260.

Valid codeword boundary detected 5260 represents the output signal or indication produced by agreement detection logic 5250 when convergence has been achieved. Valid codeword boundary detected 5260 indicates that a bit position has been identified that is guaranteed to be a valid codeword boundary, from which subsequent decoding will be correct. Once valid codeword boundary detected 5260 is signaled, decoder instances may be terminated, as the system has successfully recovered from the arbitrary starting offset and aligned with the actual codeword structure of the bitstream. Valid codeword boundary detected 5260 enables control logic to identify the precise bit position where correct decoding begins and to initiate subsequent decoding operations from that boundary. The detection of a valid codeword boundary through agreement among decoder instances provides a reliable mechanism for random access decoding without requiring modification of the encoded bitstream or insertion of synchronization markers.

FIG. 52 demonstrates how exemplary parallel execution 5205 of decoder 0 5210 through decoder L−1 5240 produces decoded output 0 5211 through decoded output L−1 5241, which are analyzed by agreement detection logic 5250 to generate valid codeword boundary detected 5260. This parallel execution embodiment minimizes convergence latency by allowing all decoder instances to advance simultaneously, though it requires sufficient parallel hardware resources to execute multiple decoders concurrently. The agreement-based detection mechanism provides a correctness guarantee that holds independently of the initial arbitrary bit offset and without modification to the encoded bitstream, enabling efficient random access decoding while preserving the compression efficiency benefits of variable-length encoding.

### Description of Method Aspects

Since the library consists of re-usable building sourceblocks, and the actual data is represented by reference codes to the library, the total storage space of a single set of data would be much smaller than conventional methods, wherein the data is stored in its entirety. The more data sets that are stored, the larger the library becomes, and the more data can be stored in reference code form.

As an analogy, imagine each data set as a collection of printed books that are only occasionally accessed. The amount of physical shelf space required to store many collections would be quite large, and is analogous to conventional methods of storing every single bit of data in every data set. Consider, however, storing all common elements within and across books in a single library, and storing the books as references codes to those common elements in that library. As a single book is added to the library, it will contain many repetitions of words and phrases. Instead of storing the whole words and phrases, they are added to a library, and given a reference code, and stored as reference codes. At this scale, some space savings may be achieved, but the reference codes will be on the order of the same size as the words themselves.

As more books are added to the library, larger phrases, quotations, and other words patterns will become common among the books. The larger the word patterns, the smaller the reference codes will be in relation to them as not all possible word patterns will be used. As entire collections of books are added to the library, sentences, paragraphs, pages, or even whole books will become repetitive. There may be many duplicates of books within a collection and across multiple collections, many references and quotations from one book to another, and much common phraseology within books on particular subjects. If each unique page of a book is stored only once in a common library and given a reference code, then a book of 1,000 pages or more could be stored on a few printed pages as a string of codes referencing the proper full-sized pages in the common library. The physical space taken up by the books would be dramatically reduced. The more collections that are added, the greater the likelihood that phrases, paragraphs, pages, or entire books will already be in the library, and the more information in each collection of books can be stored in reference form. Accessing entire collections of books is then limited not by physical shelf space, but by the ability to reprint and recycle the books as needed for use.

The projected increase in storage capacity using the method herein described is primarily dependent on two factors: 1) the ratio of the number of bits in a block to the number of bits in the reference code, and 2) the amount of repetition in data being stored by the system.

With respect to the first factor, the number of bits used in the reference codes to the sourceblocks must be smaller than the number of bits in the sourceblocks themselves in order for any additional data storage capacity to be obtained. As a simple example, 16-bit sourceblocks would require 216, or 65536, unique reference codes to represent all possible patterns of bits. If all possible 65536 blocks patterns are utilized, then the reference code itself would also need to contain sixteen bits in order to refer to all possible 65,536 blocks patterns. In such case, there would be no storage savings. However, if only 16 of those block patterns are utilized, the reference code can be reduced to 4 bits in size, representing an effective compression of 4 times (16 bits/4 bits=4) versus conventional storage. Using a typical block size of 512 bytes, or 4,096 bits, the number of possible block patterns is 24,096, which for all practical purposes is unlimited. A typical hard drive contains one terabyte (TB) of physical storage capacity, which represents 1,953,125,000, or roughly 231, 512 byte blocks. Assuming that 1 TB of unique 512-byte sourceblocks were contained in the library, and that the reference code would thus need to be 31 bits long, the effective compression ratio for stored data would be on the order of 132 times (4,096/31≈132) that of conventional storage.

With respect to the second factor, in most cases it could be assumed that there would be sufficient repetition within a data set such that, when the data set is broken down into sourceblocks, its size within the library would be smaller than the original data. However, it is conceivable that the initial copy of a data set could require somewhat more storage space than the data stored in a conventional manner, if all or nearly all sourceblocks in that set were unique. For example, assuming that the reference codes are 1/10th the size of a full-sized copy, the first copy stored as sourceblocks in the library would need to be 1.1 megabytes (MB), (1 MB for the complete set of full-sized sourceblocks in the library and 0.1 MB for the reference codes). However, since the sourceblocks stored in the library are universal, the more duplicate copies of something you save, the greater efficiency versus conventional storage methods. Conventionally, storing 10 copies of the same data requires 10 times the storage space of a single copy. For example, ten copies of a 1 MB file would take up 10 MB of storage space. However, using the method described herein, only a single full-sized copy is stored, and subsequent copies are stored as reference codes. Each additional copy takes up only a fraction of the space of the full-sized copy. For example, again assuming that the reference codes are 1/10th the size of the full-size copy, ten copies of a 1 MB file would take up only 2 MB of space (1 MB for the full-sized copy, and 0.1 MB each for ten sets of reference codes). The larger the library, the more likely that part or all of incoming data will duplicate sourceblocks already existing in the library.

The size of the library could be reduced in a manner similar to storage of data. Where sourceblocks differ from each other only by a certain number of bits, instead of storing a new sourceblock that is very similar to one already existing in the library, the new sourceblock could be represented as a reference code to the existing sourceblock, plus information about which bits in the new block differ from the existing block. For example, in the case where 512 byte sourceblocks are being used, if the system receives a new sourceblock that differs by only one bit from a sourceblock already existing in the library, instead of storing a new 512 byte sourceblock, the new sourceblock could be stored as a reference code to the existing sourceblock, plus a reference to the bit that differs. Storing the new sourceblock as a reference code plus changes would require only a few bytes of physical storage space versus the 512 bytes that a full sourceblock would require. The algorithm could be optimized to store new sourceblocks in this reference code plus changes form unless the changes portion is large enough that it is more efficient to store a new, full sourceblock.

It will be understood by one skilled in the art that transfer and synchronization of data would be increased to the same extent as for storage. By transferring or synchronizing reference codes instead of full-sized data, the bandwidth requirements for both types of operations are dramatically reduced.

In addition, the method described herein is inherently a form of encryption. When the data is converted from its full form to reference codes, none of the original data is contained in the reference codes. Without access to the library of sourceblocks, it would be impossible to reconstruct any portion of the data from the reference codes. This inherent property of the method described herein could obviate the need for traditional encryption algorithms, thereby offsetting most or all of the computational cost of conversion of data back and forth to reference codes. In theory, the method described herein should not utilize any additional computing power beyond traditional storage using encryption algorithms. Alternatively, the method described herein could be in addition to other encryption algorithms to increase data security even further.

In other embodiments, additional security features could be added, such as: creating a proprietary library of sourceblocks for proprietary networks, physical separation of the reference codes from the library of sourceblocks, storage of the library of sourceblocks on a removable device to enable easy physical separation of the library and reference codes from any network, and incorporation of proprietary sequences of how sourceblocks are read and the data reassembled.

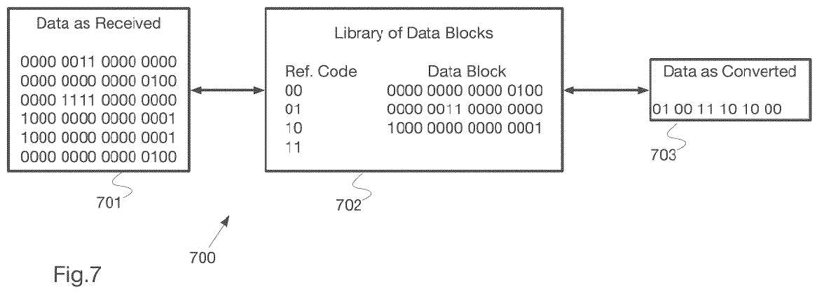

FIG. 7 is a diagram showing an example of how data might be converted into reference codes using an aspect of an embodiment 700. As data is received 701, it is read by the processor in sourceblocks of a size dynamically determined by the previously disclosed sourceblock size optimizer 410. In this example, each sourceblock is 16 bits in length, and the library 702 initially contains three sourceblocks with reference codes 00, 01, and 10. The entry for reference code 11 is initially empty. As each 16 bit sourceblock is received, it is compared with the library. If that sourceblock is already contained in the library, it is assigned the corresponding reference code. So, for example, as the first line of data (0000 0011 0000 0000) is received, it is assigned the reference code (01) associated with that sourceblock in the library. If that sourceblock is not already contained in the library, as is the case with the third line of data (0000 1111 0000 0000) received in the example, that sourceblock is added to the library and assigned a reference code, in this case 11. The data is thus converted 703 to a series of reference codes to sourceblocks in the library. The data is stored as a collection of codewords, each of which contains the reference code to a sourceblock and information about the location of the sourceblocks in the data set. Reconstructing the data is performed by reversing the process. Each stored reference code in a data collection is compared with the reference codes in the library, the corresponding sourceblock is read from the library, and the data is reconstructed into its original form.

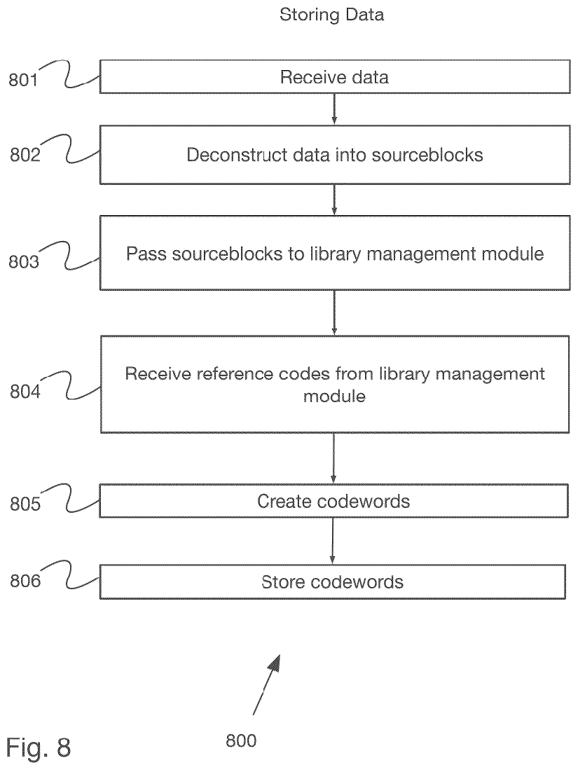

FIG. 8 is a method diagram showing the steps involved in using an embodiment 800 to store data. As data is received 801, it would be deconstructed into sourceblocks 802, and passed 803 to the library management module for processing. Reference codes would be received back 804 from the library management module, and could be combined with location information to create codewords 805, which would then be stored 806 as representations of the original data.

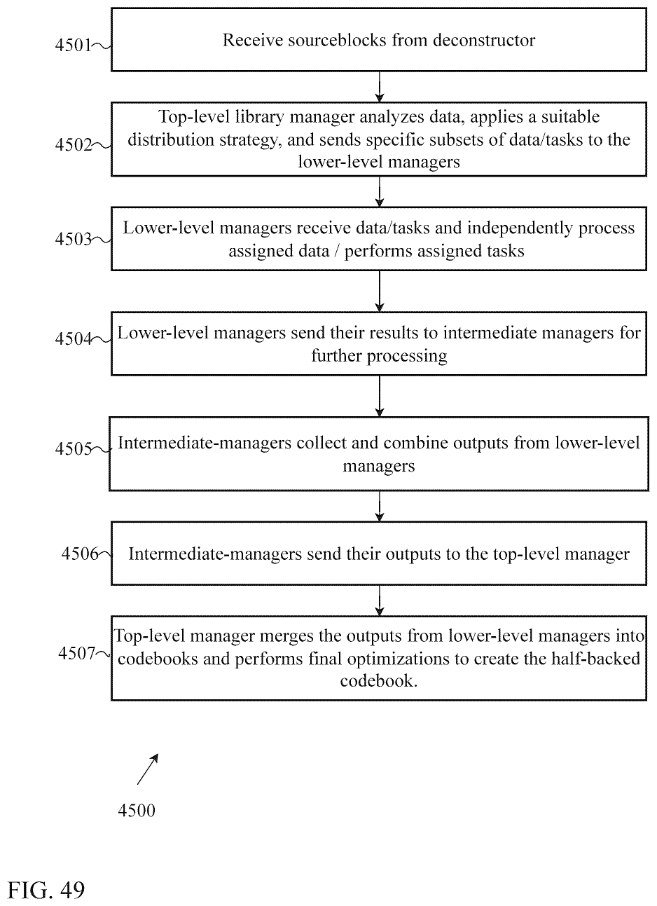

FIG. 49 is a flowchart illustrating the steps 4500 involved of the hierarchical library manager. The top-level library manager receives anonymized codeblocks 4501, analyzes the sourceblocks, and applied a suitable distribution strategy before sending the data to the lower-level managers 4502. These lower-level managers independently process their assigned sourceblocks, applying specific optimization techniques such as assigning codewords, creating partial codebooks, or performing local optimizations 4503. Once the lower-level managers have completed their processing, they send their intermediate results, which may include partially optimized codebooks or relevant metadata, to the intermediate-level library managers 4504. The intermediate-level managers collect and consolidate these results from multiple lower-level managers, combining them into more comprehensive codebooks or datasets. They may further refine and optimize the consolidated codebooks by applying additional techniques to improve efficiency or remove redundancies 4505. The intermediate-level managers then pass the refined codebooks to the top-level library manager 4506. The top-level manager, sitting at the root of the hierarchy, receives the consolidated codebooks from the intermediate-level managers and performs final optimizations 4507. This may involve merging codebooks, eliminating duplicates, or applying global optimization techniques to create the final, optimized codebook, such as the half-backed codebook, representing the entire dataset. The top-level manager may also make high-level decisions, such as determining the optimal sourceblock length or selecting the most efficient codebook structure. Finally, the top-level manager prepares the optimized codebook for further use, such as storage or transmission, completing the hierarchical processing of sourceblocks within the library manager system.

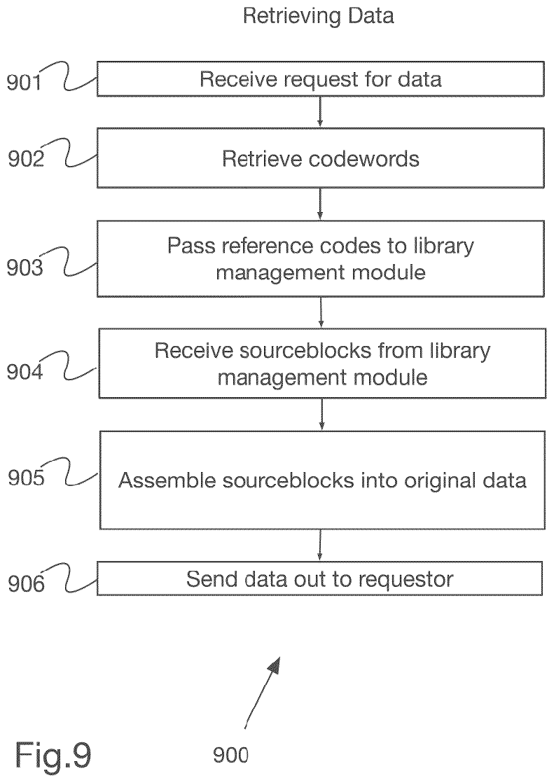

FIG. 9 is a method diagram showing the steps involved in using an embodiment 900 to retrieve data. When a request for data is received 901, the associated codewords would be retrieved 902 from the library. The codewords would be passed 903 to the library management module, and the associated sourceblocks would be received back 904. Upon receipt, the sourceblocks would be assembled 905 into the original data using the location data contained in the codewords, and the reconstructed data would be sent out 906 to the requestor.

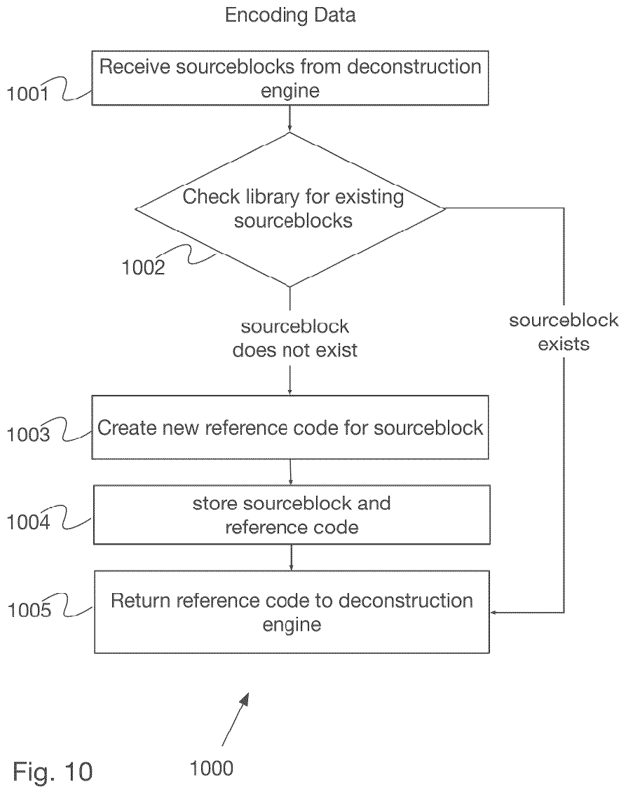

FIG. 10 is a method diagram showing the steps involved in using an embodiment 1000 to encode data. As sourceblocks are received 1001 from the deconstruction engine, they would be compared 1002 with the sourceblocks already contained in the library. If that sourceblock already exists in the library, the associated reference code would be returned 1005 to the deconstruction engine. If the sourceblock does not already exist in the library, a new reference code would be created 1003 for the sourceblock. The new reference code and its associated sourceblock would be stored 1004 in the library, and the reference code would be returned to the deconstruction engine.

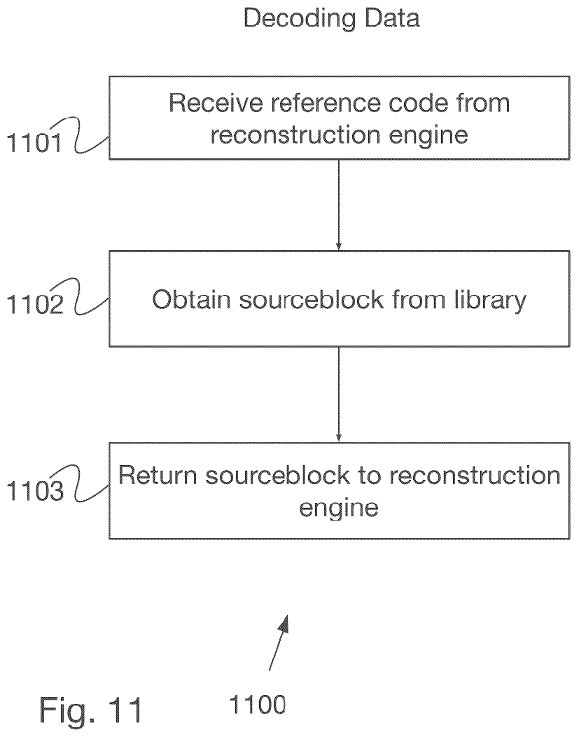

FIG. 11 is a method diagram showing the steps involved in using an embodiment 1100 to decode data. As reference codes are received 1101 from the reconstruction engine, the associated sourceblocks are retrieved 1102 from the library, and returned 1103 to the reconstruction engine.

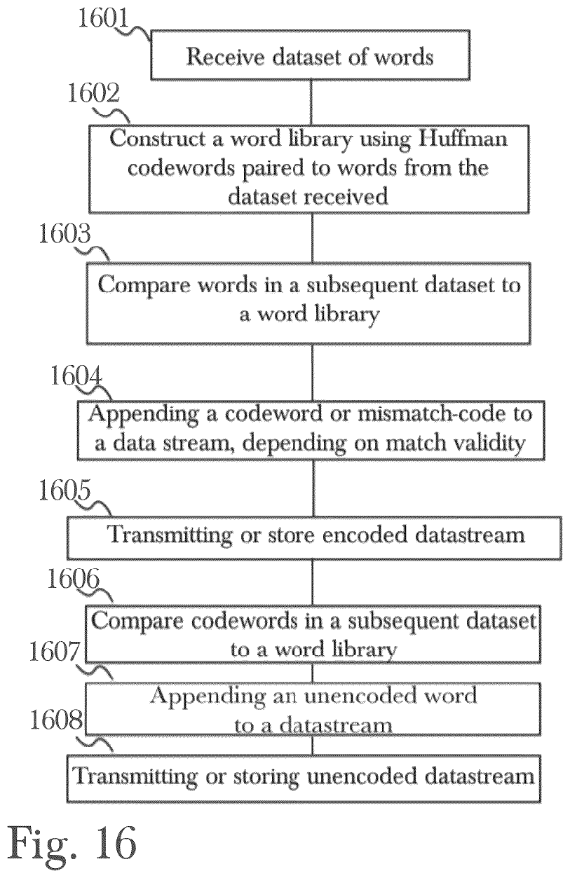

FIG. 16 is a method diagram illustrating key system functionality utilizing an encoder and decoder pair, according to a preferred embodiment. In a first step 1601, at least one incoming data set may be received at a customized library generator 1300 that then 1602 processes data to produce a customized word library 1201 comprising key-value pairs of data words (each comprising a string of bits) and their corresponding calculated binary Huffman codewords. A subsequent dataset may be received, and compared to the word library 1603 to determine the proper codewords to use in order to encode the dataset. Words in the dataset are checked against the word library and appropriate encodings are appended to a data stream 1604. If a word is mismatched within the word library and the dataset, meaning that it is present in the dataset but not the word library, then a mismatched code is appended, followed by the unencoded original word. If a word has a match within the word library, then the appropriate codeword in the word library is appended to the data stream. Such a data stream may then be stored or transmitted 1605 to a destination as desired. For the purposes of decoding, an already-encoded data stream may be received and compared 1606, and un-encoded words may be appended to a new data stream 1607 depending on word matches found between the encoded data stream and the word library that is present. A matching codeword that is found in a word library is replaced with the matching word and appended to a data stream, and a mismatch code found in a data stream is deleted and the following unencoded word is re-appended to a new data stream, the inverse of the process of encoding described earlier. Such a data stream may then be stored or transmitted 1608 as desired.

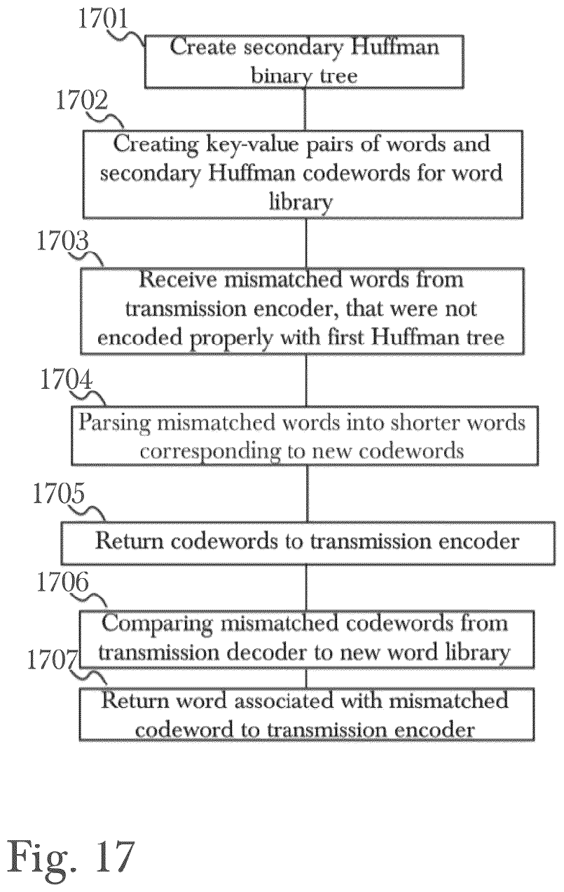

FIG. 17 is a method diagram illustrating possible use of a hybrid encoder/decoder to improve the compression ratio, according to a preferred aspect. A second Huffman binary tree may be created 1701, having a shorter maximum length of codewords than a first Huffman binary tree 1602, allowing a word library to be filled with every combination of codeword possible in this shorter Huffman binary tree 1702. A word library may be filled with these Huffman codewords and words from a dataset 1702, such that a hybrid encoder/decoder 1304, 1503 may receive any mismatched words from a dataset for which encoding has been attempted with a first Huffman binary tree 1703, 1604 and parse previously mismatched words into new partial codewords (that is, codewords that are each a substring of an original mismatched codeword) using the second Huffman binary tree 1704. In this way, an incomplete word library may be supplemented by a second word library. New codewords attained in this way may then be returned to a transmission encoder 1705, 1500. In the event that an encoded dataset is received for decoding, and there is a mismatch code indicating that additional coding is needed, a mismatch code may be removed and the unencoded word used to generate a new codeword as before 1706, so that a transmission encoder 1500 may have the word and newly generated codeword added to its word library 1707, to prevent further mismatching and errors in encoding and decoding.

It will be recognized by a person skilled in the art that the methods described herein can be applied to data in any form. For example, the method described herein could be used to store genetic data, which has four data units: C, G, A, and T. Those four data units can be represented as 2 bit sequences: 00, 01, 10, and 11, which can be processed and stored using the method described herein.

It will be recognized by a person skilled in the art that certain embodiments of the methods described herein may have uses other than data storage. For example, because the data is stored in reference code form, it cannot be reconstructed without the availability of the library of sourceblocks. This is effectively a form of encryption, which could be used for cyber security purposes. As another example, an embodiment of the method described herein could be used to store backup copies of data, provide for redundancy in the event of server failure, or provide additional security against cyberattacks by distributing multiple partial copies of the library among computers are various locations, ensuring that at least two copies of each sourceblock exist in different locations within the network.

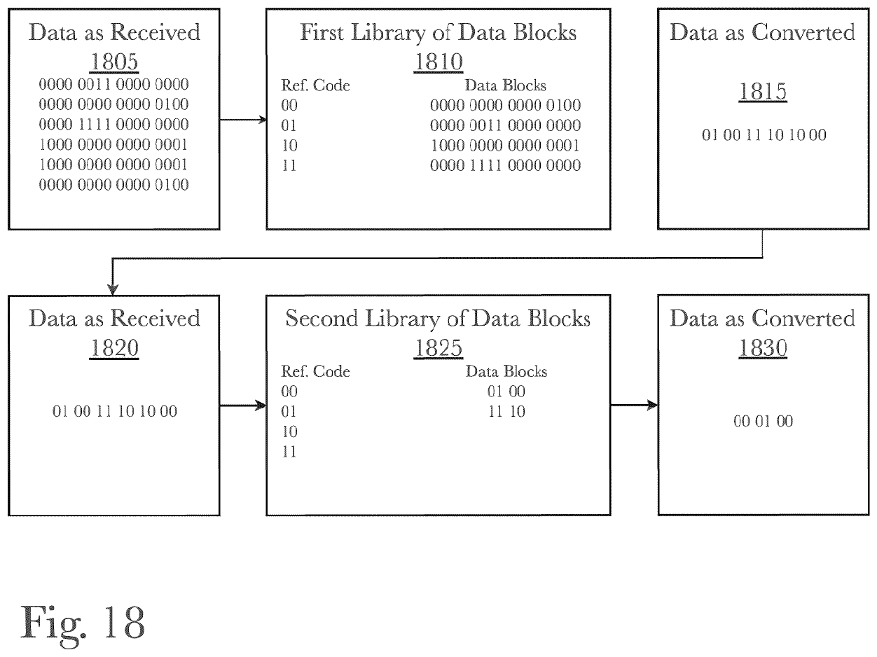

FIG. 18 is a flow diagram illustrating the use of a data encoding system used to recursively encode data to further reduce data size. Data may be input 1805 into a data deconstruction engine 102 to be deconstructed into code references, using a library of code references based on the input 1810. Such example data is shown in a converted, encoded format 1815, highly compressed, reducing the example data from 96 bits of data, to 12 bits of data, before sending this newly encoded data through the process again 1820, to be encoded by a second library 1825, reducing it even further. The newly converted data 1830 is shown as only 6 bits in this example, thus a size of 6.25% of the original data packet. With recursive encoding, then, it is possible and implemented in the system to achieve increasing compression ratios, using multi-layered encoding, through recursively encoding data. Both initial encoding libraries 1810 and subsequent libraries 1825 may be achieved through machine learning techniques to find optimal encoding patterns to reduce size, with the libraries being distributed to recipients prior to transfer of the actual encoded data, such that only the compressed data 1830 must be transferred or stored, allowing for smaller data footprints and bandwidth requirements. This process can be reversed to reconstruct the data. While this example shows only two levels of encoding, recursive encoding may be repeated any number of times. The number of levels of recursive encoding will depend on many factors, a non-exhaustive list of which includes the type of data being encoded, the size of the original data, the intended usage of the data, the number of instances of data being stored, and available storage space for codebooks and libraries. Additionally, recursive encoding can be applied not only to data to be stored or transmitted, but also to the codebooks and/or libraries, themselves. For example, many installations of different libraries could take up a substantial amount of storage space. Recursively encoding those different libraries to a single, universal library would dramatically reduce the amount of storage space required, and each different library could be reconstructed as necessary to reconstruct incoming streams of data.

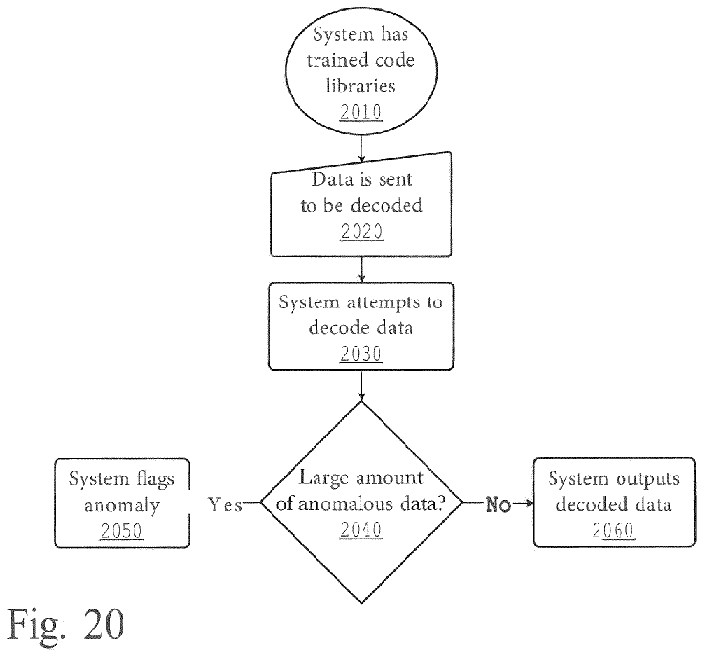

FIG. 20 is a flow diagram of an exemplary method used to detect anomalies in received encoded data and producing a warning. A system may have trained encoding libraries 2010, before data is received from some source such as a network connected device or a locally connected device including USB connected devices, to be decoded 2020. Decoding in this context refers to the process of using the encoding libraries to take the received data and attempt to use encoded references to decode the data into its original source 2030, potentially more than once if recursive encoding was used, but not necessarily more than once. An anomaly detector 1910 may be configured to detect a large amount of un-encoded data 2040 in the midst of encoded data, by locating data or references that do not appear in the encoding libraries, indicating at least an anomaly, and potentially data tampering or faulty encoding libraries. A flag or warning is set by the system 2050, allowing a user to be warned at least of the presence of the anomaly and the characteristics of the anomaly. However, if a large amount of invalid references or unencoded data are not present in the encoded data that is attempting to be decoded, the data may be decoded and output as normal 2060, indicating no anomaly has been detected.

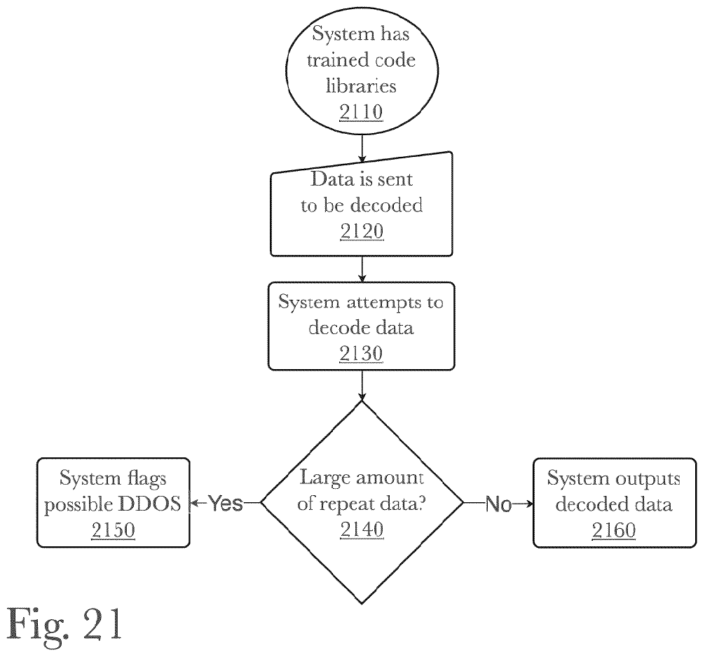

FIG. 21 is a flow diagram of a method used for Distributed Denial of Service (DDoS) attack denial. A system may have trained encoding libraries 2110, before data is received from some source such as a network connected device or a locally connected device including USB connected devices, to be decoded 2120. Decoding in this context refers to the process of using the encoding libraries to take the received data and attempt to use encoded references to decode the data into its original source 2130, potentially more than once if recursive encoding was used, but not necessarily more than once. A DDoS detector 1920 may be configured to detect a large amount of repeating data 2140 in the encoded data, by locating data or references that repeat many times over (the number of which can be configured by a user or administrator as need be), indicating a possible DDoS attack. A flag or warning is set by the system 2150, allowing a user to be warned at least of the presence of a possible DDoS attack, including characteristics about the data and source that initiated the flag, allowing a user to then block incoming data from that source. However, if a large amount of repeat data in a short span of time is not detected, the data may be decoded and output as normal 2160, indicating no DDoS attack has been detected.

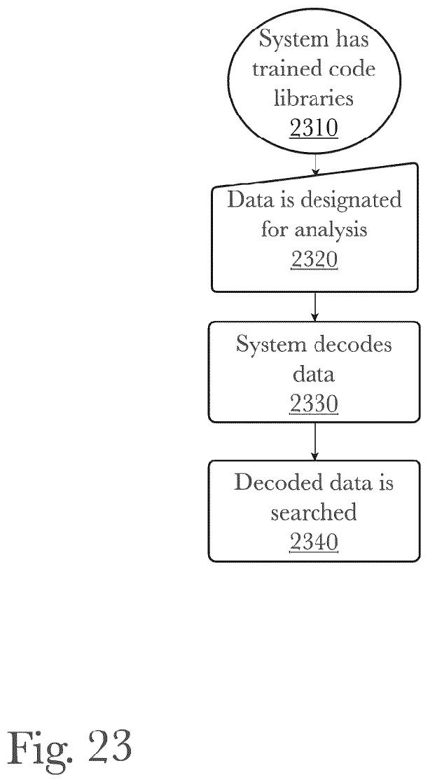

FIG. 23 is a flow diagram of an exemplary method used to enable high-speed data mining of repetitive data. A system may have trained encoding libraries 2310, before data is received from some source such as a network connected device or a locally connected device including USB connected devices, to be analyzed 2320 and decoded 2330. When determining data for analysis, users may select specific data to designate for decoding 2330, before running any data mining or analytics functions or software on the decoded data 2340. Rather than having traditional decryption and decompression operate over distributed drives, data can be regenerated immediately using the encoding libraries disclosed herein, as it is being searched. Using methods described in FIG. 9 and FIG. 11, data can be stored, retrieved, and decoded swiftly for searching, even across multiple devices, because the encoding library may be on each device. For example, if a group of servers host codewords relevant for data mining purposes, a single computer can request these codewords, and the codewords can be sent to the recipient swiftly over the bandwidth of their connection, allowing the recipient to locally decode the data for immediate evaluation and searching, rather than running slow, traditional decompression algorithms on data stored across multiple devices or transfer larger sums of data across limited bandwidth.

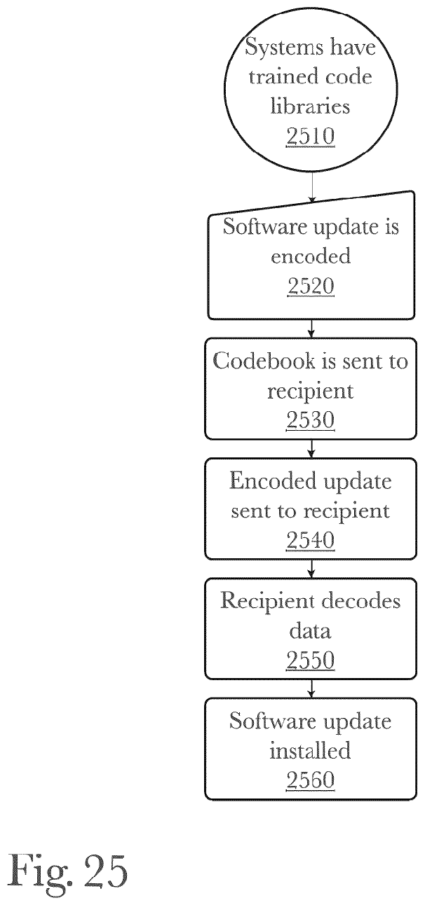

FIG. 25 is a flow diagram of an exemplary method used to encode and transfer software and firmware updates to a device for installation, for the purposes of reduced bandwidth consumption. A first system may have trained code libraries or “codebooks” present 2510, allowing for a software update of some manner to be encoded 2520. Such a software update may be a firmware update, operating system update, security patch, application patch or upgrade, or any other type of software update, patch, modification, or upgrade, affecting any computer system. A codebook for the patch must be distributed to a recipient 2530, which may be done beforehand and either over a network or through a local or physical connection, but must be accomplished at some point in the process before the update may be installed on the recipient device 2560. An update may then be distributed to a recipient device 2540, allowing a recipient with a codebook distributed to them 2530 to decode the update 2550 before installation 2560. In this way, an encoded and thus heavily compressed update may be sent to a recipient far quicker and with less bandwidth usage than traditional lossless compression methods for data, or when sending data in uncompressed formats. This especially may benefit large distributions of software and software updates, as with enterprises updating large numbers of devices at once.

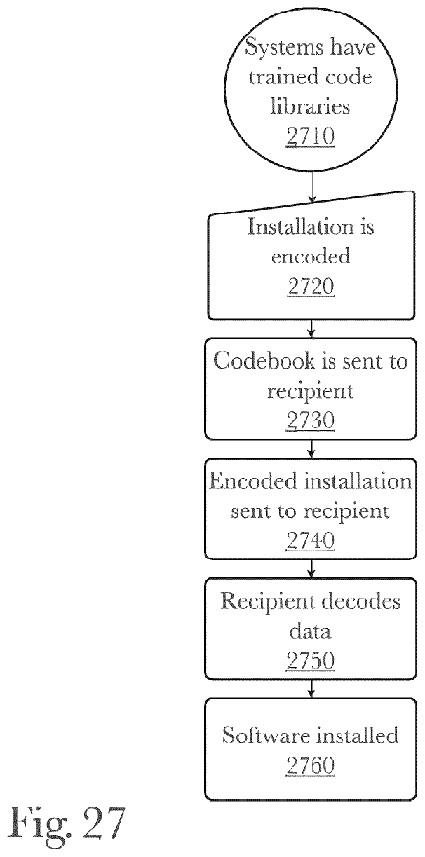

FIG. 27 is a flow diagram of an exemplary method used to encode new software and operating system installations for reduced bandwidth required for transference. A first system may have trained code libraries or “codebooks” present 2710, allowing for a software installation of some manner to be encoded 2720. Such a software installation may be a software update, operating system, security system, application, or any other type of software installation, execution, or acquisition, affecting a computer system. An encoding library or “codebook” for the installation must be distributed to a recipient 2730, which may be done beforehand and either over a network or through a local or physical connection, but must be accomplished at some point in the process before the installation can begin on the recipient device 2760. An installation may then be distributed to a recipient device 2740, allowing a recipient with a codebook distributed to them 2730 to decode the installation 2750 before executing the installation 2760. In this way, an encoded and thus heavily compressed software installation may be sent to a recipient far quicker and with less bandwidth usage than traditional lossless compression methods for data, or when sending data in uncompressed formats. This especially may benefit large distributions of software and software updates, as with enterprises updating large numbers of devices at once.

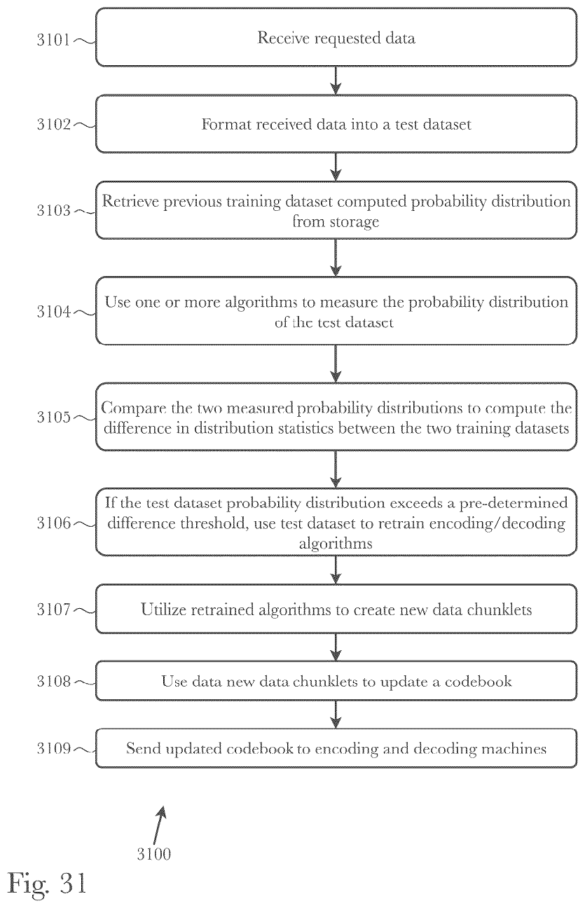

FIG. 31 is a method diagram illustrating the steps 3100 involved in using an embodiment of the codebook training system to update a codebook. The process begins when requested data is received 3101 by a codebook training module. The requested data may comprise a plurality of sourceblocks. Next, the received data may be stored in a cache and formatted into a test dataset 3102. The next step is to retrieve the previously computed probability distribution associated with the previous (most recent) training dataset from a storage device 3103. Using one or more algorithms, measure and record the probability distribution of the test dataset 3104. The step after that is to compare the measured probability distributions of the test dataset and the previous training dataset to compute the difference in distribution statistics between the two datasets 3105. If the test dataset probability distribution exceeds a pre-determined difference threshold, then the test dataset will be used to retrain the encoding/decoding algorithms 3106 to reflect the new distribution of the incoming data to the encoder/decoder system. The retrained algorithms may then be used to create new data sourceblocks 3107 that better capture the nature of the data being received. These newly created data sourceblocks may then be used to create new codewords and update a codebook 3108 with each new data sourceblock and its associated new codeword. Last, the updated codebooks may be sent to encoding and decoding machines 3109 in order to ensure the encoding/decoding system function properly.

FIG. 37 is a diagram illustrating an exemplary data source tally record 3710 and its anonymized counterpart 3720, according to some embodiments. The data source may belong to a system 3600 user who wishes to take advantage of the compaction and encryption capabilities of system 3600, but who also wishes to keep their data private. System 3600 can facilitate the compaction of anonymized data. Data source may be prepared for processing by first dividing up the data source into a plurality of sourceblocks at all reasonable lengths, for example at sourceblock lengths 3711 of 8-bits, 16-bits, 24-bits, etc. For instance, the data source may first be broken down into a plurality of sourceblocks 3713 each with a sourceblock length 3711 of 8-bits. Then, the owner of data source can create a log count 3712 (e.g., tally) of the number of times each sourceblock 3713 occurs in data source. After all the sourceblocks have been created and counted, the data source owner (e.g., system 3600 user) can anonymize 3725 the tally record 3710. According to some embodiments, data source may be anonymized using a variety of techniques including, but not limited to, directory replacement, masking out, scrambling/shuffling, generalization, blurring, data encryption, substitution, nulling out, number and date variance, or a custom anonymization technique chosen by data source owner. Because the data anonymization is carried out by the data source owner (e.g., system 3600 user) prior to sending the anonymized tally record 3720 to system 3600 for compaction and encryption, the exact method of data anonymization that is used is variable, dependent upon, and may be specific to a particular user or organization.

After the anonymization 3725 process, the original sourceblocks may be replaced with tokens 3722 acting as stand-ins for the original data. Each token 3722, its associated tally 3721, and the sourceblock length 3711 may be transmitted to system 3600 as an anonymized tally record 3720. System 3600 only requires the information included in the anonymized tally record 3720 in order to compact and encrypt the original source data without needing to be aware of what the original data was. This anonymized tally record 3720 information is enough for system 3600 to construct codebooks for the original source data and can even be used to select the optimal codebook.

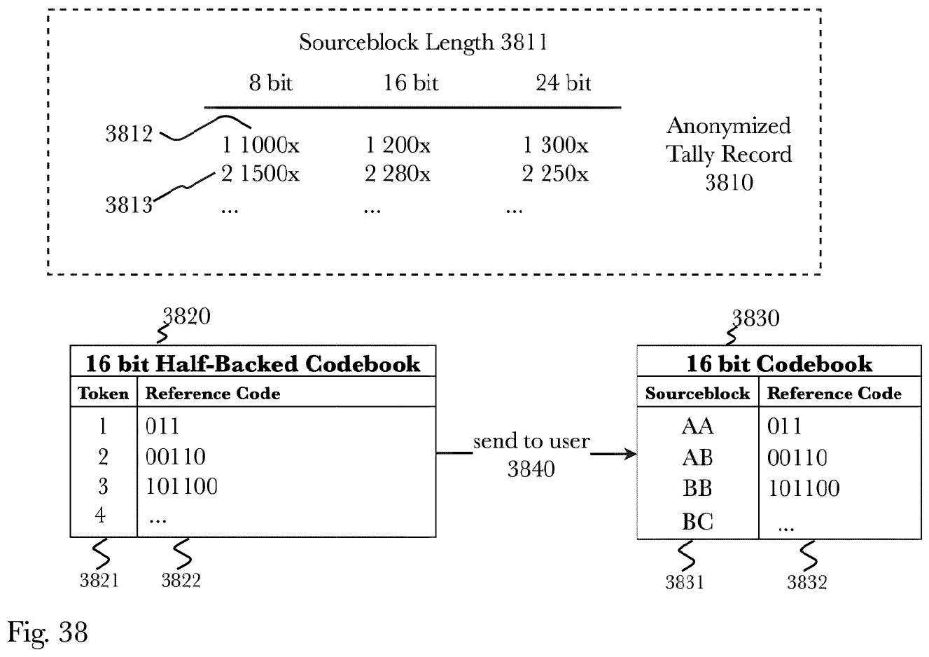

FIG. 38 is a block diagram illustrating an exemplary anonymized tally record 3810 that may be received by system 3600 and an exemplary half-backed codebook 3820 constructed using the information contained in the anonymized tally record 3810. According to some embodiments, an anonymized tally record 3810 may be received by system 3600 from a system user. Anonymized tally record 3810 may comprise an indication of the sourceblock length(s) 3811 used (e.g., 8-bit, 16-bit, 24-bit, etc.), and for each sourceblock length 3811 the anonymized data in the form of tokens 3813 which represent sourceblocks of non-anonymized data, and a tally 3812 or count of the number of times that a sourceblock, represented by token 3813 occurred in the original data source. For example, the anonymized tally record 3810 indicates that the original data source was divided into sourceblocks three different times, each time with a different sourceblock length 3811 (8-bit, 16-bit, and 24-bit). The 8-bit data is indicated as the column of data descending underneath the 8-bit column header, wherein the column has two rows indicating the token 3813 (represented as an integer value) and its associated tally 3813 (represented as an integer value followed by an ‘x’). It should be appreciated that the use of integer values used to represent the tokens 3813 was chosen to simplify this example, and that tokens 3813 may be represented in variety of ways, not limited to only integer representations. Likewise, it should also be appreciated that the tally 3812 or count need not be represented as an integer value followed by an ‘x’. Tally 3812 may be represented as a binary digit, hexadecimal digit, integer, or the like, and that different embodiments and aspects may implement different ways of representing the tally 3812.

According to some embodiments, system 3600 may process the received anonymized tally record 3810 in order to construct a half-backed codebook 3820. Half-backed codebook 3820 may be constructed similarly to regular codebooks, the only difference being that regular codebooks contain a plurality of sourceblocks and for each sourceblock a unique reference code 3822 (i.e., codeword), whereas a half-backed codebook 3820 comprises a plurality of tokens 3821 and for each token a unique reference code 3822. System 3600 performs codebook construction and reference code creation and assignment using the techniques disclosed above (referring to FIG. 36) and throughout this specification, the only difference is that tokens are used in place of sourceblocks.

The exemplary anonymized tally record 3810 of FIG. 38 is comprised of three sets of data; with each set of data corresponding to a sourceblock length 3811 (8-bit, 16-bit, and 24-bit). System 3600 can compact each set of data and then determine which compacted set of data yielded the optimal compaction results. For this example, the set of data associated with sourceblocks of length 16-bits was the most optimal set of data, so the half-backed codebook 3820 associated with that data set will be selected. Once the optimal half-backed codebook 3820 is selected, it may be sent 3840 back to the system user (e.g., customer and/or data source owner). System 3600 user can then deanonymize the tokens contained within the received half-backed codebook 3820 using the reverse of whatever data anonymization technique they used to tokenize the data. The result of this process is that the system 3600 user now has in their possession a codebook 3830 comprising sourceblocks 3831 of their original data and for each sourceblock a reference code 3832 (i.e., codeword) representing a compacted and encrypted form of the sourceblock 3831. In this way, a system 3600 user may be able to keep their data private, but also have the benefit of the data compaction and encryption provided by system 3600.

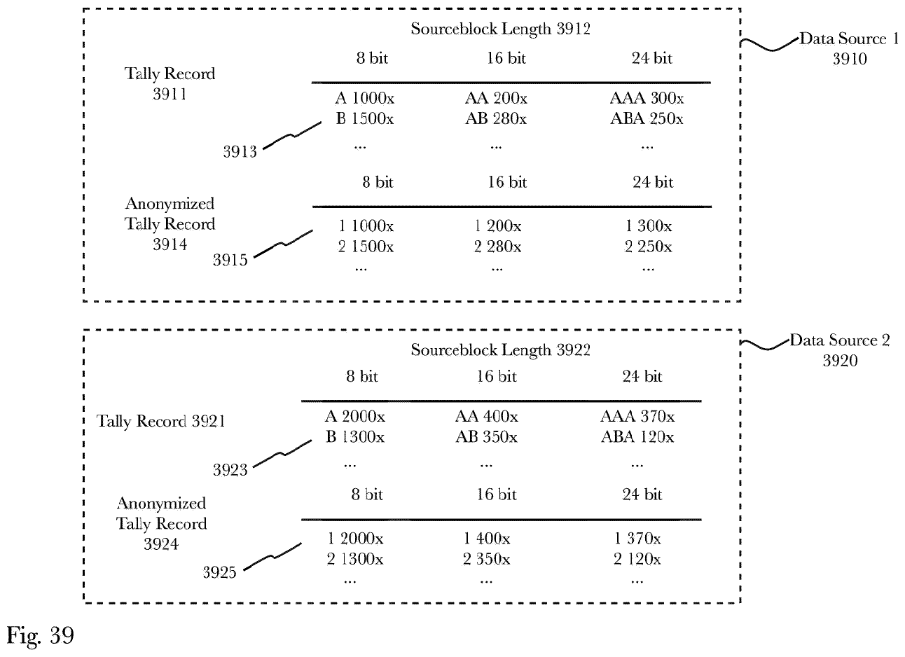

FIG. 39 is a diagram illustrating two exemplary data sources, each of which is shown in non-anonymized tally record and anonymized tally record form. According to some embodiments, system 3600 may receive two or more data sources 3910, 3920 in anonymized tally record form 3914, 3924. Data source 1 3910 may be prepared into a tally record 3911 containing a plurality of token/tally pairs 3913 for different sourceblock lengths 3912. The tally record may be anonymized resulting in an anonymized tally record 3914 comprising a plurality of token/tally pairs 3915 for different sourceblock lengths 3912. Similarly, data source 2 3920 may be prepared into a tally record 3921 comprising a plurality of sourceblock/tally pairs 3923 for different sourceblock lengths 3922. The tally record 3921 may be anonymized resulting in an anonymized tally record 3924 comprising a plurality of token/tally pairs 3925 for different sourceblock lengths. Both anonymized tally records 3914, 3924 may be sent to system 3600 for data compaction and encryption processing into a combined half-backed codebook.

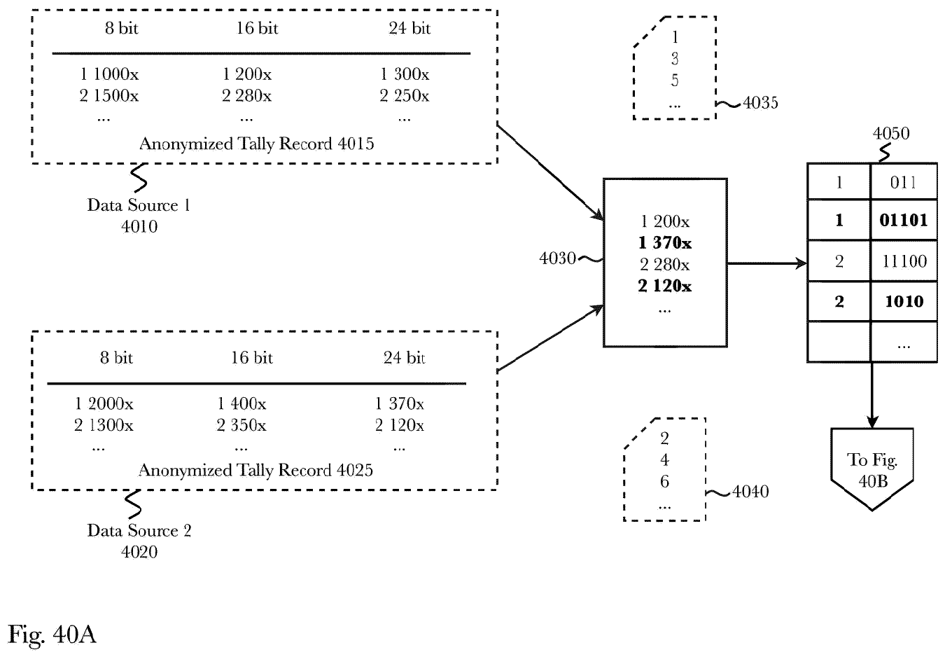

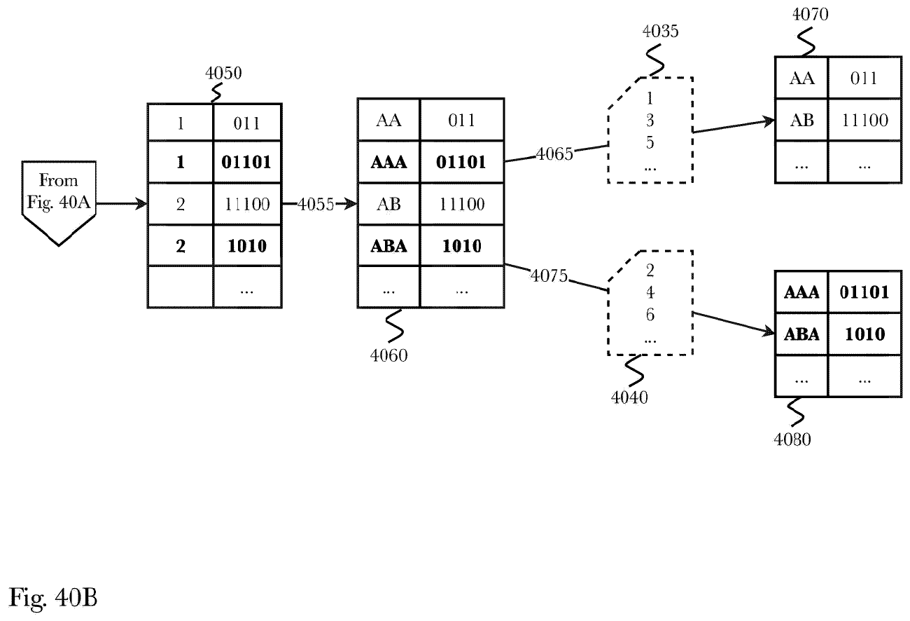

FIG. 40A is diagram illustrating an exemplary process of constructing a half-backed codebook 4050 using two data sources 4010, 4020 and data source stencils 4035, 4040, according to some embodiments. The anonymized tally records 4015, 4025 associated with data source 1 4010 and data source 2 4020 each contain three sets of data corresponding to three different sourceblock lengths (8-bit, 16-bit, 24-bit). Each set of data may be compacted and the optimally (e.g., best compaction) compacted data set from each data source may be selected for half-backed codebook creation. For example, consider the 16-bit data set from data source 1 4010 as the most optimal set from data source 1 4010, and the 24-bit data set from data source 2 4020 as the most optimal set from data source 2 4020. Each of these two sets of data with the best compaction may combined into a single data structure 4030 comprising tokens and for each token its tally. According to some embodiments, each of the two sets of data may have an accompanying stencil 4035, 4040 that is created which can be used to extract the appropriate data values from the combined data structure 4030. As illustrated, the combined data structure comprises tokens taken from the 16-bit data set of data source 1 4010 and stores these values in the odd-numbered positions of the combined data structure 4030 starting with the first position using one-based indexing. In some embodiments, the data structure may use zero-based indexing. The stencil 4035 associated with data source 1 4010 lists the positions (e.g., 1, 3, 5, 7, . . . , etc.) in the combined data structure 4030 which correspond to token/count combinations that originated from data source 1 4010. The 24-bit data set from data source 2 4020 may be added to the combined data structure 4030 in even-numbered positions starting with position 2 (indicated by the bolded values in combined data structure 4030). The stencil 4040 associated with data source 2 4020 lists the positions (e.g., 2, 4, 6, . . . , etc.) in the combined data structure 4030 which correspond to token/count combinations that originated from data source 2 4020. The combined data structure 4030 may be passed to library manager 3630 in order to compact and encrypt the data contained within combined data structure 4030 to construct a combined half-backed codebook 4050 comprising data from two different data sources. Once a combined half-backed codebook 4050 is constructed, the combined half-backed codebook 4050 and any stencils 4035, 4040 may be transmitted back to the owner of the data sources where the combined half-backed codebook 4050 may be transformed into a full-fledged codebook, as discussed in FIG. 40B.

FIG. 40B is a diagram illustrating an exemplary process of transforming a combined half-backed codebook 4050 comprising data from two different data sources using data source stencils 4035, 4040 according to some embodiments. According to some embodiments, a system user and/or data owner may receive from the system 3600 a combined half-backed codebook 4050 and any associated data source stencils 4035, 4040. The data owner can deanonymize 4055 the tokens stored within the combined half-backed codebook 4050 by replacing the tokenized data values with the original data values (sourceblocks) that existed prior to anonymization 4060. This results in transforming the combined half-backed codebook 4050 into a standard codebook 4070, 4080 comprising a plurality of sourceblocks of data and for each sourceblock a reference code (i.e., codeword). However, because this combined half-backed codebook 4050 contains data from two different data sources, it requires the use 4065, 4075 of the accompanying received stencils 4035, 4040 in order to deconstruct the combined half-backed codebook 4050 into two separate codebooks 4070, 4080, each of which is associated with its original data sources. As a result, the system user and/or data owner now has a means to store and/or transmit the original data sources 4010, 4020 in a compacted and encrypted format without disclosing the contents/values of the original data sources.

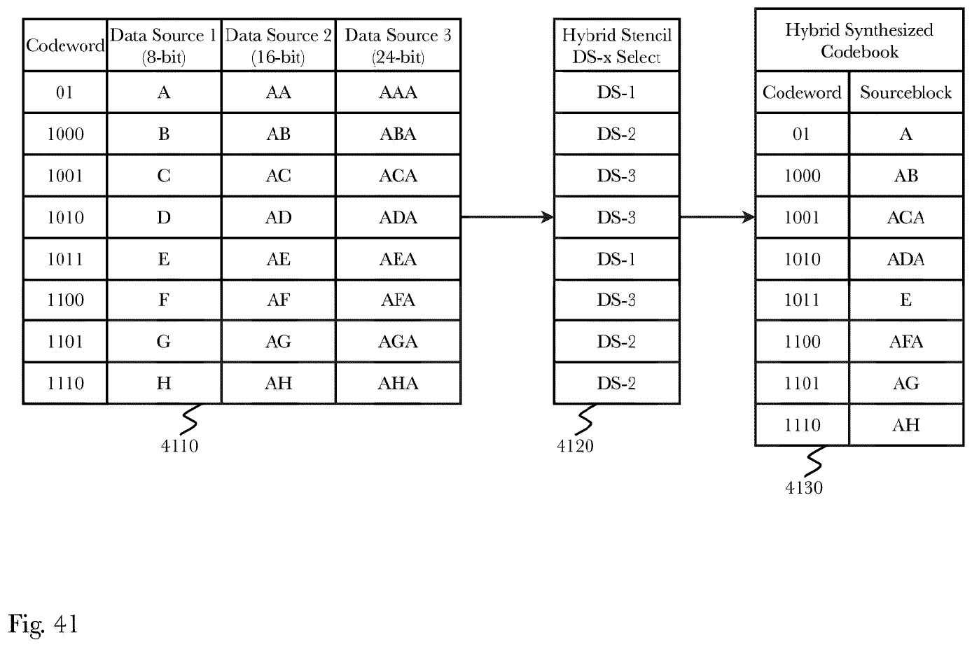

FIG. 41 is a diagram illustrating an exemplary hybrid stencil constructed using three different data sources, according to some embodiments. According to some embodiments, hybrid stencils 4120 may be used to synthesize codebooks by combining partial results from multiple datasets 4110. This may be done dynamically at runtime, requiring transmission or storage only of the hybrid stencil 4120, which is generally smaller in size than the codebook. Hybrid stencils 4120 can only use each codeword once. Using a hybrid stencil 4120 results in the construction of a hybrid synthesized codebook 4130.

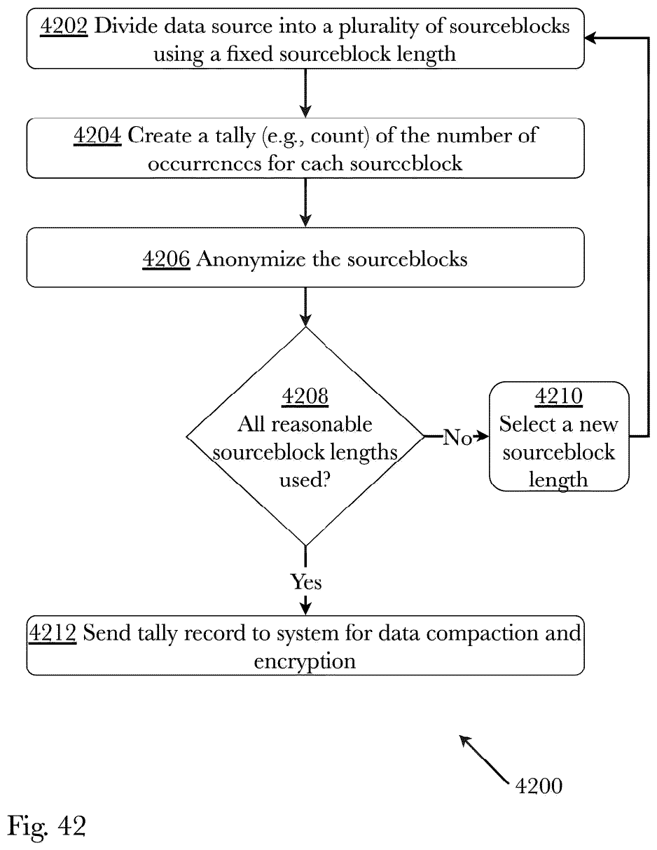

FIG. 42 is an exemplary flow diagram for a method 4200 of preparing an anonymized tally record, according to some embodiments. According to some embodiments, the process is carried out by a data owner and/or system 3600 user prior to sending an anonymized tally record to system 3600 for data compaction and encryption. The process begins at step 4202 by dividing the data source into a plurality of sourceblocks using a fixed sourceblock length (e.g., 8-bits, 16-bits, etc.). As a next step 4204, create a tally (e.g., count) of the number of occurrences for each sourceblock. After this step, the data owner should now have a tally record comprising a plurality of sourceblocks and for each sourceblock a tally value. The next step 4206 is to anonymize the sourceblocks within the tally record using a data anonymization technique or mechanism chosen by the data owner. The next step is to check 4208 whether all reasonable sourceblock lengths have been selected for dividing the data source into a plurality of sourceblocks. If not all reasonable sourceblock lengths have been used, a new sourceblock length is selected 4210 and the process returns to step 4202 until all reasonable sourceblock lengths have been iterated through. At that point, the last step 4212 is to send the anonymized tally record to system 3600 for data compaction and encryption via codebook construction and optimization.

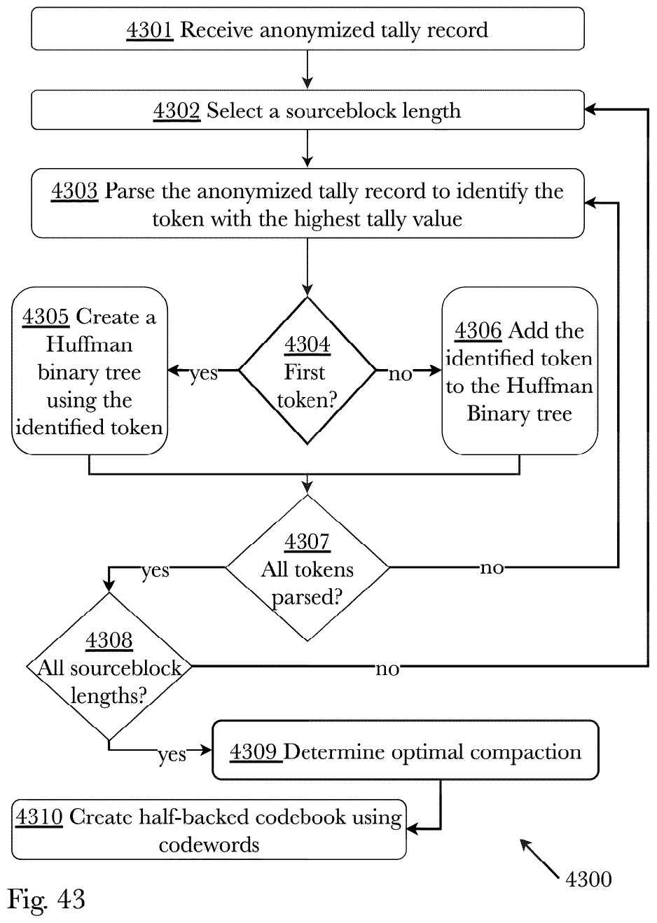

FIG. 43 is an exemplary flow diagram for a method 4300 for constructing a half-backed codebook using a received anonymized tally record, according to some embodiments. According to some embodiments, the process begins with step 4301 when system 3600 receives an anonymized tally record. At the next step 4302, a data parser 3626 may be configured to select a sourceblock length from the available options of sourceblock lengths provided by the anonymized tally record. Then, data parser 3626 may parse the anonymized tally record to identify the token with the highest tally value. Additionally, when a token is identified it may be temporarily removed (or flagged) from the anonymized tally record so that as data parser 3626 iterates through the anonymized tally record it does not identify the same token twice. The next step determines if the identified token was the first token (i.e., the token with the highest tally value) 4304. If the identified token is the first token, then it may be sent to library manager 3630 where Huffman tree creator 3631 can create a Huffman binary tree using the identified first token with the highest tally value as the starting point for the binary tree 4305 and assigned a codeword. If instead, the identified token is not the first token then it is simply added to the Huffman binary tree and assigned a codeword 4306. After a Huffman binary tree creation or after adding a token to the Huffman tree, the next step 4307 checks if all the tokens associated with a given sourceblock length have been parsed. If not all the tokens have been parsed then the process repeats itself starting with step 4303. Instead, if all tokens have been parsed, then another check occurs 4308 which determines if all sourceblock lengths contained in the received anonymized tally record have been processed. If not all sourceblock lengths have been processed then the process repeats itself starting with step 4302. However, if all sourceblock lengths have been processed then codebook creator 3632 may 4309 optimize and/or determine which sourceblock length resulted in the most optimal (e.g., best compaction ratio, etc.) compaction. Then as a last step 4310, the codebook creator 3632 may create a half-backed codebook using determined sourceblock length assigned codewords.

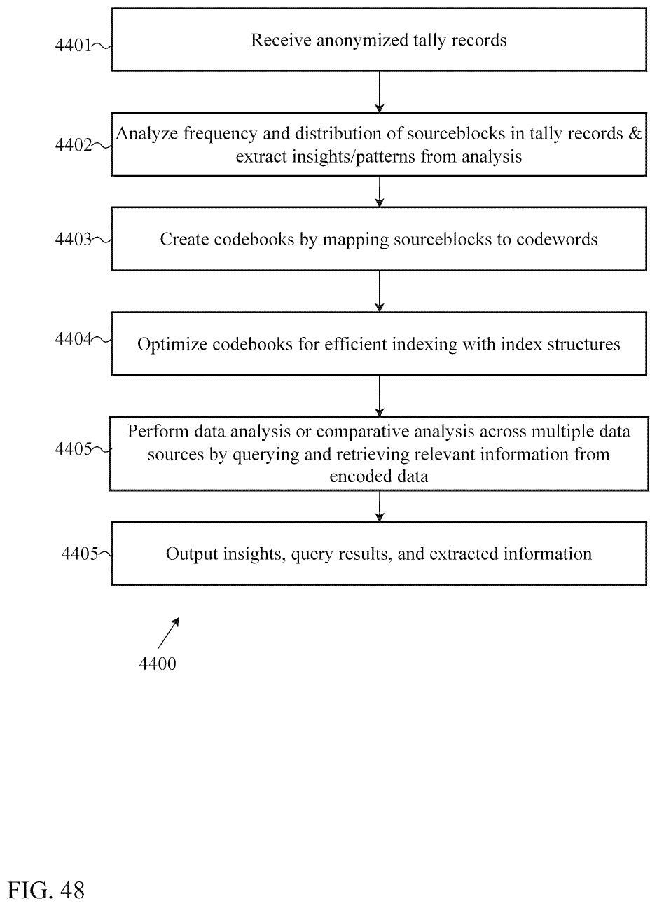

FIG. 48 is a flowchart illustrating the steps 4400 involved in the data analysis and indexing process using anonymized tally records and codebooks in an embodiment. The process begins with receiving the anonymized tally records as input 4401. These tally records then analyzed to determine the frequency and distribution of sourceblocks within the dataset 4402. This analysis step allows for extracting valuable insights and patterns from the data. Next, the codebooks are created by mapping the sourceblocks to codewords 4403, which enables efficient data compression and encryption. The codebooks are further optimized to facilitate effective indexing 4404. This optimization step involves creating suitable indexing structures, such as inverted indexes or hash tables, which enable fast search and retrieval operations on the encoded data. With the optimized codebooks and indexes in place, various data analysis tasks can be performed 4405. These tasks include querying and retrieving relevant information from the encoded data, as well as conducting comparative analysis across multiple data sources. The results of the data analysis, including insights, query results, and extracted information, are produced as output 4406.

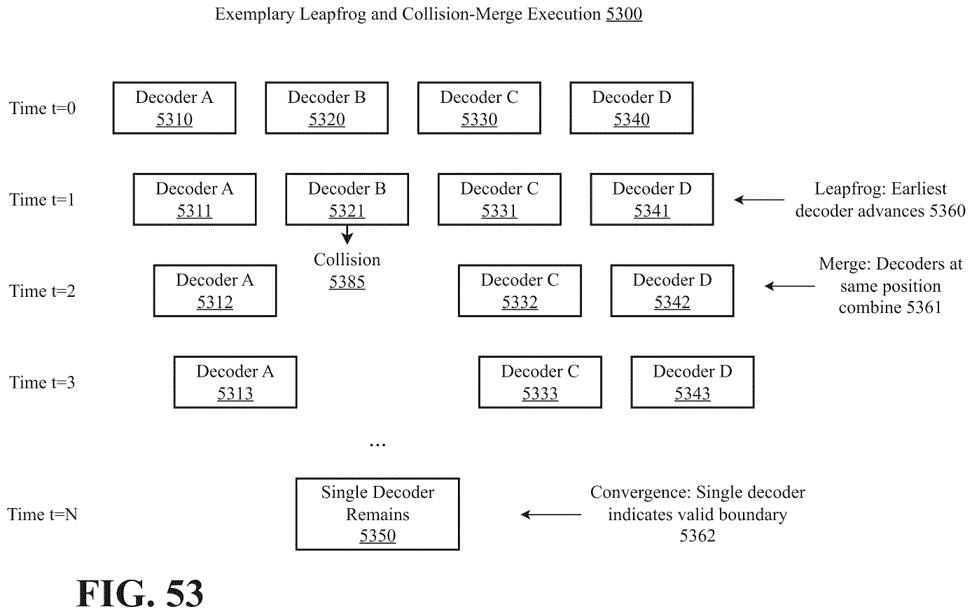

FIG. 53 illustrates leapfrog and collision-merge execution, which represents an alternative embodiment for managing multiple decoder instances that reduces redundant decoding work compared to parallel execution. Exemplary convergence of decoders 5300 demonstrates the temporal progression of decoder instances as they advance through a variable-length encoded bitstream using a leapfrog strategy. In this embodiment, decoder instances are managed using a leapfrog or collision-merge strategy where decoder instances are ordered according to their current bit positions, and only the decoder instance at the earliest position is advanced at each step. When two or more decoder instances reach the same bit position, they are deemed to have collided and are merged, with redundant instances discarded. This process continues until a single decoder instance remains, which is guaranteed to be aligned with a valid codeword boundary. This embodiment provides improved performance relative to parallel execution, particularly when convergence occurs rapidly, by avoiding redundant decoding work.

At time t=0, the initial state of decoder instances is shown with four decoders positioned at staggered bit offsets within the encoded bitstream. Decoder A 5310 represents the first decoder instance at time t=0, positioned at the earliest bit offset among the initial set of decoder instances. Decoder A 5310 begins at an arbitrary target offset N and is currently at the earliest index among the decoder instances shown at time t=0. Because decoder A 5310 occupies the earliest position, it will be selected to advance first according to the leapfrog strategy. The position of decoder A 5310 at time t=0 represents the starting point from which the leapfrog and collision-merge process will unfold.

Decoder B 5320 represents the second decoder instance at time t=0, positioned one bit offset after decoder A 5310. Decoder B 5320 starts at bit offset N+1 and is currently positioned ahead of decoder A 5310 in the bitstream. Although decoder B 5320 is not at the earliest position at time t=0, it participates in the leapfrog process and may eventually advance when it becomes the earliest decoder among the remaining instances. The initial position of decoder B 5320 at time t=0 establishes one of the staggered starting points that ensures comprehensive coverage of possible bit alignments.

Decoder C 5330 represents the third decoder instance at time t=0, positioned at bit offset N+2. Decoder C 5330 is further along in the bitstream than both decoder A 5310 and decoder B 5320 at time t=0. As the leapfrog process proceeds through subsequent time steps, decoder C 5330 will advance when it becomes the earliest positioned decoder among the remaining instances. The continued presence of decoder C 5330 through multiple time steps demonstrates that this decoder does not collide with other decoders during the illustrated time period and continues to participate in the leapfrog process.

Decoder D 5340 represents the fourth decoder instance at time t=0, positioned at bit offset N+3, making it the furthest advanced decoder at the initial time. Decoder D 5340 starts ahead of decoder A 5310, decoder B 5320, and decoder C 5330 in the bitstream. The presence of decoder D 5340 at time t=0 completes the initial staggered configuration of decoder instances, with each decoder offset by one bit position from the previous decoder. This configuration ensures that all possible bit-level alignments within the maximum codeword length are represented by the initial set of decoder instances.

At time t=1, decoder instances have advanced according to the leapfrog strategy, with the earliest positioned decoder from time t=0 having decoded and progressed forward. Decoder A 5311 represents decoder A at time t=1, shown at a more advanced position in the bitstream compared to decoder A 5310 at time t=0. Decoder A 5311 has leapfrogged over other decoder instances by decoding one or more codewords and advancing its position accordingly. The leapfrogging behavior allows decoder A 5311 to potentially move past decoders that were previously ahead of it, depending on the codeword lengths encountered during decoding. At time t=1, decoder A 5311 may or may not still be the earliest positioned decoder, as its advancement depends on the specific codewords decoded.

Decoder B 5321 represents decoder B at time t=1, shown at approximately the same position as at time t=0, or possibly having advanced if it became the earliest decoder at some point between t=0 and t=1. Decoder B 5321 participates in the ordered advancement strategy where only the earliest positioned decoder advances at each step. As exemplary convergence of decoders 5300 progresses, decoder B 5321 will be selected to advance when it occupies the earliest position among remaining decoder instances. The position of decoder B 5321 at time t=1 reflects the state of this decoder after one or more leapfrog steps have been executed by other decoder instances.

Decoder C 5331 represents decoder C at time t=1. The position of decoder C 5331 at time t=1 indicates that this decoder has either remained at its previous position or has advanced if selected as the earliest decoder during the progression from t=0 to t=1. Decoder C 5331 continues to participate in the leapfrog process and remains available to advance when it becomes the earliest positioned decoder. The continued presence of decoder C 5331 at time t=1 demonstrates that no collision with other decoders has occurred at this decoder's position up to this point in exemplary convergence of decoders 5300.

Decoder D 5341 represents decoder D at time t=1. Decoder D 5341 is positioned similarly to or potentially more advanced than its position at time t=0, depending on whether decoder D 5340 was selected to advance during any steps between t=0 and t=1. The leapfrog strategy ensures that decoder D 5341 will advance when it becomes the earliest positioned decoder among the remaining instances. At time t=1, all four decoder instances remain active, indicating that no collisions have yet occurred among the decoder positions.

At time t=2, exemplary convergence of decoders 5300 shows a significant event where decoder instances have collided and merged, resulting in a reduction in the number of active decoders. Decoder A 5312 represents decoder A at time t=2, having continued to advance through the bitstream according to the leapfrog strategy. Decoder A 5312 has progressed to a more advanced position compared to decoder A 5311 at time t=1, reflecting continued decoding of codewords and forward movement through the bitstream. The position of decoder A 5312 at time t=2 shows that this decoder has not collided with any other decoder instances and continues to participate independently in the leapfrog process.

Collision 5385 represents the event at time t=2 where two decoder instances have reached the same bit position in the bitstream and are therefore merged. Collision 5385 occurs when the leapfrog advancement of one decoder causes it to arrive at the same bit position as another decoder that was previously further along in the bitstream. When collision 5385 is detected, the two or more decoder instances at the same position are deemed to have collided and are merged, with redundant instances discarded. Specifically, at time t=2, decoder B has collided with another decoder position, resulting in the elimination of decoder B from the active set of decoder instances. Collision 5385 demonstrates the merge mechanism that reduces the number of active decoder instances during exemplary convergence of decoders 5300. The detection and handling of collision 5385 is a critical aspect of the leapfrog and collision-merge strategy, as it eliminates redundant decoders that have converged to the same bit position and alignment.

The absence of decoder B at time t=2 and subsequent times confirms that collision 5385 has resulted in the elimination of this decoder instance. When two or more decoder instances reach the same bit position, they must be following the same decoding path and producing identical outputs from that point forward. Therefore, maintaining multiple decoders at the same position is redundant, and the merge operation discards all but one of the colliding instances. This reduction in the number of active decoders through collision 5385 and subsequent collisions improves computational efficiency by reducing the amount of decoding work that must be performed.

Decoder C 5332 represents decoder C at time t=2. Decoder C 5332 continues to participate in the leapfrog process after collision 5385 has eliminated decoder B. The position of decoder C 5332 at time t=2 shows that this decoder has either remained at or advanced from its previous position, and has not collided with other decoders at this point. Decoder C 5332 will continue to advance according to the leapfrog strategy when it becomes the earliest positioned decoder among the remaining instances.

Decoder D 5342 represents decoder D at time t=2. Like decoder C 5332, decoder D 5342 remains active after collision 5385 has reduced the total number of decoder instances from four to three. Decoder D 5342 participates in the ongoing leapfrog process and will advance when selected as the earliest positioned decoder. At time t=2, three decoder instances remain active, comprising decoder A 5312, decoder C 5332, and decoder D 5342.

At time t=3, exemplary convergence of decoders 5300 continues with the remaining three decoder instances advancing according to the leapfrog strategy. Decoder A 5313 represents decoder A at time t=3, having progressed further through the bitstream from its position at time t=2. Decoder A 5313 continues to decode codewords and advance through leapfrog steps, potentially moving past other decoder instances depending on the codeword lengths encountered. The position of decoder A 5313 at time t=3 demonstrates continued participation in the leapfrog process as the system converges toward a single remaining decoder.

Decoder C 5333 represents decoder C at time t=3. Decoder C 5333 has advanced or maintained its position from time t=2, continuing to participate in the leapfrog and collision-merge process. The ongoing presence of decoder C 5333 at time t=3 indicates that no additional collisions involving this decoder have occurred between t=2 and t=3. Decoder C 5333 remains available to advance when it becomes the earliest positioned decoder among the remaining instances.

Decoder D 5343 represents decoder D at time t=3. Decoder D 5343 continues to participate in the leapfrog process alongside decoder A 5313 and decoder C 5333. The position of decoder D 5343 at time t=3 reflects advancement from its previous position according to the leapfrog strategy. At time t=3, three decoder instances remain active, demonstrating that the convergence process is still underway and additional collisions may occur as decoders continue to advance and potentially merge.

The ellipsis between time t=3 and time t=N indicates that additional time steps occur during exemplary convergence of decoders 5300 as the leapfrog and collision-merge process continues. During these intermediate time steps, the remaining decoder instances continue to advance according to the leapfrog strategy, with the earliest positioned decoder advancing at each step. Additional collisions may occur during these intermediate steps, further reducing the number of active decoder instances. The progression from three active decoders at time t=3 to single decoder remains 5350 at time t=N involves continued leapfrogging and merging until only one decoder instance survives.

At time t=N, exemplary convergence of decoders 5300 reaches its conclusion with single decoder remains 5350. Single decoder remains 5350 represents the final state of the leapfrog and collision-merge process, where all decoder instances except one have been eliminated through collisions and mergers. Single decoder remains 5350 is guaranteed to be aligned with a valid codeword boundary, as this decoder has survived the competitive advancement and collision process. When single decoder remains 5350 is the only active decoder, the process terminates because further advancement cannot lead to additional collisions. The position of single decoder remains 5350 in the bitstream marks a valid codeword boundary from which subsequent decoding operations can proceed with confidence in correctness.

Leapfrog: earliest decoder advances 5360 describes the core operational principle of the execution strategy illustrated in exemplary convergence of decoders 5300. According to this principle, decoder instances are ordered according to their current bit positions in the bitstream, and only the decoder instance at the earliest position is advanced at each step. The leapfrogging behavior enables the earliest decoder to decode one or more codewords and advance its position, potentially moving past decoders that were previously further along in the bitstream. This selective advancement based on position ordering ensures that decoders make progress toward convergence while avoiding redundant decoding work. The term leapfrog reflects the fact that an earlier decoder can jump over later decoders by decoding longer codewords, similar to the children's game where players leap over one another. Leapfrog: earliest decoder advances 5360 is applied repeatedly throughout exemplary convergence of decoders 5300 until convergence is achieved.

Merge: decoders at same position combine 5361 describes the collision and merger mechanism that reduces the number of active decoder instances during exemplary convergence of decoders 5300. When two or more decoder instances reach the same bit position in the bitstream as a result of leapfrog advancement, merge: decoders at same position combine 5361 is triggered. The decoders at the same position are deemed to have collided, and redundant instances are discarded, with only one decoder instance retained at that position. This merge operation is justified because decoders at the same bit position must be following identical decoding paths and producing identical outputs from that point forward, making it unnecessary to maintain multiple instances. Merge: decoders at same position combine 5361 reduces redundant decoding work and improves computational efficiency by eliminating decoders that have converged to the same alignment. The merge operation is illustrated at time t=2 where collision 5385 results in the elimination of decoder B.

Convergence: single decoder indicates valid boundary 5362 describes the termination condition and correctness guarantee of the leapfrog and collision-merge execution strategy. When the process reaches the state where single decoder remains 5350 at time t=N, convergence: single decoder indicates valid boundary 5362 is achieved. The remaining single decoder is guaranteed to be correctly aligned with a valid codeword boundary in the bitstream. This guarantee arises from the systematic exploration of all possible starting alignments through the initial staggered decoder configuration, combined with the competitive advancement and merger process that eliminates incorrectly aligned decoders. Convergence: single decoder indicates valid boundary 5362 signals that random access decoding has successfully recovered from the arbitrary starting offset and identified a valid codeword boundary from which correct sequential decoding can proceed. The identification of a valid boundary through single decoder remains 5350 provides the same correctness guarantee as agreement-based detection in parallel execution embodiments, but achieves this result through a different execution strategy.

FIG. 53 demonstrates that the leapfrog and collision-merge execution strategy provides an efficient alternative to parallel execution by reducing redundant decoding work. While parallel execution advances all decoder instances simultaneously, exemplary convergence of decoders 5300 shows that selective advancement according to leapfrog: earliest decoder advances 5360 minimizes the total amount of decoding performed. The progressive reduction in active decoders through merge: decoders at same position combine 5361, as demonstrated by collision 5385 at time t=2, further improves efficiency by eliminating redundant instances as soon as they are detected. The final state of single decoder remains 5350 and convergence: single decoder indicates valid boundary 5362 at time t=N confirms that the leapfrog and collision-merge strategy successfully achieves random access decoding with improved performance characteristics relative to parallel execution, particularly when convergence occurs rapidly.

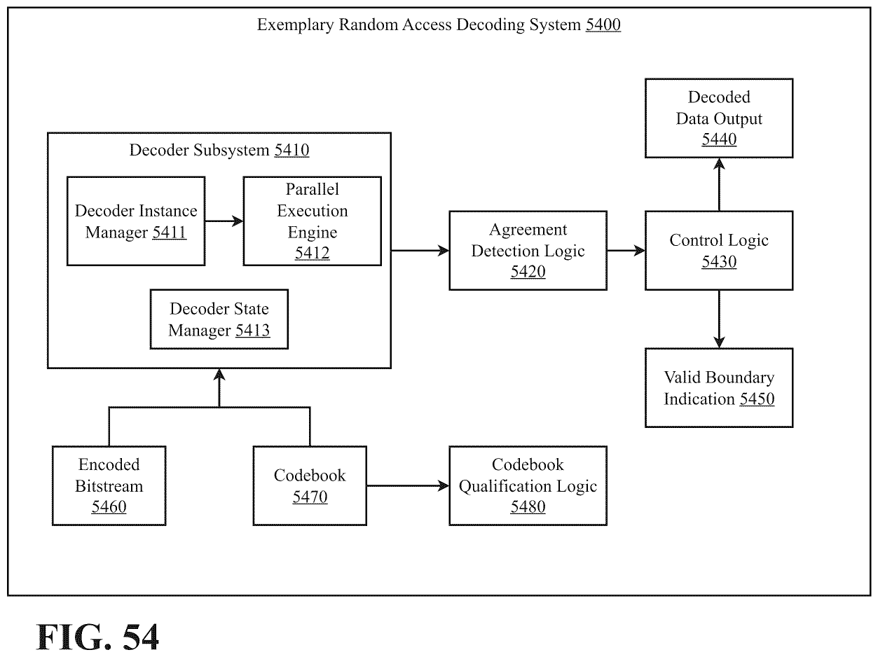

FIG. 54 illustrates a system architecture for random access decoding that enables decoding to begin at an arbitrary bit offset within a variable-length encoded bitstream and to converge rapidly to a valid codeword boundary. Exemplary random access decoding system 5400 represents a comprehensive system embodiment that integrates multiple components to perform random access decoding operations. Exemplary random access decoding system 5400 may be implemented in software, hardware, or a combination thereof, and may operate on stored or streaming encoded data. The architecture of exemplary random access decoding system 5400 demonstrates how decoder subsystem 5410, agreement detection logic 5420, control logic 5430, and codebook qualification logic 5480 interact to process encoded bitstream 5460 using codebook 5470, ultimately producing decoded data output 5440 and valid boundary indication 5450. This system architecture enables random access decoding without requiring modification of the encoded data, without inserting synchronization markers, and without sacrificing the efficiency benefits of variable-length encoding.

Decoder subsystem 5410 represents the core component of exemplary random access decoding system 5400 that manages and executes multiple decoder instances to achieve rapid convergence to valid codeword boundaries. Decoder subsystem 5410 is configured to initialize multiple decoder instances at staggered bit offsets within encoded bitstream 5460 and to advance these decoder instances according to codebook 5470. Decoder subsystem 5410 comprises decoder instance manager 5411, parallel execution engine 5412, and decoder state manager 5413, which work together to implement various decoder execution strategies including parallel execution, sequential interleaved execution, and leapfrog and collision-merge execution. Decoder subsystem 5410 receives encoded bitstream 5460 and codebook 5470 as inputs and produces decoded symbol sequences that are provided to agreement detection logic 5420 for convergence analysis.

Decoder instance manager 5411 represents the component within decoder subsystem 5410 that is responsible for creating, tracking, and terminating individual decoder instances. Given an arbitrary target offset N within encoded bitstream 5460, decoder instance manager 5411 initializes a plurality of decoder instances at staggered bit offsets N, N+1, N+2, through N+L−1, where L is the maximum codeword length associated with codebook 5470. Decoder instance manager 5411 maintains metadata about each active decoder instance, including its current bit position, decoding state, and decoded output buffer. Decoder instance manager 5411 responds to signals from control logic 5430 to terminate decoder instances when convergence has been detected by agreement detection logic 5420. Decoder instance manager 5411 may implement resource management policies such as limiting the maximum number of active decoder instances, prioritizing certain decoder instances, or terminating instances early based on heuristic indicators.

Parallel execution engine 5412 represents the component within decoder subsystem 5410 that implements concurrent execution of multiple decoder instances. Parallel execution engine 5412 enables all decoder instances managed by decoder instance manager 5411 to be executed in parallel, with each decoder instance advancing independently through encoded bitstream 5460 and decoding symbols according to codebook 5470. Parallel execution engine 5412 may be implemented using multiple processor cores, vectorized instructions, graphics processing units, or other forms of parallel hardware. In parallel execution mode, parallel execution engine 5412 coordinates the simultaneous advancement of all decoder instances without requiring communication or synchronization among individual decoders. Parallel execution engine 5412 provides conceptual simplicity and minimizes convergence latency, at the cost of increased concurrent resource usage. In alternative embodiments where sequential interleaved execution or leapfrog execution is employed, parallel execution engine 5412 may be replaced or supplemented by execution engines that implement these alternative strategies.

Decoder state manager 5413 represents the component within decoder subsystem 5410 that maintains and updates the decoding state of each active decoder instance. Decoder state manager 5413 tracks the current bit position of each decoder instance within encoded bitstream 5460, the decoded symbols produced by each instance, and any internal state required for applying codebook 5470 to interpret bit sequences as codewords. For each decoder instance, decoder state manager 5413 maintains information such as the starting offset, the current read position, the buffer of decoded symbols, and any prefix bits that are pending interpretation. Decoder state manager 5413 provides decoder state information to agreement detection logic 5420 to enable comparison of decoded outputs across decoder instances. Decoder state manager 5413 also supports the termination of decoder instances by preserving the final state of the correctly aligned decoder for subsequent use in producing decoded data output 5440.

Agreement detection logic 5420 represents the component of exemplary random access decoding system 5400 that is configured to identify convergence to a valid codeword boundary by monitoring and comparing decoded outputs from multiple decoder instances. Agreement detection logic 5420 receives decoded symbol sequences from decoder subsystem 5410, specifically from decoder state manager 5413, and evaluates whether these outputs agree with each other. Agreement detection logic 5420 detects when all decoder instances produce identical decoded symbol sequences over a defined portion of encoded bitstream 5460. The point at which agreement is achieved corresponds to a bit position that is guaranteed to be a valid codeword boundary. Agreement detection logic 5420 may evaluate agreement continuously as new decoded symbols are produced, or may perform periodic agreement checks at defined intervals. In some embodiments, agreement detection logic 5420 requires that agreement persists over a minimum number of decoded symbols or bits to reduce the likelihood of false positives. When agreement is detected, agreement detection logic 5420 signals control logic 5430 to produce valid boundary indication 5450 and to initiate termination of decoder instances.

Control logic 5430 represents the component of exemplary random access decoding system 5400 that is configured to terminate decoder instances upon convergence and to coordinate the overall operation of the system. Control logic 5430 receives signals from agreement detection logic 5420 indicating that convergence has been achieved, and in response, directs decoder instance manager 5411 to terminate decoder instances that are no longer needed. Control logic 5430 generates valid boundary indication 5450 to signal external components or applications that a valid codeword boundary has been identified. Control logic 5430 also orchestrates the production of decoded data output 5440 by directing decoder subsystem 5410 to continue decoding from the identified boundary. Control logic 5430 may implement various control policies such as selecting execution strategies, adjusting agreement criteria based on codebook characteristics, or managing resource allocation across decoder instances. Control logic 5430 provides the high-level coordination that enables exemplary random access decoding system 5400 to function as an integrated whole.

Decoded data output 5440 represents the decoded symbols produced by exemplary random access decoding system 5400 after convergence to a valid codeword boundary has been achieved. Decoded data output 5440 comprises the sequence of decoded symbols that result from decoding encoded bitstream 5460 from the identified boundary position. Once agreement detection logic 5420 has identified a valid codeword boundary and control logic 5430 has signaled convergence through valid boundary indication 5450, decoder subsystem 5410 may continue decoding from that boundary to produce decoded data output 5440. Decoded data output 5440 is guaranteed to be correct because it is produced from a verified codeword boundary identified through the agreement-based detection mechanism. Decoded data output 5440 may be provided to applications that require random access to specific portions of encoded bitstream 5460, such as search operations, partial decoding, database queries, or streaming media applications.

Valid boundary indication 5450 represents the signal or output produced by exemplary random access decoding system 5400 when a valid codeword boundary has been identified. Valid boundary indication 5450 is generated by control logic 5430 in response to agreement detection logic 5420 signaling that convergence has been achieved. Valid boundary indication 5450 may include information such as the bit position of the identified boundary within encoded bitstream 5460, the confidence level or number of agreed decoder instances, and metadata about the convergence process such as the number of bits decoded before convergence. Valid boundary indication 5450 enables applications to verify that random access decoding has been successfully completed and to proceed with using decoded data output 5440 with confidence in its correctness. Valid boundary indication 5450 provides a reliable mechanism for confirming successful random access decoding without requiring external verification or alignment information.

Encoded bitstream 5460 represents the input to exemplary random access decoding system 5400 and comprises a variable-length encoded bitstream formed by concatenating codewords of varying bit lengths. Encoded bitstream 5460 is a sequence of bits where each codeword represents a symbol or sourceblock and is drawn from a prefix-free codebook. Huffman codes and their variants are representative examples of encodings used in encoded bitstream 5460. Encoded bitstream 5460 may be stored in memory, read from storage devices, or received as streaming data from network sources. Exemplary random access decoding system 5400 enables decoding to begin at an arbitrary bit offset within encoded bitstream 5460, rather than requiring sequential decoding from the beginning. Encoded bitstream 5460 is provided to decoder subsystem 5410 for decoding operations and is not modified by the random access decoding process, preserving the original compression efficiency and encoding format.

Codebook 5470 represents the prefix-free codebook that defines the mapping between binary codewords and their corresponding decoded symbols. Codebook 5470 contains the information necessary for decoder subsystem 5410 to interpret bit sequences in encoded bitstream 5460 as codewords corresponding to symbols or sourceblocks. Codebook 5470 may be a canonical Huffman codebook, a non-canonical Huffman codebook, or another type of prefix-free variable-length code. Codebook 5470 includes information such as codeword lengths, bit patterns, and symbol mappings that enable decoding operations. The structural properties of codebook 5470, particularly the maximum codeword length L, determine the number of decoder instances that must be initialized by decoder instance manager 5411. Codebook 5470 may be evaluated by codebook qualification logic 5480 to determine whether it satisfies criteria for rapid convergence during random access decoding. Codebook 5470 is shared read-only by all decoder instances within decoder subsystem 5410, ensuring that all decoders apply consistent decoding rules.

Codebook qualification logic 5480 represents an optional component of exemplary random access decoding system 5400 that is configured to classify codebooks as BAD or NOT BAD based on structural properties that affect convergence behavior. Codebook qualification logic 5480 analyzes codebook 5470 to determine whether it exhibits structural properties that prevent or significantly inhibit convergence when decoding is initiated from arbitrary bit offsets. A BAD codebook is defined as a variable-length, prefix-free codebook that satisfies structural criteria such as having a greatest common divisor of codeword lengths greater than one, or being expressible as a recursive composition of BAD codebooks. A NOT BAD codebook is a codebook that does not satisfy the criteria of a BAD codebook and that enables high-probability rapid convergence under random access decoding. Codebook qualification logic 5480 may evaluate codebook 5470 prior to deployment by computing the greatest common divisor of codeword lengths and checking for recursive composition patterns. In some embodiments, codebook qualification logic 5480 rejects or modifies codebooks classified as BAD, or provides warnings to control logic 5430 that convergence may not be reliable. Codebook qualification logic 5480 enables system designers to trade off encoding efficiency, codebook structure, and random access performance in a controlled manner, without relying on ad hoc heuristics or undocumented assumptions.

FIG. 54 demonstrates how the components of exemplary random access decoding system 5400 interact to enable random access decoding within variable-length encoded bitstreams. Decoder subsystem 5410, comprising decoder instance manager 5411, parallel execution engine 5412, and decoder state manager 5413, processes encoded bitstream 5460 using codebook 5470 to generate decoded outputs that are analyzed by agreement detection logic 5420. When convergence is detected, control logic 5430 coordinates the termination of decoder instances and produces valid boundary indication 5450 and decoded data output 5440. Codebook qualification logic 5480 provides optional validation of codebook 5470 to ensure predictable convergence behavior. The architecture shown enables efficient random access, search, and partial decoding operations over variable-length encoded data while preserving the efficiency and flexibility benefits of variable-length encoding and remaining compatible with existing encoding systems.

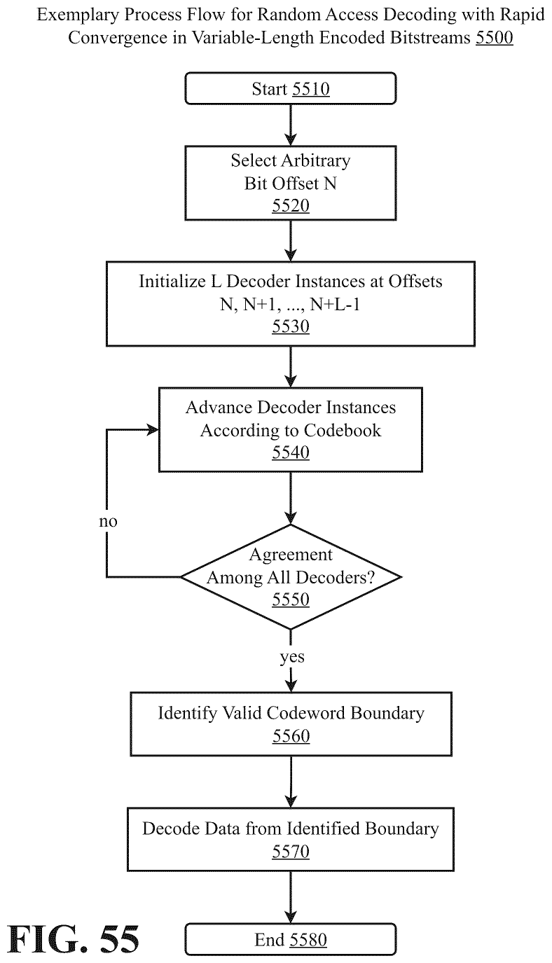

FIG. 55 illustrates a method flowchart for random access decoding that enables decoding to begin at an arbitrary bit offset within a variable-length encoded bitstream and to converge rapidly to a valid codeword boundary. Exemplary process flow for random access decoding with rapid convergence in variable-length encoded bitstreams 5500 represents a computer-implemented method that may be executed by one or more processors to perform random access decoding operations. Exemplary process flow for random access decoding with rapid convergence in variable-length encoded bitstreams 5500 comprises a sequence of steps that initialize multiple decoder instances at staggered bit offsets, advance these instances according to a codebook, detect agreement among decoded outputs, identify a valid codeword boundary based on detected agreement, and decode data from the identified boundary. This method enables correct random access decoding without requiring modification of encoded bitstreams, without inserting synchronization markers, and without sacrificing compression efficiency.

Start 5510 represents the entry point of exemplary process flow for random access decoding with rapid convergence in variable-length encoded bitstreams 5500. Start 5510 indicates the beginning of method execution, which may be triggered by a request to decode data from a specific location within a variable-length encoded bitstream, by a search operation that has identified a candidate match location, or by any application that requires random access to encoded data. When exemplary process flow for random access decoding with rapid convergence in variable-length encoded bitstreams 5500 begins at start 5510, a system or processor initiating the method may have already received or identified a variable-length encoded bitstream and an associated codebook, and may have determined an approximate or desired bit offset for random access decoding. From start 5510, execution proceeds to select arbitrary bit offset N 5520.

Select arbitrary bit offset N 5520 represents the step of selecting an arbitrary bit position within a variable-length encoded bitstream from which random access decoding will commence. Select arbitrary bit offset N 5520 may involve receiving an offset value from an external application, computing an offset based on a desired byte or symbol position, identifying an offset from search results or index structures, or accepting an offset provided by a user or higher-level system component. The offset N selected at select arbitrary bit offset N 5520 is arbitrary in the sense that it is not known a priori to coincide with a valid codeword boundary in the encoded bitstream. The arbitrary nature of offset N means that decoding initiated directly from this position would likely produce incorrect decoded symbols until convergence to a valid codeword boundary occurs. Select arbitrary bit offset N 5520 establishes the target location for random access decoding and defines the reference point from which staggered decoder instances will be initialized. After selecting arbitrary bit offset N at select arbitrary bit offset N 5520, execution proceeds to initialize L decoder instances at offsets N, N+1, through N+L−1 5530.

Initialize L decoder instances at offsets N, N+1, through N+L−1 5530 represents the step of creating a plurality of decoder instances at staggered bit offsets to ensure comprehensive coverage of all possible starting alignments within the maximum codeword length. At initialize L decoder instances at offsets N, N+1, through N+L−1 5530, L decoder instances are created, where L is the maximum codeword length associated with the codebook being used for decoding. Each decoder instance is initialized at a consecutive bit offset starting from the arbitrary offset N selected at select arbitrary bit offset N 5520. Specifically, a first decoder instance is initialized at offset N, a second decoder instance is initialized at offset N+1, a third decoder instance is initialized at offset N+2, and so forth, continuing through a final decoder instance initialized at offset N+L−1. This staggered initialization pattern ensures that all possible bit-level alignments within one maximum codeword length are represented by the plurality of decoder instances. By initializing L decoder instances at consecutive bit offsets spanning from N to N+L−1, the method guarantees that at least one decoder instance must begin at a valid codeword boundary or at a position that will rapidly converge to correct decoding. Initialize L decoder instances at offsets N, N+1, through N+L−1 5530 may involve allocating memory for decoder state structures, setting initial read positions, and preparing each instance to begin decoding operations. After initializing decoder instances at initialize L decoder instances at offsets N, N+1, through N+L−1 5530, execution proceeds to advance decoder instances according to codebook 5540.

Advance decoder instances according to codebook 5540 represents the step of executing decoding operations for the plurality of decoder instances using a prefix-free codebook. At advance decoder instances according to codebook 5540, each decoder instance processes bit sequences from the variable-length encoded bitstream starting from its assigned offset and interprets these bit sequences as codewords according to the codebook. Advance decoder instances according to codebook 5540 may be implemented using parallel execution where all decoder instances advance simultaneously, sequential interleaved execution where decoder instances advance incrementally in turns, or leapfrog execution where the decoder instance at the earliest bit position advances at each step. Each decoder instance applies the prefix-free property of the codebook to identify codeword boundaries and decode symbols, producing a sequence of decoded symbols as it advances through the bitstream. The advancement at advance decoder instances according to codebook 5540 continues until a sufficient number of symbols have been decoded to enable reliable agreement detection. During advancement, each decoder instance maintains its current bit position, decoded symbol buffer, and any internal state required for codebook interpretation. After advancing decoder instances at advance decoder instances according to codebook 5540, execution proceeds to agreement among all decoders 5550 to evaluate whether convergence has been achieved.

Agreement among all decoders 5550 represents a decision point in exemplary process flow for random access decoding with rapid convergence in variable-length encoded bitstreams 5500 where decoded outputs from all decoder instances are compared to determine whether convergence to a valid codeword boundary has occurred. At agreement among all decoders 5550, decoded symbol sequences produced by the decoder instances during advance decoder instances according to codebook 5540 are evaluated to detect whether all instances produce identical decoded symbol sequences over a defined portion of the bitstream. Agreement among all decoders 5550 implements comparison logic that identifies when the decoded outputs agree, which indicates that decoder instances have converged to the same codeword alignment. In some embodiments, agreement among all decoders 5550 requires that agreement persists over a minimum number of decoded symbols or bits to reduce the likelihood of false positives. The evaluation at agreement among all decoders 5550 determines whether convergence has been achieved with sufficient confidence to proceed. If agreement among all decoders 5550 determines that agreement has not yet been achieved, execution returns to advance decoder instances according to codebook 5540 to continue decoding and generate additional decoded symbols for comparison. If agreement among all decoders 5550 determines that agreement has been achieved, execution proceeds to identify valid codeword boundary 5560.

The loop between advance decoder instances according to codebook 5540 and agreement among all decoders 5550 continues iteratively until convergence is detected. During each iteration of this loop, decoder instances make additional progress through the bitstream, decoding more symbols and advancing their positions. The negative branch from agreement among all decoders 5550 back to advance decoder instances according to codebook 5540 ensures that the method continues execution until agreement is achieved. For NOT BAD codebooks and data generated by realistic stochastic sources, this loop typically terminates after a relatively small number of iterations, with expected convergence distances on the order of O(M²) where M is the average codeword length. The iterative nature of the loop accommodates codebooks and data patterns where convergence may take longer, while ensuring that the method eventually identifies a valid codeword boundary.

Identify valid codeword boundary 5560 represents the step of determining the bit position within the variable-length encoded bitstream that corresponds to a valid codeword boundary, based on the detected agreement among decoder instances. When execution reaches identify valid codeword boundary 5560 from agreement among all decoders 5550, the agreement condition has been satisfied, indicating that all decoder instances have converged to the same codeword alignment. At identify valid codeword boundary 5560, the method determines the specific bit position where convergence occurred by analyzing the state of the agreed decoder instances. Because all decoder instances are producing identical decoded outputs from the point of agreement forward, the bit position at which this agreement begins corresponds to a valid codeword boundary. Identify valid codeword boundary 5560 may record metadata about the identified boundary such as its bit offset within the bitstream, the confidence level or number of agreed symbols, and the convergence distance from the arbitrary starting offset N. The valid codeword boundary identified at identify valid codeword boundary 5560 is guaranteed to be correct because agreement among all decoder instances initialized at all possible alignments within the maximum codeword length can only occur when decoders are following the same correct decoding path. After identifying the valid codeword boundary at identify valid codeword boundary 5560, execution proceeds to decode data from identified boundary 5570.

Decode data from identified boundary 5570 represents the step of performing sequential decoding operations from the valid codeword boundary identified at identify valid codeword boundary 5560 to produce correctly decoded output data. At decode data from identified boundary 5570, a decoder instance continues decoding from the verified codeword boundary position, applying the codebook to interpret bit sequences and generate decoded symbols. Because the boundary identified at identify valid codeword boundary 5560 is guaranteed to be a valid codeword boundary, the decoded data produced at decode data from identified boundary 5570 is guaranteed to be correct. Decode data from identified boundary 5570 may decode a predetermined number of symbols, decode until a specific stopping condition is met, decode until the end of the bitstream is reached, or decode a segment of data required by the application that initiated the random access decoding request. The decoded data produced at decode data from identified boundary 5570 may be provided to applications for purposes such as search result verification, partial content extraction, database query results, or media playback from arbitrary positions. Decode data from identified boundary 5570 may reuse one of the decoder instances that participated in the convergence process, or may initialize a new decoder instance at the identified boundary for clean-state decoding. After decoding data at decode data from identified boundary 5570, execution proceeds to end 5580.

End 5580 represents the termination point of exemplary process flow for random access decoding with rapid convergence in variable-length encoded bitstreams 5500. End 5580 indicates that the method has successfully completed random access decoding by identifying a valid codeword boundary through agreement-based detection and producing decoded data from that boundary. When execution reaches end 5580, the random access decoding operation initiated at start 5510 has been completed, and decoded data has been produced with correctness guarantees. At end 5580, the method may clean up resources such as terminating remaining decoder instances, deallocating memory used for decoder state, and returning control to the calling application. End 5580 may also involve reporting metrics about the random access decoding operation such as the convergence distance, the number of iterations required, the number of symbols decoded, or performance measurements. The completion at end 5580 confirms that random access decoding has been achieved without modification of the encoded bitstream, without insertion of synchronization markers, and while preserving the compression efficiency of the variable-length encoding.

FIG. 55 demonstrates the sequential flow of operations in exemplary process flow for random access decoding with rapid convergence in variable-length encoded bitstreams 5500, beginning with start 5510 and progressing through select arbitrary bit offset N 5520, initialize L decoder instances at offsets N, N+1, through N+L−1 5530, an iterative loop comprising advance decoder instances according to codebook 5540 and agreement among all decoders 5550, followed by identify valid codeword boundary 5560, decode data from identified boundary 5570, and concluding with end 5580. This method embodiment provides a concrete algorithm for implementing random access decoding with rapid convergence, enabling applications to access arbitrary portions of variable-length encoded data without requiring sequential decoding from the beginning of the bitstream. The method illustrated achieves correctness guarantees through the systematic initialization of staggered decoder instances at initialize L decoder instances at offsets N, N+1, through N+L−1 5530, the iterative advancement and agreement detection loop between advance decoder instances according to codebook 5540 and agreement among all decoders 5550, and the verification of convergence before proceeding to decode data from identified boundary 5570. The method transforms variable-length encoded data from a sequential-access format into one that supports efficient random access, search, and partial decoding operations while maintaining compatibility with existing encoding formats and preserving compression efficiency.

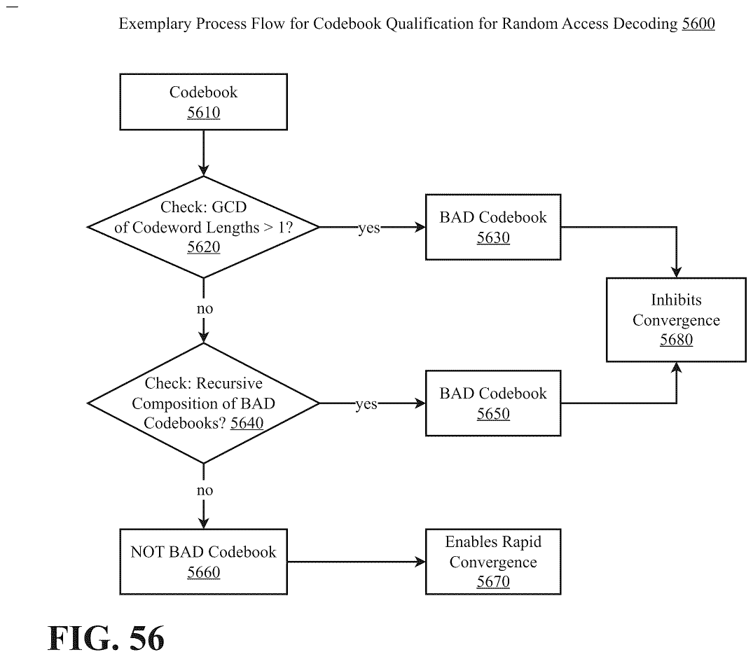

FIG. 56 illustrates a decision tree for codebook qualification that classifies variable-length prefix-free codebooks based on structural properties that affect convergence behavior under random access decoding. Exemplary process flow for codebook qualification for random access decoding 5600 represents a method for evaluating codebooks prior to or during deployment to determine whether they satisfy criteria for reliable convergence when decoding is initiated from arbitrary bit offsets. Exemplary process flow for codebook qualification for random access decoding 5600 enables system designers to identify codebooks that are suitable for random access decoding and to reject, modify, or flag codebooks that exhibit structural properties that prevent or significantly inhibit convergence. By explicitly qualifying codebooks according to their convergence properties, the process illustrated provides predictable and reliable random access decoding behavior without relying on ad hoc heuristics or undocumented assumptions.

Codebook 5610 represents a variable-length, prefix-free codebook that is being evaluated for suitability in random access decoding applications. Codebook 5610 contains a mapping between binary codewords of varying lengths and their corresponding decoded symbols. Codebook 5610 may be a canonical Huffman codebook, a non-canonical Huffman codebook, or another type of prefix-free variable-length code. The structural properties of codebook 5610, particularly the lengths of its codewords and any compositional patterns, determine whether codebook 5610 will enable rapid convergence when used for random access decoding. Codebook 5610 serves as the input to exemplary process flow for codebook qualification for random access decoding 5600, and the qualification process analyzes properties of codebook 5610 to classify it as either BAD codebook 5630, BAD codebook 5650, or NOT BAD codebook 5660. From codebook 5610, the qualification process proceeds to check: GCD of codeword lengths >1 5620.

Check: GCD of codeword lengths >1 5620 represents the first decision point in exemplary process flow for codebook qualification for random access decoding 5600, where the greatest common divisor of all codeword lengths in codebook 5610 is evaluated. At check: GCD of codeword lengths >1 5620, the lengths of all codewords in codebook 5610 are examined, and the greatest common divisor of these lengths is computed. If the greatest common divisor is greater than one, this indicates a structural property that prevents reliable convergence under random access decoding. When all codewords in codebook 5610 have lengths that share a common divisor greater than one, decoding initiated at misaligned offsets may cycle indefinitely among incorrect alignments, preventing convergence to a valid codeword boundary. Check: GCD of codeword lengths >1 5620 implements a mathematical test that can be performed efficiently by extracting codeword length information from codebook 5610 and computing the greatest common divisor using standard algorithms. If check: GCD of codeword lengths >1 5620 determines that the greatest common divisor is greater than one, the qualification process branches to BAD codebook 5630 via the yes branch. If check: GCD of codeword lengths >1 5620 determines that the greatest common divisor is equal to one, the qualification process proceeds to check: recursive composition of BAD codebooks 5640 via the no branch.

BAD codebook 5630 represents the classification result when codebook 5610 is determined to have a greatest common divisor of codeword lengths greater than one at check: GCD of codeword lengths >1 5620. When the qualification process reaches BAD codebook 5630, codebook 5610 is classified as a BAD codebook that exhibits structural properties preventing reliable convergence under random access decoding. A BAD codebook is defined as a variable-length, prefix-free codebook that satisfies one or more structural criteria that prevent or significantly inhibit convergence when decoding is initiated from arbitrary bit offsets. Codebook 5610 classified as BAD codebook 5630 may cause decoder instances to fail to converge or to produce ambiguous agreement signals, making it unsuitable for use with random access decoding techniques. From BAD codebook 5630, the consequence is inhibits convergence 5680, indicating that codebook 5610 should be rejected, modified, or flagged as unsuitable for random access decoding.

Check: recursive composition of BAD codebooks 5640 represents the second decision point in exemplary process flow for codebook qualification for random access decoding 5600, reached when codebook 5610 has a greatest common divisor of codeword lengths equal to one. At check: recursive composition of BAD codebooks 5640, the structure of codebook 5610 is analyzed to determine whether it can be expressed as a recursive composition of one or more BAD codebooks. Check: recursive composition of BAD codebooks 5640 evaluates whether codebook 5610 has a compositional form where one BAD codebook is used to structure another codebook, creating a hierarchical encoding that inherits the non-convergent properties of the constituent BAD codebook. The recursive composition evaluation at check: recursive composition of BAD codebooks 5640 may involve analyzing the construction method of codebook 5610, examining whether symbols are encoded using a two-level scheme where a primary BAD codebook is applied and then modified or extended by a secondary codebook, or detecting other patterns of hierarchical composition. If check: recursive composition of BAD codebooks 5640 determines that codebook 5610 does exhibit recursive composition of BAD codebooks, the qualification process branches to BAD codebook 5650 via the yes branch. If check: recursive composition of BAD codebooks 5640 determines that codebook 5610 does not exhibit such composition, the qualification process proceeds to NOT BAD codebook 5660 via the no branch.

BAD codebook 5650 represents the classification result when codebook 5610 is determined to exhibit recursive composition of BAD codebooks at check: recursive composition of BAD codebooks 5640. When the qualification process reaches BAD codebook 5650, codebook 5610 is classified as BAD even though its greatest common divisor of codeword lengths is equal to one. BAD codebook 5650 indicates that codebook 5610 has a compositional structure that inherits convergence-inhibiting properties from constituent BAD codebooks. Like BAD codebook 5630, codebook 5610 classified as BAD codebook 5650 may cause decoder instances to fail to converge or to produce ambiguous agreement signals. From BAD codebook 5650, the consequence inhibits convergence 5680, indicating that codebook 5610 should not be used for random access decoding without modification or replacement.

NOT BAD codebook 5660 represents the classification result when codebook 5610 passes both check: GCD of codeword lengths >1 5620 and check: recursive composition of BAD codebooks 5640 without being classified as BAD. When the qualification process reaches NOT BAD codebook 5660, codebook 5610 is determined to be suitable for random access decoding with reliable convergence properties. A NOT BAD codebook is defined as a variable-length, prefix-free codebook that does not satisfy the criteria of a BAD codebook and that enables high-probability rapid convergence to a valid codeword boundary under random access decoding. Canonical Huffman codebooks with codeword lengths having a greatest common divisor of one constitute a provable subclass of NOT BAD codebooks. Other non-canonical Huffman variants and related prefix-free encodings may also be NOT BAD provided they lack the structural defects associated with BAD codebooks. Codebook 5610 classified as NOT BAD codebook 5660 is approved for use in random access decoding systems. From NOT BAD codebook 5660, the consequence enables rapid convergence 5670, indicating that codebook 5610 provides the structural properties necessary for reliable and efficient random access decoding.

Enables rapid convergence 5670 represents the favorable outcome when codebook 5610 is classified as NOT BAD codebook 5660 through exemplary process flow for codebook qualification for random access decoding 5600. Enables rapid convergence 5670 indicates that codebook 5610 will support high-probability rapid convergence when used for random access decoding. For NOT BAD codebooks and data generated by realistic stochastic sources, the expected number of bits that must be decoded before convergence occurs is on the order of O(M²), where M is the average length of codewords in codebook 5610. This expected convergence distance is typically small relative to the size of encoded files or streams, making random access decoding practical for applications such as search, partial decoding, and database queries. Enables rapid convergence 5670 confirms that codebook 5610 can be safely deployed in random access decoding systems with confidence that decoder instances will converge to valid codeword boundaries within a reasonable number of decoding steps. The qualification result of enables rapid convergence 5670 provides system designers with assurance that codebook 5610 satisfies the necessary structural criteria for reliable random access decoding performance.

Inhibits convergence 5680 represents the unfavorable outcome when codebook 5610 is classified as BAD codebook 5630 or BAD codebook 5650 through exemplary process flow for codebook qualification for random access decoding 5600. Inhibits convergence 5680 indicates that codebook 5610 exhibits structural properties that prevent or significantly inhibit convergence when decoding is initiated from arbitrary bit offsets. Codebook 5610 with the consequence of inhibits convergence 5680 may cause incorrect decoding to persist indefinitely or may prevent reliable detection of correctness through agreement among decoder instances. In some embodiments, codebooks that result in inhibits convergence 5680 are rejected and not deployed for random access decoding. In other embodiments, such codebooks may be modified to eliminate the structural defects, such as by adding or removing codewords to ensure the greatest common divisor of codeword lengths equals one, or by restructuring the codebook to eliminate recursive composition patterns. In still other embodiments, codebooks that inhibit convergence 5680 may be flagged with warnings so that system operators are aware of potential reliability issues. The identification of inhibits convergence 5680 enables proactive quality control and prevents deployment of codebooks that would result in unreliable or inefficient random access decoding performance.

FIG. 56 demonstrates that exemplary process flow for codebook qualification for random access decoding 5600 provides a systematic method for classifying codebook 5610 based on two primary structural criteria evaluated at check: GCD of codeword lengths >1 5620 and check: recursive composition of BAD codebooks 5640. The decision tree structure illustrates that codebook 5610 will be classified as BAD codebook 5630 if the greatest common divisor test fails, or as BAD codebook 5650 if the recursive composition test fails, or as NOT BAD codebook 5660 if both tests pass. The consequences of enables rapid convergence 5670 for NOT BAD codebooks and inhibits convergence 5680 for BAD codebooks provide clear guidance on deployment decisions. By explicitly qualifying codebooks according to their convergence properties, the process enables system designers to trade off encoding efficiency, codebook structure, and random access performance in a controlled manner. The qualification method illustrated ensures that only codebooks with favorable convergence properties are used for random access decoding, providing predictable and reliable performance without relying on undocumented assumptions about codebook behavior.

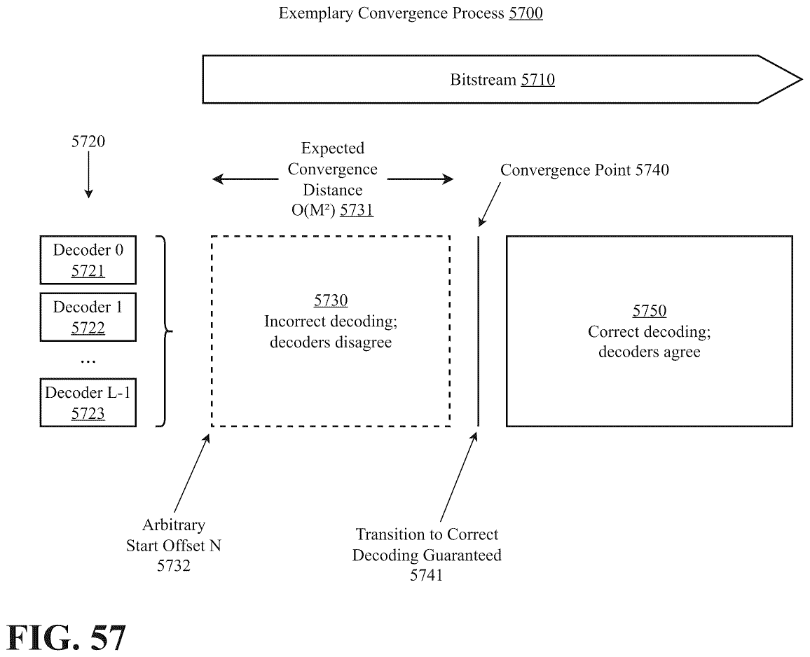

FIG. 57 illustrates the temporal progression of decoder convergence showing the transition from incorrect decoding to correct decoding as multiple decoder instances advance through a variable-length encoded bitstream. Exemplary convergence process 5700 demonstrates how decoder instances initialized at staggered bit offsets initially produce divergent decoded outputs that eventually converge to agreement, marking the identification of a valid codeword boundary. Exemplary convergence process 5700 provides a visual representation of the convergence behavior that enables random access decoding, showing the progression from an arbitrary starting position through a region of disagreement to a convergence point where all decoders begin producing identical outputs. This illustration captures the fundamental mechanism by which agreement-based boundary detection enables correct random access decoding without requiring synchronization markers or modification of the encoded bitstream.

Bitstream 5710 represents a variable-length encoded bitstream formed by concatenating codewords of varying bit lengths, where each codeword represents a symbol or sourceblock and is drawn from a prefix-free codebook. Bitstream 5710 is the input data being processed by decoder instances 5720 during exemplary convergence process 5700. Bitstream 5710 extends horizontally to represent the sequential nature of the encoded data, with bit positions progressing from left to right. The structure of bitstream 5710 contains valid codeword boundaries at specific bit positions, though these boundaries are not explicitly marked or visible without proper decoding. Decoder instances 5720 access bitstream 5710 starting from arbitrary start offset N 5732 and advance through the encoded data by interpreting bit sequences as codewords according to a codebook. Bitstream 5710 serves as the reference against which the convergence behavior of decoder instances 5720 can be understood.

Decoder instances 5720 represent the plurality of decoder instances initialized at staggered bit offsets within bitstream 5710 to enable random access decoding. Decoder instances 5720 comprise decoder 0 5721, decoder 1 5722, through decoder L−1 5723, where L is the maximum codeword length. Decoder instances 5720 are initialized at consecutive bit positions starting from arbitrary start offset N 5732 and proceeding through positions N+1, N+2, and so forth up to N+L−1. Each instance within decoder instances 5720 operates independently, decoding bitstream 5710 from its assigned starting offset and producing decoded symbol sequences. During exemplary convergence process 5700, decoder instances 5720 initially produce divergent outputs in the region of incorrect decoding 5740, but eventually converge to produce identical outputs after convergence point 5750. The collective behavior of decoder instances 5720 enables the detection of valid codeword boundaries through agreement-based mechanisms.

Decoder 0 5721 represents the first decoder instance within decoder instances 5720, initialized at arbitrary start offset N 5732 in bitstream 5710. Decoder 0 5721 begins decoding from position N and advances through bitstream 5710 by interpreting consecutive bit sequences as codewords according to a prefix-free codebook. Because arbitrary start offset N 5732 is not known a priori to coincide with a valid codeword boundary, decoder 0 5721 may initially produce incorrect decoded symbols in the region of incorrect decoding 5740. As decoder 0 5721 continues to advance through bitstream 5710, it eventually transitions to producing correct decoded symbols after convergence point 5750, where its output begins to agree with the outputs of other decoder instances within decoder instances 5720.

Decoder 1 5722 represents the second decoder instance within decoder instances 5720, initialized at bit position N+1, which is one bit position after the starting position of decoder 0 5721. Decoder 1 5722 operates in parallel or in an interleaved manner with decoder 0 5721 and other decoder instances, independently decoding bitstream 5710 from its assigned offset. Like decoder 0 5721, decoder 1 5722 may produce incorrect outputs initially but eventually converges to correct decoding after convergence point 5750. The staggered starting position of decoder 1 5722 relative to decoder 0 5721 ensures that different possible bit-level alignments are explored by decoder instances 5720.

Ellipsis 5730 indicates that additional decoder instances exist between decoder 1 5722 and decoder L−1 5723 within decoder instances 5720. Ellipsis 5730 represents the continuation of the staggered initialization pattern, with intermediate decoder instances starting at positions N+2, N+3, and so forth. These intermediate decoder instances follow the same convergence behavior as decoder 0 5721 and decoder 1 5722, initially producing potentially incorrect outputs in the region of incorrect decoding 5740 and eventually converging to correct decoding after convergence point 5750. Ellipsis 5730 avoids visual clutter while indicating the presence of the complete set of L decoder instances required to ensure comprehensive coverage of all possible bit-level alignments within the maximum codeword length.

Decoder L−1 5723 represents the final decoder instance within decoder instances 5720, initialized at bit position N+L−1 where L is the maximum codeword length. Decoder L−1 5723 completes the coverage of all possible starting alignments by beginning at the last position in the staggered initialization window. Like all decoder instances within decoder instances 5720, decoder L−1 5723 decodes bitstream 5710 from its assigned starting position and participates in the convergence process illustrated by exemplary convergence process 5700. The presence of decoder L−1 5723 ensures that at least one decoder among decoder instances 5720 must be correctly aligned or will rapidly converge to a valid codeword boundary.

Arbitrary start offset N 5732 represents the bit position within bitstream 5710 from which random access decoding is initiated. Arbitrary start offset N 5732 serves as the reference point for initializing decoder instances 5720, with decoder 0 5721 starting at position N, decoder 1 5722 starting at position N+1, and so forth. The arbitrary nature of arbitrary start offset N 5732 means that this position is not known a priori to coincide with a valid codeword boundary in bitstream 5710. Because arbitrary start offset N 5732 may fall at any bit position, including positions that are mid-codeword, decoder instances 5720 initialized from this offset typically produce incorrect decoded symbols initially. Arbitrary start offset N 5732 marks the beginning of the convergence process where decoder instances 5720 must identify valid codeword boundaries through their collective decoding behavior and agreement detection.

Incorrect decoding 5740 represents the initial region of exemplary convergence process 5700 where decoder instances 5720 produce divergent and potentially incorrect decoded outputs. In incorrect decoding 5740, decoder 0 5721, decoder 1 5722, and other decoder instances within decoder instances 5720 are decoding from different bit alignments, most of which do not correspond to valid codeword boundaries. During incorrect decoding 5740, decoders disagree, meaning that the decoded symbol sequences produced by different decoder instances differ from one another because each instance is interpreting bit sequences from different misaligned positions. Incorrect decoding 5740 extends from arbitrary start offset N 5732 to convergence point 5750, representing the period during which decoder instances 5720 are advancing through bitstream 5710 but have not yet aligned to produce consistent outputs. The extent of incorrect decoding 5740 corresponds to expected convergence distance O(M²) 5731, which quantifies the typical number of bits that must be processed before convergence occurs.

Convergence point 5750 represents the bit position within bitstream 5710 where decoder instances 5720 transition from producing divergent incorrect outputs to producing identical correct outputs. Convergence point 5750 marks the boundary between incorrect decoding 5740 and the subsequent region where decoders agree and produce correct decoded symbols. At convergence point 5750, all decoder instances within decoder instances 5720 have aligned to the same codeword structure in bitstream 5710 and begin producing identical decoded symbol sequences. Convergence point 5750 corresponds to a valid codeword boundary in bitstream 5710, which is guaranteed by the agreement among all decoder instances initialized at all possible alignments within the maximum codeword length. The identification of convergence point 5750 enables transition to correct decoding guaranteed 5741, confirming that subsequent decoding operations will produce correct output. Convergence point 5750 is detected through agreement detection mechanisms that monitor the outputs of decoder instances 5720 and identify when all instances produce matching symbol sequences.

Expected convergence distance O(M²) 5731 represents the typical number of bits that must be decoded from arbitrary start offset N 5732 before convergence point 5750 is reached. Expected convergence distance O(M²) 5731 is characterized mathematically as being on the order of M², where M is the average length of codewords in the codebook used for decoding bitstream 5710. For NOT BAD codebooks and data generated by stochastic sources, expected convergence distance O(M²) 5731 is typically small relative to the size of encoded files or streams, making random access decoding practical for real-world applications. Expected convergence distance O(M²) 5731 quantifies the extent of incorrect decoding 5740 and provides a performance characterization of exemplary convergence process 5700. The probabilistic nature of expected convergence distance O(M²) 5731 reflects that convergence behavior depends on both the structure of the codebook and the statistical properties of the encoded data. While expected convergence distance O(M²) 5731 provides a typical case estimate, actual convergence may occur sooner or later depending on specific data patterns and codebook characteristics.

Transition to correct decoding guaranteed 5741 represents the assurance that decoding operations after convergence point 5750 will produce correct decoded symbols from bitstream 5710. Transition to correct decoding guaranteed 5741 is established by the agreement among all decoder instances within decoder instances 5720 at convergence point 5750. Because decoder instances 5720 are initialized at all possible bit-level alignments within the maximum codeword length, agreement among all instances can only occur when decoders are following the same correct decoding path that aligns with actual codeword boundaries in bitstream 5710. Transition to correct decoding guaranteed 5741 provides the correctness guarantee that enables random access decoding to be used reliably without requiring synchronization markers or external verification. After convergence point 5750, the region characterized by transition to correct decoding guaranteed 5741 extends indefinitely through the remainder of bitstream 5710, with all decoder instances within decoder instances 5720 producing identical and correct decoded outputs. The guarantee provided by transition to correct decoding guaranteed 5741 holds independently of arbitrary start offset N 5732 and without modification to bitstream 5710.

FIG. 57 demonstrates the temporal and spatial progression of exemplary convergence process 5700 as decoder instances 5720, comprising decoder 0 5721, decoder 1 5722, through decoder L−1 5723, advance through bitstream 5710 starting from arbitrary start offset N 5732. The illustration shows the transition from incorrect decoding 5740 where decoders disagree to the region after convergence point 5750 where decoders agree and produce correct output. Expected convergence distance O(M²) 5731 characterizes the typical extent of incorrect decoding 5740, while transition to correct decoding guaranteed 5741 provides assurance of correctness after convergence point 5750. This visual representation illustrates how the agreement-based detection mechanism enables random access decoding by identifying convergence point 5750 through the collective behavior of decoder instances 5720, transforming variable-length encoded bitstream 5710 from a sequential-access format into one that supports efficient random access, search, and partial decoding operations while preserving compression efficiency and maintaining compatibility with existing encoding formats.

### Hardware Architecture

Generally, the techniques disclosed herein may be implemented on hardware or a combination of software and hardware. For example, they may be implemented in an operating system kernel, in a separate user process, in a library package bound into network applications, on a specially constructed machine, on an application-specific integrated circuit (ASIC), or on a network interface card.

Software/hardware hybrid implementations of at least some of the aspects disclosed herein may be implemented on a programmable network-resident machine (which should be understood to include intermittently connected network-aware machines) selectively activated or reconfigured by a computer program stored in memory. Such network devices may have multiple network interfaces that may be configured or designed to utilize different types of network communication protocols. A general architecture for some of these machines may be described herein in order to illustrate one or more exemplary means by which a given unit of functionality may be implemented. According to specific aspects, at least some of the features or functionalities of the various aspects disclosed herein may be implemented on one or more general-purpose computers associated with one or more networks, such as for example an end-user computer system, a client computer, a network server or other server system, a mobile computing device (e.g., tablet computing device, mobile phone, smartphone, laptop, or other appropriate computing device), a consumer electronic device, a music player, or any other suitable electronic device, router, switch, or other suitable device, or any combination thereof. In at least some aspects, at least some of the features or functionalities of the various aspects disclosed herein may be implemented in one or more virtualized computing environments (e.g., network computing clouds, virtual machines hosted on one or more physical computing machines, or other appropriate virtual environments).

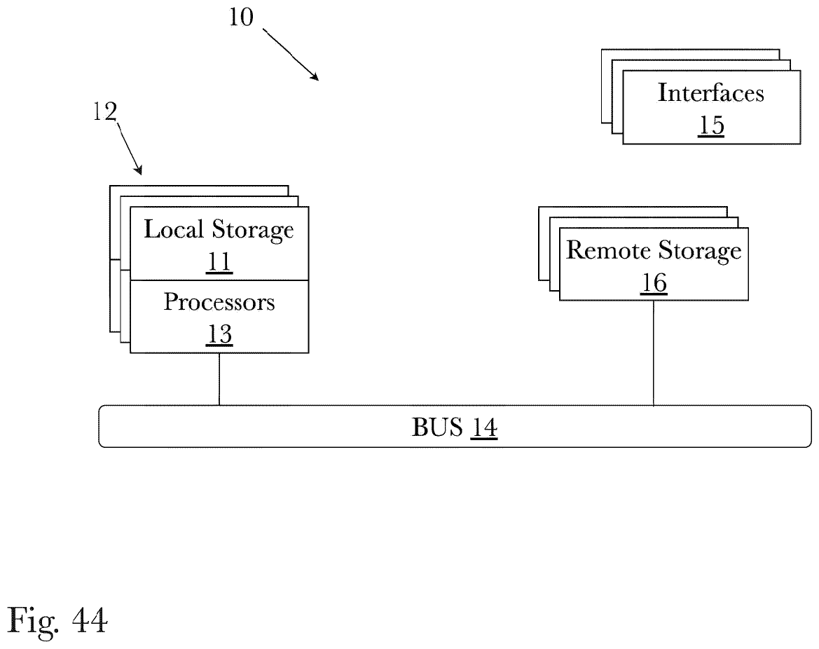

Referring now to FIG. 44, there is shown a block diagram depicting an exemplary computing device 10 suitable for implementing at least a portion of the features or functionalities disclosed herein. Computing device 10 may be, for example, any one of the computing machines listed in the previous paragraph, or indeed any other electronic device capable of executing software- or hardware-based instructions according to one or more programs stored in memory. Computing device 10 may be configured to communicate with a plurality of other computing devices, such as clients or servers, over communications networks such as a wide area network a metropolitan area network, a local area network, a wireless network, the Internet, or any other network, using known protocols for such communication, whether wireless or wired.

In one aspect, computing device 10 includes one or more central processing units (CPU) 12, one or more interfaces 15, and one or more busses 14 (such as a peripheral component interconnect (PCI) bus). When acting under the control of appropriate software or firmware, CPU 12 may be responsible for implementing specific functions associated with the functions of a specifically configured computing device or machine. For example, in at least one aspect, a computing device 10 may be configured or designed to function as a server system utilizing CPU 12, local memory 11 and/or remote memory 16, and interface(s) 15. In at least one aspect, CPU 12 may be caused to perform one or more of the different types of functions and/or operations under the control of software modules or components, which for example, may include an operating system and any appropriate applications software, drivers, and the like.

CPU 12 may include one or more processors 13 such as, for example, a processor from one of the Intel, ARM, Qualcomm, and AMD families of microprocessors. In some aspects, processors 13 may include specially designed hardware such as application-specific integrated circuits (ASICs), electrically erasable programmable read-only memories (EEPROMs), field-programmable gate arrays (FPGAs), and so forth, for controlling operations of computing device 10. In a particular aspect, a local memory 11 (such as non-volatile random access memory (RAM) and/or read-only memory (ROM), including for example one or more levels of cached memory) may also form part of CPU 12. However, there are many different ways in which memory may be coupled to system 10. Memory 11 may be used for a variety of purposes such as, for example, caching and/or storing data, programming instructions, and the like. It should be further appreciated that CPU 12 may be one of a variety of system-on-a-chip (SOC) type hardware that may include additional hardware such as memory or graphics processing chips, such as a QUALCOMM SNAPDRAGON™ or SAMSUNG EXYNOS™ CPU as are becoming increasingly common in the art, such as for use in mobile devices or integrated devices.

As used herein, the term “processor” is not limited merely to those integrated circuits referred to in the art as a processor, a mobile processor, or a microprocessor, but broadly refers to a microcontroller, a microcomputer, a programmable logic controller, an application-specific integrated circuit, and any other programmable circuit.

In one aspect, interfaces 15 are provided as network interface cards (NICs). Generally, NICs control the sending and receiving of data packets over a computer network; other types of interfaces 15 may for example support other peripherals used with computing device 10. Among the interfaces that may be provided are Ethernet interfaces, frame relay interfaces, cable interfaces, DSL interfaces, token ring interfaces, graphics interfaces, and the like. In addition, various types of interfaces may be provided such as, for example, universal serial bus (USB), Serial, Ethernet, FIREWIRE™, THUNDERBOLT™, PCI, parallel, radio frequency (RF), BLUETOOTH™, near-field communications (e.g., using near-field magnetics), 802.11 (Wi-Fi), frame relay, TCP/IP, ISDN, fast Ethernet interfaces, Gigabit Ethernet interfaces, Serial ATA (SATA) or external SATA (ESATA) interfaces, high-definition multimedia interface (HDMI), digital visual interface (DVI), analog or digital audio interfaces, asynchronous transfer mode (ATM) interfaces, high-speed serial interface (HSSI) interfaces, Point of Sale (POS) interfaces, fiber data distributed interfaces (FDDIs), and the like. Generally, such interfaces 15 may include physical ports appropriate for communication with appropriate media. In some cases, they may also include an independent processor (such as a dedicated audio or video processor, as is common in the art for high-fidelity A/V hardware interfaces) and, in some instances, volatile and/or non-volatile memory (e.g., RAM).

Although the system shown in FIG. 44 illustrates one specific architecture for a computing device 10 for implementing one or more of the aspects described herein, it is by no means the only device architecture on which at least a portion of the features and techniques described herein may be implemented. For example, architectures having one or any number of processors 13 may be used, and such processors 13 may be present in a single device or distributed among any number of devices. In one aspect, a single processor 13 handles communications as well as routing computations, while in other aspects a separate dedicated communications processor may be provided. In various aspects, different types of features or functionalities may be implemented in a system according to the aspect that includes a client device (such as a tablet device or smartphone running client software) and server systems (such as a server system described in more detail below).

Regardless of network device configuration, the system of an aspect may employ one or more memories or memory modules (such as, for example, remote memory block 16 and local memory 11) configured to store data, program instructions for the general-purpose network operations, or other information relating to the functionality of the aspects described herein (or any combinations of the above). Program instructions may control execution of or comprise an operating system and/or one or more applications, for example. Memory 16 or memories 11, 16 may also be configured to store data structures, configuration data, encryption data, historical system operations information, or any other specific or generic non-program information described herein.

Because such information and program instructions may be employed to implement one or more systems or methods described herein, at least some network device aspects may include nontransitory machine-readable storage media, which, for example, may be configured or designed to store program instructions, state information, and the like for performing various operations described herein. Examples of such nontransitory machine-readable storage media include, but are not limited to, magnetic media such as hard disks, floppy disks, and magnetic tape; optical media such as CD-ROM disks; magneto-optical media such as optical disks, and hardware devices that are specially configured to store and perform program instructions, such as read-only memory devices (ROM), flash memory (as is common in mobile devices and integrated systems), solid state drives (SSD) and “hybrid SSD” storage drives that may combine physical components of solid state and hard disk drives in a single hardware device (as are becoming increasingly common in the art with regard to personal computers), memristor memory, random access memory (RAM), and the like. It should be appreciated that such storage means may be integral and non-removable (such as RAM hardware modules that may be soldered onto a motherboard or otherwise integrated into an electronic device), or they may be removable such as swappable flash memory modules (such as “thumb drives” or other removable media designed for rapidly exchanging physical storage devices), “hot-swappable” hard disk drives or solid state drives, removable optical storage discs, or other such removable media, and that such integral and removable storage media may be utilized interchangeably. Examples of program instructions include both object code, such as may be produced by a compiler, machine code, such as may be produced by an assembler or a linker, byte code, such as may be generated by for example a JAVA™ compiler and may be executed using a Java virtual machine or equivalent, or files containing higher level code that may be executed by the computer using an interpreter (for example, scripts written in Python, Perl, Ruby, Groovy, or any other scripting language).

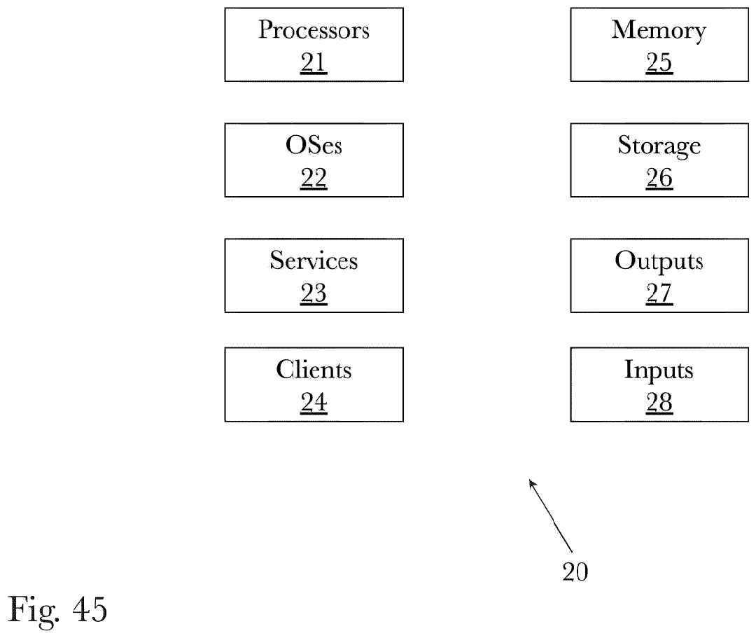

In some aspects, systems may be implemented on a standalone computing system. Referring now to FIG. 45, there is shown a block diagram depicting a typical exemplary architecture of one or more aspects or components thereof on a standalone computing system. Computing device 20 includes processors 21 that may run software that carry out one or more functions or applications of aspects, such as for example a client application 24. Processors 21 may carry out computing instructions under control of an operating system 22 such as, for example, a version of MICROSOFT WINDOWS™ operating system, APPLE macOS™ or iOS™ operating systems, some variety of the Linux operating system, ANDROID™ operating system, or the like. In many cases, one or more shared services 23 may be operable in system 20, and may be useful for providing common services to client applications 24. Services 23 may for example be WINDOWS™ services, user-space common services in a Linux environment, or any other type of common service architecture used with operating system 21. Input devices 28 may be of any type suitable for receiving user input, including for example a keyboard, touchscreen, microphone (for example, for voice input), mouse, touchpad, trackball, or any combination thereof. Output devices 27 may be of any type suitable for providing output to one or more users, whether remote or local to system 20, and may include for example one or more screens for visual output, speakers, printers, or any combination thereof. Memory 25 may be random-access memory having any structure and architecture known in the art, for use by processors 21, for example to run software. Storage devices 26 may be any magnetic, optical, mechanical, memristor, or electrical storage device for storage of data in digital form (such as those described above, referring to FIG. 44). Examples of storage devices 26 include flash memory, magnetic hard drive, CD-ROM, and/or the like.

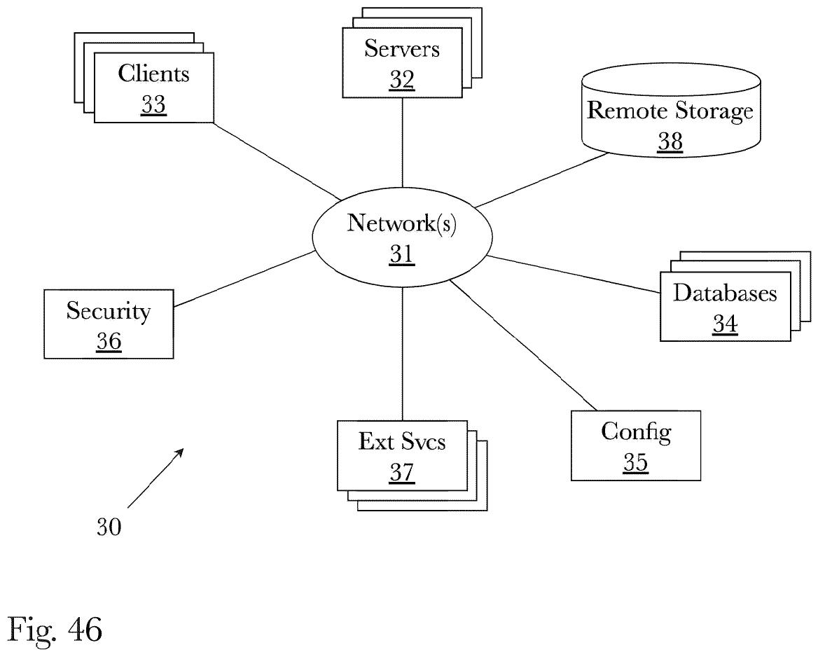

In some aspects, systems may be implemented on a distributed computing network, such as one having any number of clients and/or servers. Referring now to FIG. 46, there is shown a block diagram depicting an exemplary architecture 30 for implementing at least a portion of a system according to one aspect on a distributed computing network. According to the aspect, any number of clients 33 may be provided. Each client 33 may run software for implementing client-side portions of a system; clients may comprise a system 20 such as that illustrated in FIG. 45. In addition, any number of servers 32 may be provided for handling requests received from one or more clients 33. Clients 33 and servers 32 may communicate with one another via one or more electronic networks 31, which may be in various aspects any of the Internet, a wide area network, a mobile telephony network (such as CDMA or GSM cellular networks), a wireless network (such as Wi-Fi, WiMAX, LTE, and so forth), or a local area network (or indeed any network topology known in the art; the aspect does not prefer any one network topology over any other). Networks 31 may be implemented using any known network protocols, including for example wired and/or wireless protocols.

In addition, in some aspects, servers 32 may call external services 37 when needed to obtain additional information, or to refer to additional data concerning a particular call. Communications with external services 37 may take place, for example, via one or more networks 31. In various aspects, external services 37 may comprise web-enabled services or functionality related to or installed on the hardware device itself. For example, in one aspect where client applications 24 are implemented on a smartphone or other electronic device, client applications 24 may obtain information stored in a server system 32 in the cloud or on an external service 37 deployed on one or more of a particular enterprise's or user's premises.

In some aspects, clients 33 or servers 32 (or both) may make use of one or more specialized services or appliances that may be deployed locally or remotely across one or more networks 31. For example, one or more databases 34 may be used or referred to by one or more aspects. It should be understood by one having ordinary skill in the art that databases 34 may be arranged in a wide variety of architectures and using a wide variety of data access and manipulation means. For example, in various aspects one or more databases 34 may comprise a relational database system using a structured query language (SQL), while others may comprise an alternative data storage technology such as those referred to in the art as “NoSQL” (for example, HADOOP CASSANDRA™, GOOGLE BIGTABLE™, and so forth). In some aspects, variant database architectures such as column-oriented databases, in-memory databases, clustered databases, distributed databases, or even flat file data repositories may be used according to the aspect. It will be appreciated by one having ordinary skill in the art that any combination of known or future database technologies may be used as appropriate, unless a specific database technology or a specific arrangement of components is specified for a particular aspect described herein. Moreover, it should be appreciated that the term “database” as used herein may refer to a physical database machine, a cluster of machines acting as a single database system, or a logical database within an overall database management system. Unless a specific meaning is specified for a given use of the term “database”, it should be construed to mean any of these senses of the word, all of which are understood as a plain meaning of the term “database” by those having ordinary skill in the art.

Similarly, some aspects may make use of one or more security systems 36 and configuration systems 35. Security and configuration management are common information technology (IT) and web functions, and some amount of each are generally associated with any IT or web systems. It should be understood by one having ordinary skill in the art that any configuration or security subsystems known in the art now or in the future may be used in conjunction with aspects without limitation, unless a specific security 36 or configuration system 35 or approach is specifically required by the description of any specific aspect.

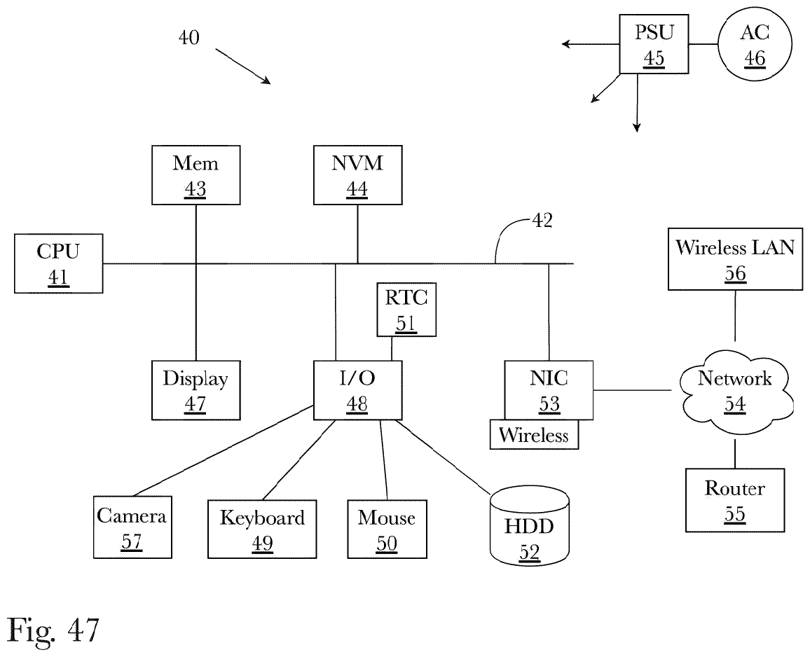

FIG. 47 shows an exemplary overview of a computer system 40 as may be used in any of the various locations throughout the system. It is exemplary of any computer that may execute code to process data. Various modifications and changes may be made to computer system 40 without departing from the broader scope of the system and method disclosed herein. Central processor unit (CPU) 41 is connected to bus 42, to which bus is also connected memory 43, nonvolatile memory 44, display 47, input/output (I/O) unit 48, and network interface card (NIC) 53. I/O unit 48 may, typically, be connected to peripherals such as a keyboard 49, pointing device 50, hard disk 52, real-time clock 51, a camera 57, and other peripheral devices. NIC 53 connects to network 54, which may be the Internet or a local network, which local network may or may not have connections to the Internet. The system may be connected to other computing devices through the network via a router 55, wireless local area network 56, or any other network connection. Also shown as part of system 40 is power supply unit 45 connected, in this example, to a main alternating current (AC) supply 46. Not shown are batteries that could be present, and many other devices and modifications that are well known but are not applicable to the specific novel functions of the current system and method disclosed herein. It should be appreciated that some or all components illustrated may be combined, such as in various integrated applications, for example Qualcomm or Samsung system-on-a-chip (SOC) devices, or whenever it may be appropriate to combine multiple capabilities or functions into a single hardware device (for instance, in mobile devices such as smartphones, video game consoles, in-vehicle computer systems such as navigation or multimedia systems in automobiles, or other integrated hardware devices).

In various aspects, functionality for implementing systems or methods of various aspects may be distributed among any number of client and/or server components. For example, various software modules may be implemented for performing various functions in connection with the system of any particular aspect, and such modules may be variously implemented to run on server and/or client components.

The skilled person will be aware of a range of possible modifications of the various aspects described above. Accordingly, the present invention is defined by the claims and their equivalents.

What is claimed is:

1. A computer system configured to execute software instructions stored on nontransitory machine-readable storage media, wherein the software instructions comprise instructions that cause the computer system to:
receive a variable-length encoded bitstream comprising a sequence of codewords drawn from a prefix-free codebook;
select an arbitrary bit offset within the variable-length encoded bitstream;
initialize a plurality of decoder instances at staggered bit offsets, wherein the staggered bit offsets comprise the arbitrary bit offset and a set of additional offsets positioned sequentially following the arbitrary bit offset, and wherein a spacing between consecutive offsets does not exceed a maximum codeword length associated with the prefix-free codebook;
advance each decoder instance of the plurality of decoder instances through the variable-length encoded bitstream by decoding symbols according to the prefix-free codebook;
monitor decoded outputs produced by the plurality of decoder instances to detect decoder agreement, wherein decoder agreement is identified when all decoder instances produce identical decoded symbol sequences over a defined region of the bitstream;
identify a valid codeword boundary at a bit position where decoder agreement is detected; and
decode data from the identified valid codeword boundary.

2. The computer system of claim 1, wherein the plurality of decoder instances comprises L decoder instances initialized at consecutive bit offsets from N to N+L−1, where N is the arbitrary bit offset and L is the maximum codeword length.

3. The computer system of claim 1, further comprising software instructions that cause the computer system to:
execute the plurality of decoder instances in parallel using multiple processor cores or vectorized instructions; and
evaluate agreement among the plurality of decoder instances continuously or at periodic checkpoints during parallel execution.

4. The computer system of claim 1, further comprising software instructions that cause the computer system to:
execute the plurality of decoder instances in an interleaved manner by advancing each decoder instance incrementally; and
evaluate agreement among the plurality of decoder instances after each incremental advancement or after a fixed number of decoding steps.

5. The computer system of claim 1, further comprising software instructions that cause the computer system to:
order the plurality of decoder instances according to their current bit positions;
advance only a decoder instance at an earliest position among the plurality of decoder instances at each decoding step;
detect when two or more decoder instances reach a same bit position and merge the two or more decoder instances by discarding redundant instances; and
identify a valid codeword boundary when a single decoder instance remains after merging.

6. The computer system of claim 1, further comprising software instructions that cause the computer system to:
evaluate the prefix-free codebook to determine whether the prefix-free codebook is a BAD codebook or a NOT BAD codebook;
classify the prefix-free codebook as a BAD codebook when a greatest common divisor of all codeword lengths in the prefix-free codebook is greater than one; and
reject or modify the prefix-free codebook when the prefix-free codebook is classified as a BAD codebook.

7. The computer system of claim 6, wherein the prefix-free codebook is classified as a NOT BAD codebook when the greatest common divisor of all codeword lengths is equal to one, and wherein NOT BAD codebooks enable high-probability rapid convergence to valid codeword boundaries.

8. The computer system of claim 7, wherein the prefix-free codebook comprises a canonical Huffman codebook in which codewords of a same length are assigned consecutive binary values and shorter codewords have numerically smaller values than longer codewords.

9. The computer system of claim 1, further comprising software instructions that cause the computer system to:
require decoder agreement to persist over a minimum number of decoded symbols or bits before declaring convergence; and
adjust a length of an agreement window to achieve a desired confidence level that convergence has occurred.

10. The computer system of claim 1, further comprising software instructions that cause the computer system to perform random access search by:
identifying a candidate match location within the variable-length encoded bitstream using a search operation;
initiating decoding at or near the candidate match location by selecting an arbitrary bit offset corresponding to the candidate match location;
converging to a valid codeword boundary using the plurality of decoder instances and agreement-based boundary detection; and
verifying the candidate match location by decoding a limited window of data surrounding the identified valid codeword boundary.

11. A computer-implemented method comprising the steps of:
receiving a variable-length encoded bitstream comprising a sequence of codewords drawn from a prefix-free codebook;
selecting an arbitrary bit offset within the variable-length encoded bitstream;
initializing a plurality of decoder instances at staggered bit offsets, wherein the staggered bit offsets comprise the arbitrary bit offset and a set of additional offsets positioned sequentially following the arbitrary bit offset, and wherein a spacing between consecutive offsets does not exceed a maximum codeword length associated with the prefix-free codebook;
advancing each decoder instance of the plurality of decoder instances through the variable-length encoded bitstream by decoding symbols according to the prefix-free codebook;
monitoring decoded outputs produced by the plurality of decoder instances to detect decoder agreement, wherein decoder agreement is identified when all decoder instances produce identical decoded symbol sequences over a defined region of the bitstream;
identifying a valid codeword boundary at a bit position where decoder agreement is detected; and
decoding data from the identified valid codeword boundary.

12. The method of claim 11, wherein the plurality of decoder instances comprises L decoder instances initialized at consecutive bit offsets from N to N+L−1, where N is the arbitrary bit offset and L is the maximum codeword length.

13. The method of claim 11, further comprising the steps of:
executing the plurality of decoder instances in parallel using multiple processor cores or vectorized instructions; and
evaluating agreement among the plurality of decoder instances continuously or at periodic checkpoints during parallel execution.

14. The method of claim 11, further comprising the steps of:
executing the plurality of decoder instances in an interleaved manner by advancing each decoder instance incrementally; and
evaluating agreement among the plurality of decoder instances after each incremental advancement or after a fixed number of decoding steps.

15. The method of claim 11, further comprising the steps of:
ordering the plurality of decoder instances according to their current bit positions;
advancing only a decoder instance at an earliest position among the plurality of decoder instances at each decoding step;
detecting when two or more decoder instances reach a same bit position and merging the two or more decoder instances by discarding redundant instances; and
identifying a valid codeword boundary when a single decoder instance remains after merging.

16. The method of claim 11, further comprising the steps of:
evaluating the prefix-free codebook to determine whether the prefix-free codebook is a BAD codebook or a NOT BAD codebook;
classifying the prefix-free codebook as a BAD codebook when a greatest common divisor of all codeword lengths in the prefix-free codebook is greater than one; and
rejecting or modifying the prefix-free codebook when the prefix-free codebook is classified as a BAD codebook.

17. The method of claim 16, wherein the prefix-free codebook is classified as a NOT BAD codebook when the greatest common divisor of all codeword lengths is equal to one, and wherein NOT BAD codebooks enable high-probability rapid convergence to valid codeword boundaries.

18. The method of claim 17, wherein the prefix-free codebook comprises a canonical Huffman codebook in which codewords of a same length are assigned consecutive binary values and shorter codewords have numerically smaller values than longer codewords.

19. The method of claim 11, further comprising the steps of:
requiring decoder agreement to persist over a minimum number of decoded symbols or bits before declaring convergence; and
adjusting a length of an agreement window to achieve a desired confidence level that convergence has occurred.

20. The method of claim 11, further comprising the steps of performing random access search by:
identifying a candidate match location within the variable-length encoded bitstream using a search operation;
initiating decoding at or near the candidate match location by selecting an arbitrary bit offset corresponding to the candidate match location;
converging to a valid codeword boundary using the plurality of decoder instances and agreement-based boundary detection; and
verifying the candidate match location by decoding a limited window of data surrounding the identified valid codeword boundary.
